(19) United States
(12) Patent Application Publication
(10) Pub. No.: US 2023/0004085 A1
(43) Pub. Date: Jan. 5, 2023

(54) METHOD FOR MANUFACTURING CHEMICALLY AMPLIFIED PHOTOSENSITIVE COMPOSITION, PREMIX SOLUTION FOR PREPARING CHEMICALLY AMPLIFIED PHOTOSENSITIVE COMPOSITION, CHEMICALLY AMPLIFIED PHOTOSENSITIVE COMPOSITION, METHOD FOR MANUFACTURING PHOTOSENSITIVE DRY FILM, AND METHOD FOR MANUFACTURING PATTERNED RESIST FILM

(71) Applicant: TOKYO OHKA KOGYO CO., LTD., Kawasaki-shi (JP)

(72) Inventors: Daisuke OJIMA, Kawasaki-shi (JP); Kazuaki EBISAWA, Kawasaki-shi (JP)

(21) Appl. No.: 17/755,253

(22) PCT Filed: Oct. 16, 2020
(86) PCT No.: PCT/JP2020/039019

§ 371 Date: Apr. 25, 2022

(30) Foreign Application Priority Data
Nov. 12, 2019 (JP) 2019-205087

(51) Int. Cl. G03F 7/004; G03F 7/039

(52) U.S. Cl. CPC G03F 7/0048; G03F 7/0392; G03F 7/0045

(57) ABSTRACT

A method for manufacturing a chemically amplified photosensitive composition capable of reducing a foreign matter derived from a sulfur-containing compound. The method includes an acid generating agent which generates an acid by irradiation with an active ray or radiation, a sulfur-containing compound which is a solid at room temperature, a first solvent having a Hansen solubility parameter in which a polar term δp is 10 (MPa^{0.5}) or more, and a second solvent which is different than the first solvent, the method including preparing a solution of the sulfur-containing compound by dissolving the sulfur-containing compound in the first solvent, and blending the solution of the sulfur-containing compound, the acid generating agent, and the second solvent.

### TECHNICAL FIELD

The present invention relates to a method for manufacturing a chemically amplified photosensitive composition, a premix solution for preparing a chemically amplified photosensitive composition, the premix solution being capable of being used in the method for manufacturing a chemically amplified photosensitive composition, a chemically amplified photosensitive composition capable of being manufactured by the method for manufacturing a chemically amplified photosensitive composition, a method for manufacturing a photosensitive dry film including a photosensitive layer including the chemically amplified photosensitive composition, and a method for manufacturing a patterned resist film by using the chemically amplified photosensitive composition.

### BACKGROUND ART

Photofabrication is now the mainstream of a microfabrication technique. Photofabrication is a generic term describing the technology used for manufacturing a wide variety of precision components such as semiconductor packages. The manufacturing is carried out by applying a photoresist composition to the surface of a processing target to form a photoresist layer, patterning this photoresist layer using photolithographic techniques, and then conducting chemical etching, electrolytic etching, or electroforming mainly based on electroplating, using the patterned photoresist layer (photoresist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these high density packaging techniques, connection terminals, such as protruding electrodes (mounting terminals), e.g., bumps protruding from the package, or metal posts to connect redistribution that extends from peripheral terminals on the wafer with the mounting terminals, are disposed on the surface of the substrate with high precision.

In the photofabrication as described above, a photoresist composition is used, and chemically amplified photosensitive compositions containing an acid generating agent have been known as such a photoresist composition (see Patent Documents 1, 2 and the like). According to the chemically amplified photosensitive composition, an acid is generated from the acid generating agent upon irradiation with radiation (exposure) and diffusion of the acid is promoted through heat treatment, to cause an acid catalytic reaction with a base resin and the like in the composition, resulting in a change to the alkali-solubility of the same.

Such chemically amplified photosensitive compositions are used, for example, in formation of plated articles such as bumps, metal posts, and Cu redistribution, for example, in plating steps, in addition to formation of patterned insulating films or etching masks. Specifically, a photoresist layer having a desired film thickness is formed on a support such as a metal substrate using a chemically amplified photosensitive composition, and the photoresist layer is exposed through a predetermined mask pattern and is developed. Thereby, a photoresist pattern used as a template in which portions for forming plated articles have been selectively removed (stripped) is formed. Then, bumps, metal posts, and Cu redistribution can be formed by embedding a conductor such as copper into the removed portions (nonresist portions) using plating, and then removing the surrounding photoresist pattern.
Patent Document 1: Japanese Unexamined Patent Application, Publication No. H09-176112
Patent Document 2: Japanese Unexamined Patent Application, Publication No. H11-52562
Patent Document 3: Japanese Unexamined Patent Application, Publication No. 2015-87759
Patent Document 4: Japanese Unexamined Patent Application, Publication No. 2016-502142
Patent Document 5: Japanese Unexamined Patent Application, Publication No. 2019-514072

### DISCLOSURE OF THE INVENTION

### Problems to be Solved by the Invention

In general, when a resist pattern is formed, its cross-sectional shape is desirably rectangular in many cases. In particular, formation of connection terminals such as bumps and metal posts, or formation of Cu redistribution, by the plating as mentioned above, the cross-sectional shape of a nonresist section of the resist pattern as a template is strongly desired to be rectangular. In the formation process of a plated article, when the cross-sectional shape of a nonresist section of the resist pattern as a template is rectangular, a contact area between the connection terminals such as bumps, metal posts, and the like, or the bottom surface of the Cu redistribution and a support can be sufficiently secured. Thus, connection terminals or Cu redistribution having favorable adhesion to the support can be easily obtained.

As a technique to improve a shape of a resist pattern, formulating a sulfur-containing compound has been disclosed (Patent Documents 3 to 5). However, when forming a resist pattern by using one of the chemically amplified resist compositions including a sulfur-containing compound, as disclosed in Patent Documents 3 to 5, etc., a foreign matter is often contained in the photosensitive composition or a foreign matter is often generated in the obtained resist pattern. This foreign matter is derived from the sulfur-containing compound included in the chemically amplified resist composition. When a resist pattern including a foreign matter is used as a template for forming a plated article or etching mask, it is difficult to form a plated article or etched product having a desired shape. In addition, while a chemically amplified resist composition is often used after filtration, when a foreign matter derived from the sulfur-containing compound is removed by this filtration, there is a risk that a desired effect of improving the shape of a resist pattern may be impaired due to a reduction in the content of the sulfur-containing compound in the chemically amplified resist composition. For this reason, a method for producing a chemically amplified resist composition capable of reducing an amount of foreign matter derived from a sulfur-containing compound, a chemically amplified resist composition produced by the method, and the like are desired.

The present invention has been made in light of the above-described problem, and objects of the present invention are to provide: a method for manufacturing a chemically amplified photosensitive composition capable of reducing an amount of a foreign matter derived from a sulfur-containing compound, a premix solution for preparing a chemically amplified photosensitive composition, the premix solution being capable of being used in the method for manufacturing a chemically amplified photosensitive composition, a chemically amplified photosensitive composition capable of being manufactured by the method for manufacturing a chemically amplified photosensitive composition, a method for manufacturing a photosensitive dry film including a photosensitive layer including the chemically amplified photosensitive composition, and a method for manufacturing a patterned resist film by using the chemically amplified photosensitive composition.

### Means for Solving the Problems

As a result of extensive studies in order to achieve the above-mentioned objects, the present inventors have found that the above-mentioned problem can be solved by the following method: when preparing a chemically amplified photosensitive composition including: an acid generating agent (A) to generate an acid by irradiation with an active ray or radiation and a sulfur-containing compound (C), the sulfur-containing compound (C) being solid at room temperature, the sulfur-containing compound (C) is dissolved, in advance, in a solvent (S1) having a Hansen solubility parameter in which a polar term δp is 10 (MPa^{0.5}) or more to prepare a solution of the sulfur-containing compound (C), and this solution of the sulfur-containing compound (C) is blended with the acid generating agent (A) and a solvent (S2), the solvent (S2) being a different solvent from the solvent (S1), whereby the present invention has been completed. Specifically, the present invention provides the following.

A first aspect of the present invention relates to a method for manufacturing a chemically amplified photosensitive composition,
the photosensitive composition including:
   an acid generating agent (A) to generate an acid by irradiation with an active ray or radiation,
   a sulfur-containing compound (C), the sulfur-containing compound (C) being solid at room temperature,
   a solvent (S1) having a Hansen solubility parameter in which a polar term δp is 10 (MPa^{0.5}) or more, and
   a solvent (S2), the solvent (S2) being a different solvent from the solvent (S1),
the method including:
   preparing a solution of the sulfur-containing compound (C) by dissolving the sulfur-containing compound (C) in the solvent (S1), and
   blending the solution of the sulfur-containing compound (C), the acid generating agent (A), and the solvent (S2).

A second aspect of the present invention relates to a premix solution for preparing a chemically amplified photosensitive composition,
the premix solution including:
   a sulfur-containing compound (C), the sulfur-containing compound (C) being solid at room temperature, and
   a solvent (S1) having a Hansen solubility parameter in which a polar term δp is 10 (MPa^{0.5}) or more,
the sulfur-containing compound (C) being dissolved in the solvent (S1).

A third aspect of the present invention relates to a chemically amplified photosensitive composition, including:
an acid generating agent (A) to generate an acid by irradiation with an active ray or radiation,
a sulfur-containing compound (C), the sulfur-containing compound (C) being solid at room temperature,
a solvent (S1) having a Hansen solubility parameter in which a polar term δp is 10 (MPa^{0.5}) or more, and
a solvent (S2), the solvent (S2) being a different solvent from the solvent (S1),
   the chemically amplified photosensitive composition having a content of the solvent (S1) of greater than 0% by mass and less than 5% by mass, with respect to a total mass of the solvent (S1) and the solvent (S2).

A fourth aspect of the present invention relates to a method for manufacturing a photosensitive dry film, the method including coating a substrate film with the chemically amplified photosensitive composition as described in the third aspect, to form the photosensitive layer.

A fifth aspect of the present invention relates to a method for manufacturing a patterned resist film, the method including: laminating a photosensitive layer on a substrate, the layer including the chemically amplified photosensitive composition as described in the third aspect; exposing the photosensitive layer through irradiation with an active ray or radiation in a position-selective manner; and developing the exposed photosensitive layer.

### Effects of the Invention

According to the present invention, it is possible to provide a method for manufacturing a chemically amplified photosensitive composition capable of reducing an amount of a foreign matter derived from a sulfur-containing compound, a premix solution for preparing a chemically amplified photosensitive composition, the premix solution being capable of being used in the method for manufacturing a chemically amplified photosensitive composition, a chemically amplified photosensitive composition manufactured by the method for manufacturing a chemically amplified photosensitive composition, a method for manufacturing a photosensitive dry film including a photosensitive layer including the chemically amplified photosensitive composition, and a method for manufacturing a patterned resist film by using the chemically amplified photosensitive composition.

### Preferred Mode for Carrying Out the Invention

### <<Manufacturing Method of Chemically Amplified Photosensitive Composition, the Chemically Amplified Photosensitive Composition, and Premix Solution for Preparing the Chemically Amplified Photosensitive Composition>>

By the method described below for manufacturing a chemically amplified photosensitive composition, the chemically amplified photosensitive composition including an acid generating agent (A) to generate an acid by irradiation with an active ray or radiation (hereinafter, also referred to as an acid generating agent (A)), a sulfur-containing compound (C), the sulfur-containing compound (C) being solid at room temperature, a solvent (S1) having a Hansen solubility parameter in which a polar term δp is 10 (MPa^{0.5}) or more, and a solvent (S2), the solvent (S2) being a different solvent from the solvent (S1). The method described below for manufacturing the photosensitive composition includes preparing a solution of the sulfur-containing compound (C) by dissolving the sulfur-containing compound (C) in the solvent (S1), and blending the solution of the sulfur-containing compound (C), the acid generating agent (A), and the solvent (S2). Firstly, the chemically amplified photosensitive composition prepared by the manufacturing method of the chemically amplified photosensitive composition is described.

The chemically amplified photosensitive composition is the same as conventionally known chemically amplified photosensitive compositions each including an acid generating agent (A), except that the acid generating agent (A), the sulfur-containing compound (C), the sulfur-containing compound (C) being solid at room temperature, the solvent (S1) having a Hansen solubility parameter in which a polar term δp is 10 (MPa^{0.5}) or more, and the solvent (S2), the solvent (S2) being a different solvent from the solvent (S1), are included. The chemically amplified photosensitive composition may be a positive-type photosensitive composition having a developing solution-solubility that increases under action of an acid generated by exposure, or a negative-type photosensitive composition having a developing solution-solubility that decreases under action of an acid generated by exposure.

Examples of the positive-type chemically amplified photosensitive composition include a photosensitive composition including a resin (B) having an alkali solubility that increases under action of an acid in addition to the acid generating agent (A), the sulfur-containing compound (C), the solvent (S1), and the solvent (S2), the resin (B) including an alkali soluble group protected by a group to be deprotected by action of an acid, typified by a tert-butyl group, a tert-butoxy carbonyl group, a tetrahydropyranyl group, an acetal group, and a trimethylsilyl group. Examples of the negative-type chemically amplified photosensitive composition include a photosensitive composition including a condensing agent such as methylol melamine, and a resin to be crosslinked by a condensing agent such as a novolac resin, in addition to the acid generating agent (A), the sulfur-containing compound (C), the solvent (S1), and the solvent (S2). When such a photosensitive composition is exposed to light, the photosensitive composition is cured by a crosslinking reaction caused by an acid generated by the exposure. Furthermore, as the negative-type chemically amplified photosensitive composition, a photosensitive composition including an epoxy compound together with the acid generating agent (A), the sulfur-containing compound (C), the solvent (S1), and the solvent (S2) is preferable. When such a photosensitive composition is exposed to light, cationic polymerization of the epoxy compound proceeds by an acid generated by exposure to light, and as a result, the photosensitive composition is cured.

Among these chemically amplified photosensitive compositions, the chemically amplified positive-type photosensitive composition including the acid generating agent (A), the resin (B) having an alkali solubility that increases under action of an acid, and the acid diffusion inhibiting agent (F) is preferable, because desired high sensitivity can be particularly easily achieved, and because the patterned resist film is easily provided with desired characteristics by adjusting the types of constituent units or the ratio of the constituent units of the resin (B) having an alkali solubility that increases under action of an acid.

Hereinafter, essential or optional components of the chemically amplified positive-type photosensitive composition (hereinafter, also referred to as “photosensitive composition”) including the acid generating agent (A), the resin (B) having an alkali solubility that increases under action of an acid (hereinafter, also referred to as “resin (B)), the sulfur-containing compound (C), the solvent (S1), and the solvent (S2) are described as a representative example of the photosensitive composition. The manufacturing method thereof will be also described. Note here that the below-mentioned acid generating agent (A), the sulfur-containing compound (C), the solvent (S1), and the solvent (S2) are applicable to photosensitive compositions other than the positive-type photosensitive composition described below.

### <Acid Generating Agent (A)>

The acid generating agent (A) is a compound to produce an acid when irradiated with an active ray or radiation, and is not particularly limited as long as it is a compound which directly or indirectly produces an acid under the action of light. The acid generating agent (A) is preferably any one of the acid generating agents of the first to fifth aspects that will be described below. Hereinafter, among suitably used acid generating agents (A) in the positive-type photosensitive composition, particularly suitable acid generating agents (A) will be described as the first to fifth aspects.

An example of the first aspect of the acid generating agent (A) may include a compound represented by the following formula (a1).

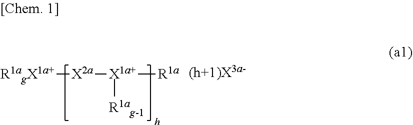

In the formula (a1), X^{1a} represents a sulfur atom or iodine atom respectively having a valence of g; g represents 1 or 2. h represents the number of repeating units in the structure within parentheses. R^{1a} represents an organic group that is bonded to X^{1a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms, or an alkynyl group having 2 or more and 30 or less carbon atoms, and R^{1a} may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and halogen atoms. The number of R^{1a}s is g+h(g−1)+1, and the R^{1a}s may be respectively identical to or different from each other. Furthermore, two or more R^{1a}s may be bonded to each other directly or via —O—, —S—, —SO—, —SO₂—, —NH—, —NR^{2a}—, —CO—, —COO—, —CONH—, an alkylene group having 1 or more and 3 or less carbon atoms, or a phenylene group, and may form a ring structure including X^{1a}. R^{2a} represents an alkyl group having 1 or more and 5 or less carbon atoms, or an aryl group having 6 or more and 10 or less carbon atoms.

X^{2a} represents a structure represented by the following formula (a2).

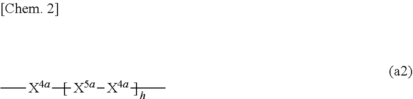

In the above formula (a2), X^{4a} represents an alkylene group having 1 or more and 8 or less carbon atoms, an arylene group having 6 or more and 20 or less carbon atoms, or a divalent group of a heterocyclic compound having 8 or more and 20 or less carbon atoms, and X^{4a} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{5a} represents —O—, —S—, —SO—, —SO₂—, —NH—, —NR^{2a}—, —CO—, —COO—, —CONH—, an alkylene group having 1 or more and 3 or less carbon atoms, or a phenylene group. h represents the number of repeating units of the structure in parentheses. X^{4a}s in the number of h+1 and X^{5a}s in the number of h may be identical to or different from each other. R^{2a} has the same definition as described above.

X^{3a-} represents a counterion of an onium, and examples thereof include a fluorinated alkylfluorophosphoric acid anion represented by the following formula (a17) or a borate anion represented by the following formula (a18).

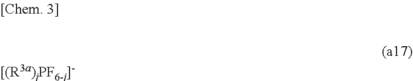

In the formula (a17), R^{3a} represents an alkyl group having 80% or more of the hydrogen atoms substituted with fluorine atoms. j represents the number of R^{3a}s and is an integer of 1 or more and 5 or less. R^{3a}s in the number of j may be respectively identical to or different from each other.

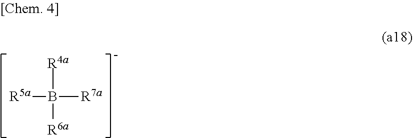

In the formula (a18), R^{4a} to R^{7a} each independently represents a fluorine atom or a phenyl group, and a part or all of the hydrogen atoms of the phenyl group may be substituted with at least one selected from the group consisting of a fluorine atom and a trifluoromethyl group.

Examples of the onium ion in the compound represented by the above formula (a1) include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfo-nium, 2-naphthylmethyl(1-ethoxycarbonyl)ethylsulfonium, 4-hydroxyphenylmethylphenacylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, or the like.

Among the onium ions in the compound represented by the above formula (a1), a preferred onium ion may be a sulfonium ion represented by the following formula (a19).

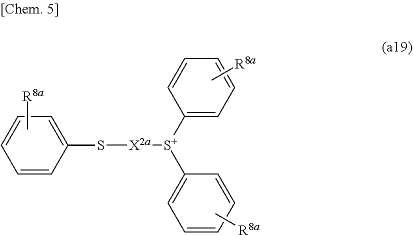

In the above formula (a19), R^{8a}s each independently represents a hydrogen atom or a group selected from the group consisting of alkyl, hydroxyl, alkoxy, alkylcarbonyl, alkylcarbonyloxy, alkyloxycarbonyl, a halogen atom, an aryl, which may be substituted, and arylcarbonyl. X^{2a} has the same definition as X^{2a} in the above formula (a1)

Specific examples of the sulfonium ion represented by the above formula (a19) include 4-(phenylthio)phenyldiphenylsulfonium, 4-(4-benzoyl-2-chlorophenylthio)phenylbis (4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, and diphenyl[4-(p-terphenylthio)phenyl]diphenylsulfonium.

In regard to the fluorinated alkylfluorophosphoric acid anion represented by the above formula (a17), R^{3a} represents an alkyl group substituted with a fluorine atom, and a preferred number of carbon atoms is 1 or more and 8 or less, while a more preferred number of carbon atoms is 1 or more and 4 or less. Specific examples of the alkyl group include linear alkyl groups such as methyl, ethyl, propyl, butyl, pentyl and octyl; branched alkyl groups such as isopropyl, isobutyl, sec-butyl and tert-butyl; and cycloalkyl groups such as cyclopropyl, cyclobutyl, cyclopentyl, and cyclohexyl. The proportion of hydrogen atoms substituted with fluorine atoms in the alkyl groups is usually 80% or more, preferably 90% or more, and even more preferably 100%. If the substitution ratio of fluorine atoms is less than 80%, the acid strength of the onium fluorinated alkylfluorophosphate represented by the above formula (a1) decreases.

A particularly preferred example of R^{3a} is a linear or branched perfluoroalkyl group having 1 or more and 4 or less carbon atoms and a substitution ratio of fluorine atoms of 100%. Specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF, and (CF₃)₃C. j which is the number of R^{3a}s represents an integer of 1 or more and 5 or less, and is preferably 2 or more and 4 or less, and particularly preferably 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻, or [(CF₃CF₂CF₂)₃PF₃]⁻. Among these, [(CF₃CF₂)₃PF₃]⁻, [(CF₃CF₂CF₂)₃PF₃]⁻, [((CF₃) CF)₃PF₃]⁻, [((CF₃)₂CF)₂PF₄]⁻, [((CF₃)₂CFCF₂)₃PF₃]⁻, or [((CF₃)₂CFCF₂)₂PF₄]⁻ are particularly preferred.

Preferred specific examples of the borate anion represented by the above formula (a18) include tetrakis (pentafluorophenyl) borate ([B(C₆F₅)₄]⁻), tetrakis [(trifluoromethyl)phenyl] borate ([B(C₆H₄CF₃)₄]⁻), difluorobis (pentafluorophenyl) borate ([(C₆F₅)₂BF₂]⁻), trifluoro(pentafluorophenyl)borate ([(C₆F₅)BF₃]⁻), and tetrakis (difluorophenyl) borate ([B(C₆H₃F₂)₄]⁻). Among these, tetrakis (pentafluorophenyl) borate ([B(C₆F₅)₄]⁻) is particularly preferred.

Examples of the second aspect of the acid generating agent (A) include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-S-ethoxyphenyl)ethenyl]-s-triazine, 2,4-bis(trichloromethyl)-6-[2-(3-methoxy-S-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following formula (a3) such as tris(2,3-dibromopropyl)isocyanurate.

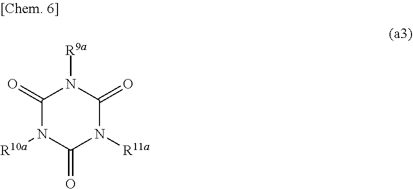

In the above formula (a3), R^{9a}, R^{10a}, and R^{11a} each independently represent a halogenated alkyl group.

Further, examples of the third aspect of the acid generating agent (A) include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile, and compounds represented by the following formula (a4) having an oximesulfonate group.

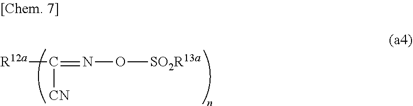

In the above formula (a4), R^{12a} represents a monovalent, divalent or trivalent organic group, R^{13a} represents a substituted or unsubstituted saturated hydrocarbon group, an unsaturated hydrocarbon group, or an aromatic group, and n represents the number of repeating units of the structure in the parentheses.

In the formula (a4), examples of the aromatic group include aryl groups such as a phenyl group and a naphthyl group, and heteroaryl groups such as a furyl group and a thienyl group. These may have one or more appropriate substituents such as halogen atoms, alkyl groups, alkoxy groups and nitro groups on the rings. It is particularly preferable that R^{13a} is an alkyl group having 1 or more and 6 or less carbon atoms such as a methyl group, an ethyl group, a propyl group, and a butyl group. In particular, compounds in which R^{12a} represents an aromatic group, and R^{13a} represents an alkyl group having 1 or more and 4 or less carbon atoms are preferred.

Examples of the acid generating agent represented by the above formula (a4) include compounds in which R^{12a} is any one of a phenyl group, a methylphenyl group and a methoxyphenyl group, and R^{13a} is a methyl group, provided that n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene](o-tolyl)acetonitrile and the like. Provided that n is 2, the acid generating agent represented by the above formula (a4) is specifically an acid generating agent represented by the following formulae.

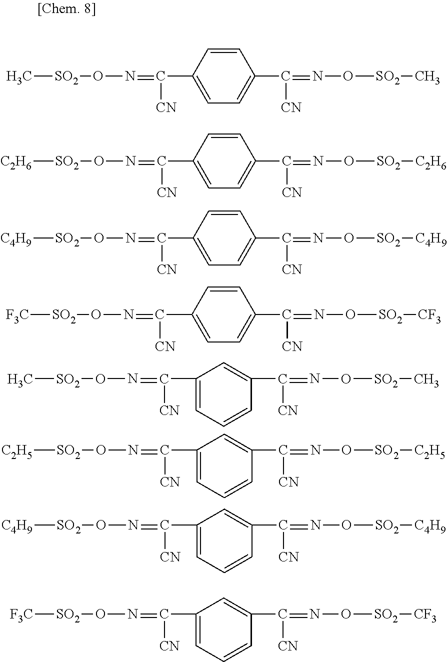

In addition, examples of the fourth aspect of the acid generating agent (A) may include onium salts having a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group, a linear or branched alkoxy group having 1 or more and 6 or less carbon atoms or the like. The structure derived from the naphthalene ring, which may be of a monovalent group (one free valance) or of a divalent group (two free valences), is desirably of a monovalent group (in this regard, the number of free valance is counted except for the portions connecting with the substituents described above). The number of naphthalene rings is preferably 1 or more and 3 or less.

Preferably, the cation moiety of the onium salt having a naphthalene ring at the cation moiety is of the structure represented by the following formula (a5).

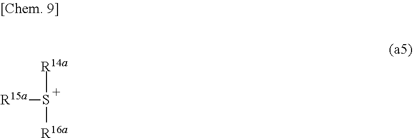

In the above formula (a5), at least one of R^{14a}, R^{15a} and R^{16a} represents a group represented by the following formula (a6), and the remaining represents a linear or branched alkyl group having 1 or more and 6 or less carbon atoms, a phenyl group optionally having a substituent, a hydroxyl group, or a linear or branched alkoxy group having 1 or more and 6 or less carbon atoms. Alternatively, one of R^{14a}, R^{15a} and R^{16a} is a group represented by the following formula (a6), and the remaining two are each independently a linear or branched alkylene group having 1 or more and 6 or less carbon atoms, and these terminals may bond to form a ring structure.

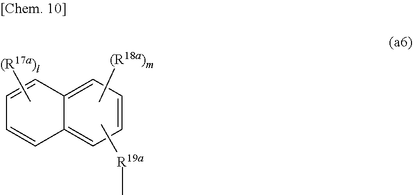

In the formula (a6), R^{17a} and R^{18a} each independently represent a hydroxyl group, a linear or branched alkoxy group having 1 or more and 6 or less carbon atoms, or a linear or branched alkyl group having 1 or more and 6 or less carbon atoms, and R^{19a} represents a single bond or a linear or branched alkylene group having 1 or more and 6 or less carbon atoms that may have a substituent. 1 and m each independently represent an integer of 0 or more and 2 or less, and 1+m is 3 or less. Herein, when there exists a plurality of R^{17a}, they may be identical to or different from each other. Furthermore, when there exists a plurality of R^{18a}, they may be identical to or different from each other.

Preferably, among R^{14a}, R^{15a} and R^{16a} as above, the number of groups represented by the above formula (a6) is one in view of the stability of the compound, and the remaining are linear or branched alkylene groups having 1 or more and 6 or less carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or more and 6 or less.

Examples of the substituent, which the alkylene group may have, include an oxygen atom (in this case, a carbonyl group is formed together with a carbon atom that constitutes the alkylene group), a hydroxyl group or the like.

Furthermore, examples of the substituent, which the phenyl group may have, include a hydroxyl group, a linear or branched alkoxy group having 1 or more and 6 or less carbon atoms, a linear or branched alkyl group having 1 or more and 6 or less carbon atoms, or the like.

Examples of suitable cations for the suitable cation moiety include cations represented by the following formulae (a7) and (a8), and the structure represented by the following formula (a8) is particularly preferable.

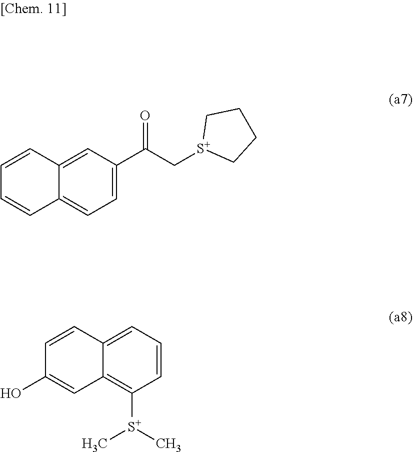 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in view of acid-producing efficiency.

It is, therefore, desirable that the suitable anions for the anion moiety of the onium salt having a naphthalene ring at the cation moiety is an anion capable of forming a sulfonium salt.

The anion moiety of the acid generating agent is exemplified by fluoroalkylsulfonic acid ions or aryl sulfonic acid ions, of which hydrogen atom(s) being partially or entirely fluorinated.

The alkyl group of the fluoroalkylsulfonic acid ions may be linear, branched or cyclic and have 1 or more and 20 or less carbon atoms. Preferably, the carbon number is 1 or more and 10 or less in view of bulkiness and diffusion distance of the produced acid. In particular, branched or cyclic alkyl groups are preferable due to shorter diffusion length. Also, methyl, ethyl, propyl, butyl, octyl groups and the like are preferable due to being inexpensively synthesizable.

The aryl group of the aryl sulfonic acid ions may be an aryl group having 6 or more and 20 or less carbon atoms, and is exemplified by a phenol group or a naphthyl group that may be unsubstituted or substituted with an alkyl group or a halogen atom. In particular, aryl groups having 6 or more and 10 or less carbon atoms are preferable due to being inexpensively synthesizable. Specific examples of preferable aryl group include phenyl, toluenesulfonyl, ethylphenyl, naphthyl, methylnaphthyl groups and the like.

When hydrogen atoms in the above fluoroalkylsulfonic acid ion or the aryl sulfonic acid ion are partially or entirely substituted with a fluorine atom, the fluorination rate is preferably 10% or more and 100% or less, and more preferably 50% or more and 100% or less; it is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among these, the preferable anion moiety is exemplified by those represented by the following formula (a9).

[Chem. 12]

R^{20a}SO₃⁻ (a9)

In the above formula (a9), R^{20a} represents groups represented by the following formulae (a10), (a11), and (a12).

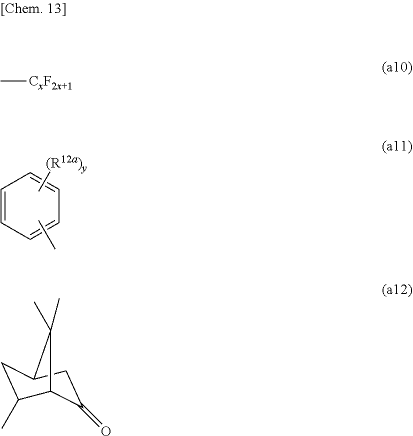

In the above formula (a10), x represents an integer of 1 or more and 4 or less. Also, in the above formula (a11), R^{21a} represents a hydrogen atom, a hydroxyl group, a linear or branched alkyl group having 1 or more and 6 or less carbon atoms, or a linear or branched alkoxy group having 1 or more and 6 or less carbon atoms, and y represents an integer of 1 or more and 3 or less. Of these, trifluoromethane sulfonate, and perfluorobutane sulfonate are preferable in view of safety.

In addition, a nitrogen-containing moiety represented by the following formulae (a13) and (a14) may also be used for the anion moiety.

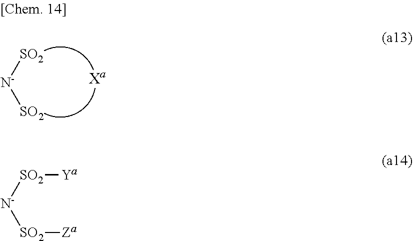

In the formulae (a13) and (a14), X^{a} represents a linear or branched alkylene group in which at least one hydrogen atom is substituted with a fluorine atom, the carbon number of the alkylene group is 2 or more and 6 or less, preferably 3 or more and 5 or less, and most preferably the carbon number is 3. In addition, Y^{a} and Z^{a} each independently represent a linear or branched alkyl group of which at least one hydrogen atom is substituted with a fluorine atom, the number of carbon atoms of the alkyl group is 1 or more and 10 or less, preferably 1 or more and 7 or less, and more preferably 1 or more and 3 or less.

The smaller number of carbon atoms in the alkylene group of X^{a}, or in the alkyl group of Y^{a} or Z^{a} is preferred since the solubility into organic solvent is favorable.

In addition, a larger number of hydrogen atoms each substituted with a fluorine atom in the alkylene group of X^{a}, or in the alkyl group of Y^{a} or Z^{a} is preferred since the acid strength becomes greater. The percentage of fluorine atoms in the alkylene group or alkyl group, i.e., the fluorination rate is preferably 70% or more and 100% or less and more preferably 90% or more and 100% or less, and most preferable are perfluoroalkylene or perfluoroalkyl groups in which all of the hydrogen atoms are each substituted with a fluorine atom.

Examples of preferable compounds for onium salts having a naphthalene ring at their cation moieties include compounds represented by the following formulae (a15) and (a16).

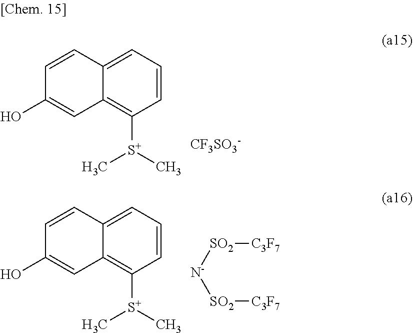

Also, examples of the fifth aspect of the acid generating agent (A) may include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-(trifluoromethylsulfonyloxy)phthalimide, N-(trifluoromethylsulfonyloxy)-1,8-naphthalimide and N-(trifluoromethylsulfonyloxy)-4-butyl-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates and the like.

This acid generating agent (A) may be used alone, or two or more types may be used in combination. Furthermore, the content of the acid generating agent (A) is adjusted to preferably 0.1% by mass or more and 10% by mass or less, more preferably 0.2% by mass or more and 6% by mass or less, and particularly preferably 0.5% by mass or more and 3% by mass or less, relative to the total mass of the solid component of the positive-type photosensitive composition. When the amount of the acid generating agent (A) used is adjusted to the range mentioned above, it is easy to prepare a positive-type photosensitive composition which is a uniform solution having satisfactory sensitivity and excellent storage stability.

### <Resin (B)>

The resin (B) having an alkali solubility that increases under action of an acid is not particularly limited, and any resin having an alkali solubility that increases under action of an acid can be used. Among them, it is preferable to contain at least one resin selected from the group consisting of a novolac resin (B1), a polyhydroxystyrene resin (B2), and an acrylic resin (B3).

### [Novolac Resin (B1)]

As the novolak resin (B1), a resin including the constituent unit represented by the following formula (b1) may be used.

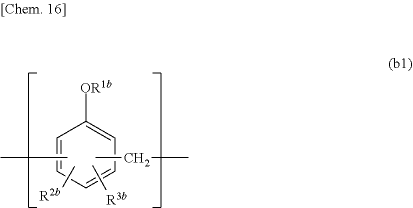

In the formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above R^{1b} is preferably a group represented by the following formula (b2) or (b3), a linear, branched or cyclic alkyl group having 1 or more and 6 or less carbon atoms, a vinyloxyethyl group, a tetrahydropyranyl group, a tetrahydrofuranyl group, or a trialkylsilyl group.

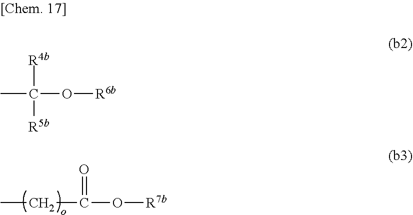

In the above formulae (b2) and (b3), R^{4b} and R^{5b} each independently represent a hydrogen atom, or a linear or branched alkyl group having 1 or more and 6 or less carbon atoms, R^{6b} represents a linear, branched or cyclic alkyl group having 1 or more and 10 or less carbon atoms, R^{7b} represents a linear, branched or cyclic alkyl group having 1 or more and 6 or less carbon atoms, and o represents 0 or 1.

Examples of the above linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Also, examples of the above cyclic alkyl group include a cyclopentyl group, a cyclohexyl group, and the like.

Specific examples of the acid-dissociable dissolution-inhibiting group represented by the above formula (b2) include a methoxyethyl group, an ethoxyethyl group, an n-propoxyethyl group, an isopropoxyethyl group, an n-butoxyethyl group, an isobutoxyethyl group, a tert-butoxyethyl group, a cyclohexyloxyethyl group, a methoxypropyl group, an ethoxypropyl group, a 1-methoxy-1-methyl-ethyl group, a 1-ethoxy-1-methylethyl group, and the like. Furthermore, specific examples of the acid-dissociable dissolution-inhibiting group represented by the above formula (b3) include a tert-butoxycarbonyl group, a tert-butoxycarbonylmethyl group, and the like. Examples of the above trialkylsilyl group include a trimethylsilyl group and a tri-tert-butyldimethylsilyl group in which each alkyl group has 1 or more and 6 or less carbon atoms.

### [Polyhydroxystyrene Resin (B2)]

As the polyhydroxystyrene resin (B2), a resin including a constituent unit represented by the following formula (b4) may be used.

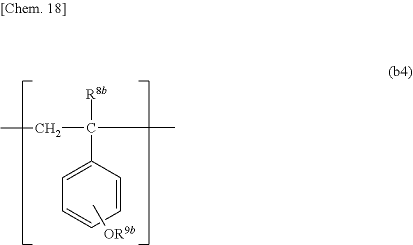

In the above formula (b4), R^{8b} represents a hydrogen atom or an alkyl group having 1 or more and 6 or less carbon atoms, and R^{9b} represents an acid-dissociable dissolution-inhibiting group.

The above alkyl group having 1 or more and 6 or less carbon atoms may include, for example, linear, branched or cyclic alkyl groups having 1 or more and 6 or less carbon atoms. Examples of the linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Examples of the cyclic alkyl group include a cyclopentyl group and a cyclohexyl group.

The acid-dissociable dissolution-inhibiting group represented by the above R^{9b} may be similar to those exemplified in terms of the above formulae (b2) and (b3).

Furthermore, the polyhydroxystyrene resin (B2) may include another polymerizable compound as a constituent unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl (meth)acrylate and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

### [Acrylic Resin (B3)]

An acrylic resin (B3) is not particularly limited as long as it is an acrylic resin having an alkali solubility that increases under action of an acid, and has conventionally been blended in various photosensitive compositions. Preferably, the acrylic resin (B3) contains a constituent unit (b-3) derived from, for example, an acrylic ester including an —SO₂-containing cyclic group or a lactone-containing cyclic group. In such a case, when a resist pattern is formed, a resist pattern having a preferable cross-sectional shape can be easily formed.

### (—SO₂-Containing Cyclic Group)

Herein, the “—SO₂-containing cyclic group” refers to a cyclic group having a cyclic group containing a ring including —SO₂— in the ring skeleton thereof, specifically a cyclic group in which the sulfur atom (S) in —SO₂— forms a part of the ring skeleton of the cyclic group. Considering a ring including —SO₂— in the ring skeleton thereof as the first ring, a group having that ring alone is called a monocyclic group, and a group further having another ring structure is called a polycyclic group regardless of its structure. The —SO₂-containing cyclic group may be monocyclic or polycyclic.

In particular, the —SO₂-containing cyclic group is preferably a cyclic group containing —O—SO₂— in the ring skeleton thereof, i.e., a cyclic group containing a sultone ring in which —O—S— in —O—SO₂— forms a part of the ring skeleton.

The number of carbon atoms in an —SO₂-containing cyclic group is preferably 3 or more and 30 or less, more preferably 4 or more and 20 or less, even more preferably 4 or more and 15 or less, and in particular preferably 4 or more and 12 or less. The above number of carbon atoms is the number of carbon atoms constituting a ring skeleton, and shall not include the number of carbon atoms in a substituent.

The —SO₂-containing cyclic group may be an —SO₂-containing aliphatic cyclic group or an —SO₂-containing aromatic cyclic group. It is preferably an —SO₂-containing aliphatic cyclic group.

—SO₂— containing aliphatic cyclic groups include a group in which at least one hydrogen atom is removed from an aliphatic hydrocarbon ring where a part of the carbon atoms constituting the ring skeleton thereof is(are) substituted with —SO₂— or —O—SO₂—. More specifically, they include a group in which at least one hydrogen atom is removed from an aliphatic hydrocarbon ring where —CH₂— constituting the ring skeleton thereof is substituted with —SO₂— and a group in which at least one hydrogen atom is removed from an aliphatic hydrocarbon ring where —CH₂—CH₂— constituting the ring thereof is substituted with —O—SO₂—.

The number of carbon atoms in the above alicyclic hydrocarbon ring is preferably 3 or more and 20 or less, more preferably 3 or more and 12 or less. The above alicyclic hydrocarbon ring may be polycyclic, or may be monocyclic. As the monocyclic alicyclic hydrocarbon group, preferred is a group in which two hydrogen atoms are removed from monocycloalkane having 3 or more and 6 or less carbon atoms. Examples of the above monocycloalkane can include cyclopentane, cyclohexane and the like. As the polycyclic alicyclic hydrocarbon ring, preferred is a group in which two hydrogen atoms are removed from polycycloalkane having 7 or more and 12 or less carbon atoms, and specific examples of the above polycycloalkane include adamantane, norbornane, isobornane, tricyclodecane, tetracyclododecane and the like.

The —SO₂-containing cyclic group may have a substituent. Examples of the above substituent include, for example, an alkyl group, an alkoxy group, a halogen atom, a halogenated alkyl group, a hydroxyl group, an oxygen atom (═O), —COOR″, —OC(═O)R″, a hydroxyalkyl group, a cyano group and the like.

For an alkyl group as the above substituent, preferred is an alkyl group having 1 or more and 6 or less carbon atoms. The above alkyl group is preferably linear or branched. Specific examples include a methyl group, an ethyl group, an n-propyl group, an isopropyl group, an n-butyl group, an isobutyl group, a tert-butyl group, an n-pentyl group, an isopentyl group, a neopentyl group, an n-hexyl group and the like. Among these, a methyl group or an ethyl group is preferred, and a methyl group is particularly preferred.

For an alkoxy group as the above substituent, preferred is an alkoxy group having 1 or more and 6 or less carbon atoms. The above alkoxy group is preferably linear or branched. Specific examples include a group in which an alkyl groups recited as an alkyl group for the above substituent is attached to the oxygen atom (—O—).

Halogen atoms as the above substituent include a fluorine atom, a chlorine atom, a bromine atom, an iodine atom and the like, and a fluorine atom is preferred.

Halogenated alkyl groups for the above substituent include a group in which a part or all of the hydrogen atoms in the above alkyl group is(are) substituted with the above halogen atom(s).

Halogenated alkyl groups as the above substituent include a group in which a part or all of the hydrogen atoms in the alkyl groups recited as an alkyl group for the above substituent is(are) substituted with the above halogen atom(s). As the above halogenated alkyl group, a fluorinated alkyl group is preferred, and a perfluoroalkyl group is particularly preferred.

R″s in the aforementioned —COOR″ and —OC(═O)R″ are either a hydrogen atom or a linear, branched or cyclic alkyl group having 1 or more and 15 or less carbon atoms.

In a case where R″ is a linear or branched alkyl group, the number of carbon atoms in the above chain alkyl group is preferably 1 or more and 10 or less, more preferably 1 or more and 5 or less, and in particular preferably 1 or 2.

In a case where R″ is a cyclic alkyl group, the number of carbon atoms in the above cyclic alkyl group is preferably 3 or more and 15 or less, more preferably 4 or more and 12 or less, and in particular preferably 5 or more and 10 or less. Specific examples can include a group in which one or more hydrogen atoms are removed from monocycloalkane; and polycycloalkane such as bicycloalkane, tricycloalkane, tetracycloalkane and the like optionally substituted with a fluorine atom or a fluorinated alkyl group. More specific examples include a group in which one or more hydrogen atoms are removed from monocycloalkane such as cyclopentane and cyclohexane; and polycycloalkane such as adamantane, norbornane, isobornane, tricyclodecane and tetracyclododecane.

For a hydroxyalkyl group as the above substituent, preferred is a hydroxyalkyl group having 1 or more and 6 or less carbon atoms. Specific examples include a group in which at least one of the hydrogen atoms in the alkyl groups recited as an alkyl group for the above substituent is substituted with a hydroxyl group.

More specific examples of the —SO₂-containing cyclic group include the groups represented by the following formulae (3-1) to (3-4).

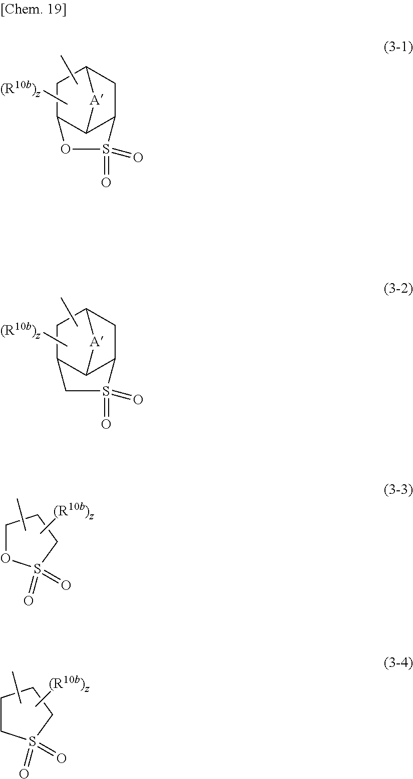

(In the formulae, A′ represents an alkylene group having 1 or more and 5 or less carbon atoms optionally including an oxygen atom or a sulfur atom, an oxygen atom or a sulfur atom; z represents an integer of 0 or more and 2 or less; R^{10b} represents an alkyl group, an alkoxy group, a halogenated alkyl group, a hydroxyl group, —COOR″, —OC(═O)R″, a hydroxyalkyl group, or a cyano group; and R″ represents a hydrogen atom or an alkyl group.)

In the above formulae (3-1) to (3-4), A′ represents an alkylene group having 1 or more and 5 or less carbon atoms optionally including an oxygen atom (—O—) or a sulfur atom (—S—), an oxygen atom or a sulfur atom. As an alkylene group having 1 or more and 5 or less carbon atoms in A′, a linear or branched alkylene group is preferred, and examples thereof include a methylene group, an ethylene group, an n-propylene group, an isopropylene group and the like.

In a case where the above alkylene group includes an oxygen atom or a sulfur atom, specific examples thereof include a group in which —O— or —S— is present at a terminal or between carbon atoms of the above alkylene group, for example, —O—CH₂—, —CH₂—O—CH₂—, —S—CH₂—, —CH₂—S—CH₂—, and the like. As A′, an alkylene group having 1 or more and 5 or less carbon atoms or —O— is preferred, and an alkylene group having 1 or more and 5 or less carbon atoms is more preferred, and a methylene group is most preferred.

z may be any of 0, 1, and 2, and is most preferably 0. In a case where z is 2, a plurality of R^{10b} may be the same, or may differ from each other.

An alkyl group, —COOR″, —OC(═O)R″ and a hydroxyalkyl group in R^{10b} include those similar to the groups described above for the alkyl group, the alkoxy group, the halogenated alkyl group, —COOR″, —OC(═O)R″ and the hydroxyalkyl group, respectively, which are recited as those optionally contained in the —SO₂-containing cyclic group.

Below, specific cyclic groups represented by the above formulae (3-1) to (3-4) will be illustrated. Note here that “Ac” in the formulae represents an acetyl group.

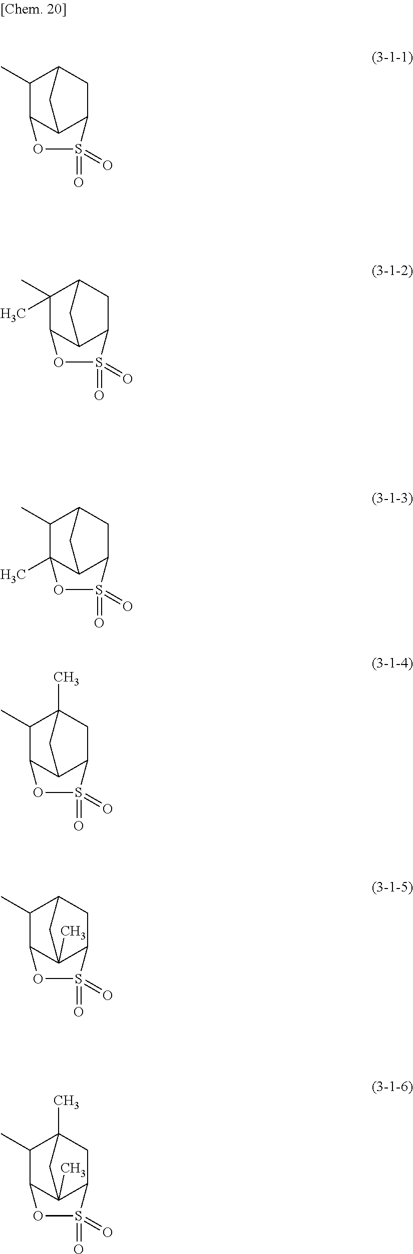

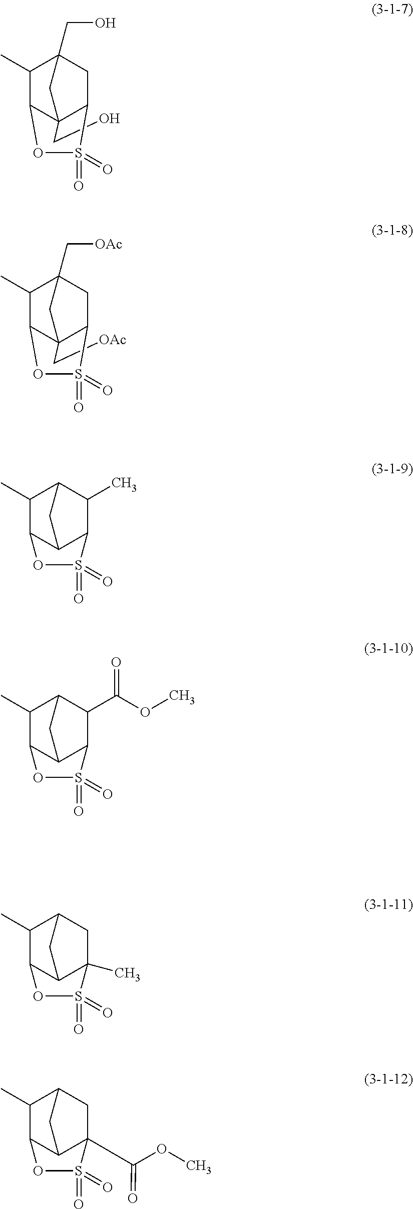

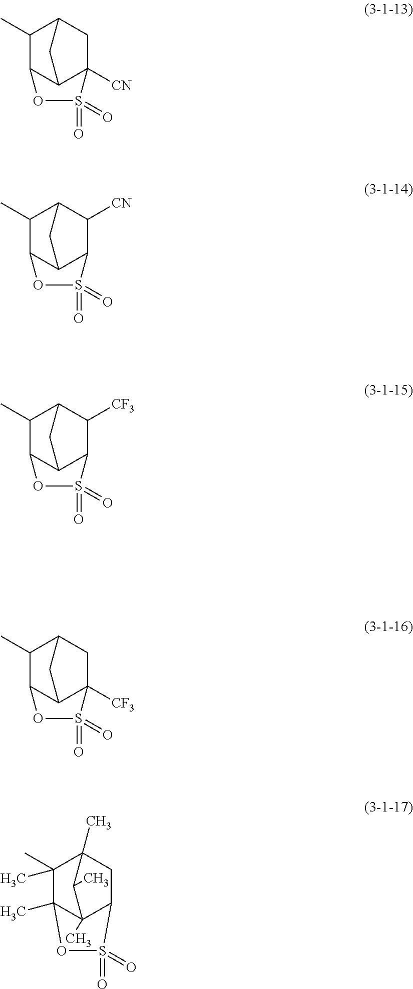 [SMILES: CC1C2CC3C1OS(=O)(=O)C3(C#N)C2 ; CC1C2CC3C1OS(=O)(=O)C3C2C#N ; CC1C2CC3C1OS(=O)(=O)C3C2C(F)(F)F ; CC1C2CC3C1OS(=O)(=O)C3(C(F)(F)F)C2 ; CC1C2(C)CC3C1(C)C(C)(OS3(=O)=O)C2(C)C]

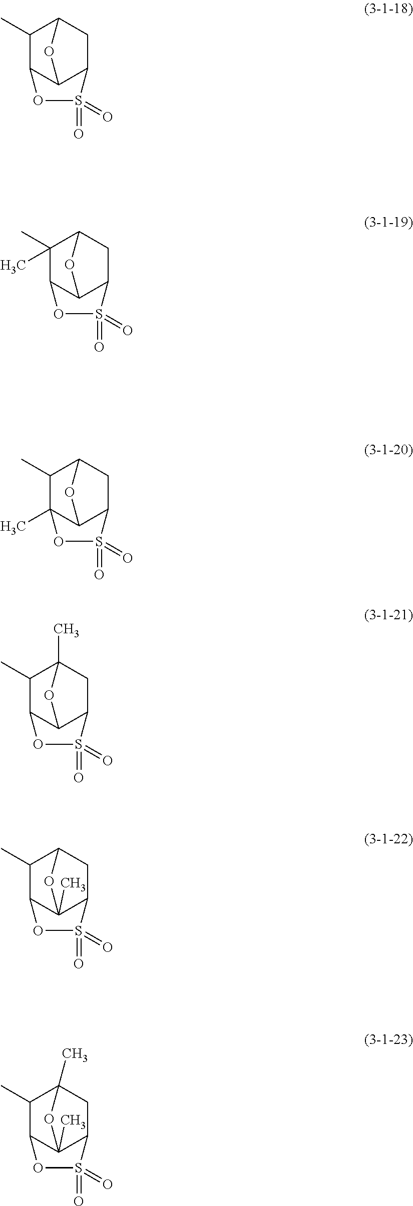

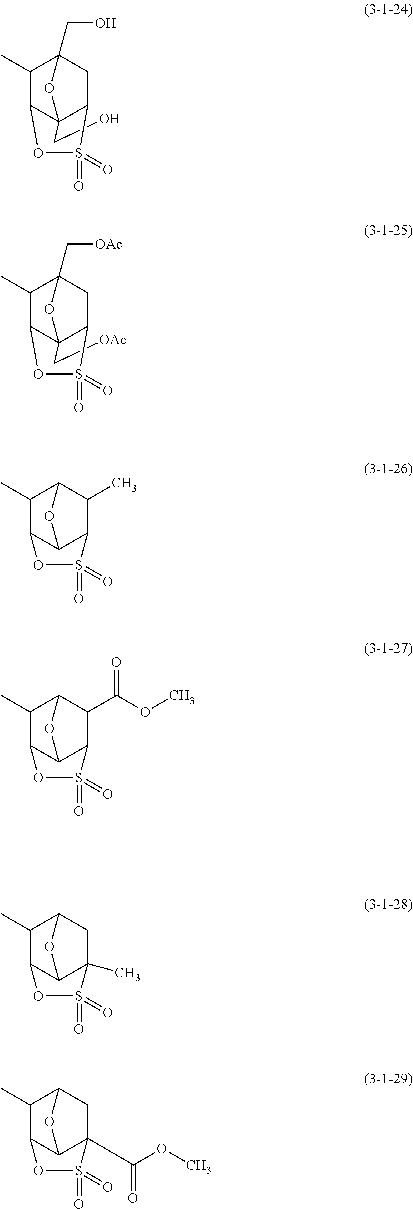

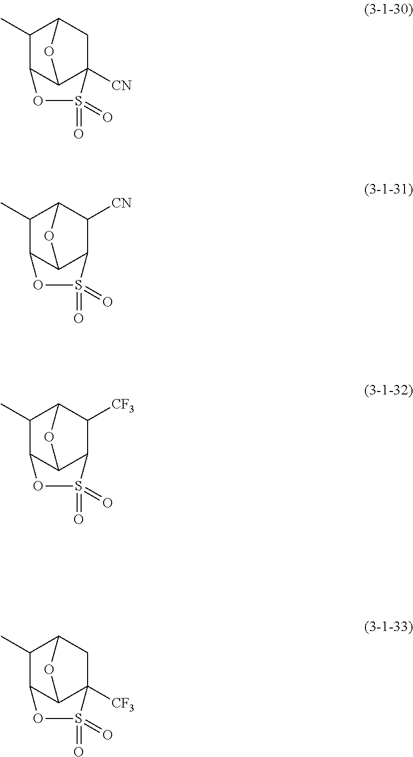 [SMILES: CC1C2CC3(C#N)C(O2)C1OS3(=O)=O ; CC1C2OC3C1OS(=O)(=O)C3C2C#N ; CC1C2OS(=O)(=O)C3C2OC1C3C(F)(F)F ; CC1C2CC3(C(F)(F)F)C(O2)C1OS3(=O)=O]

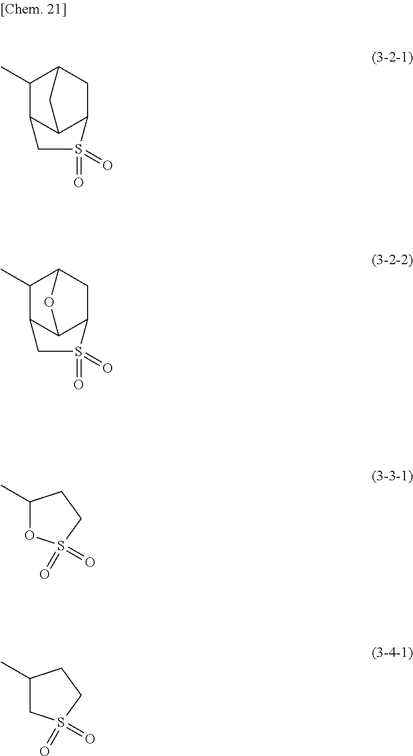

As the —SO₂-containing cyclic group, among those shown above, a group represented by the above formula (3-1) is preferred, and at least one selected from the group consisting of the groups represented by any of the aforementioned formulae (3-1-1), (3-1-18), (3-3-1) and (3-4-1) is more preferred, and a group represented by the aforementioned formula (3-1-1) is most preferred.

### (Lactone-Containing Cyclic Group)

The “lactone-containing cyclic group” refers to a cyclic group containing a ring (lactone ring) including —O—C(═O)— in the ring skeleton thereof. Considering the lactone ring as the first ring, a group having that lactone ring alone is called a monocyclic group, and a group further having another ring structure is called a polycyclic group regardless of its structure. The lactone-containing cyclic group may be a monocyclic group, or may be a polycyclic group.

There is no particular limitation on the lactone cyclic group in the constituent unit (b-3), and any cyclic group can be used. Specifically, examples of the lactone-containing monocyclic groups include a group in which one hydrogen atom is removed from 4 to 6 membered ring lactone, for example, a group in which one hydrogen atom is removed from β-propiono lactone, a group in which one hydrogen atom is removed from γ-butyrolactone, a group in which one hydrogen atom is removed from δ-valerolactone and the like. Further, lactone-containing polycyclic groups include a group in which one hydrogen atom is removed from bicycloalkane, tricycloalkane and tetracycloalkane having a lactone ring.

As to the constituent unit (b-3), as long as the constituent unit (b-3) has an —SO₂-containing cyclic group or a lactone-containing cyclic group, the structures of other parts are not particularly limited. A preferred constituent unit (b-3) is at least one constituent unit selected from the group consisting of a constituent unit (b-3-S) derived from an acrylic acid ester including an —SO₂-containing cyclic group in which a hydrogen atom attached to the carbon atom in the α position may be substituted with a substituent; and a constituent unit (b-3-L) derived from an acrylic acid ester including a lactone-containing cyclic group in which the hydrogen atom attached to the carbon atom in the α position may be substituted with a substituent.

[Constituent Unit (b-3-S)]

More specifically, examples of the constituent unit (b-3-S) include one represented by the following formula (b-S1).

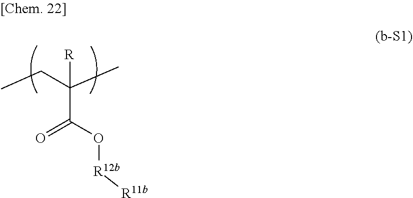

(In the formula, R represents a hydrogen atom, an alkyl group having 1 or more 5 or less carbon atoms or a halogenated alkyl group having 1 or more 5 or less carbon atoms; and R^{11b} represents an —SO₂-containing cyclic group; and R^{12b} represents a single-bond or divalent linking group.)

In the formula (b-S1), R is similarly defined as above. R^{11b} is similarly defined as in the —SO₂-containing cyclic group described above. R^{12b} may be either a single-bond linking group or a divalent linking group.

There is no particular limitation on the divalent linking group in R^{12b}, and suitable groups include an optionally substituted divalent hydrocarbon group, a divalent linking group including a heteroatom, and the like.

### - Optionally Substituted Divalent Hydrocarbon Group

The hydrocarbon group as a divalent linking group may be an aliphatic hydrocarbon group, or may be an aromatic hydrocarbon group. The aliphatic hydrocarbon group means a hydrocarbon group without aromaticity. The above aliphatic hydrocarbon group may be saturated or may be unsaturated. Usually, a saturated hydrocarbon group is preferred. More specifically, examples of the above aliphatic hydrocarbon group include a linear or branched aliphatic hydrocarbon group, an aliphatic hydrocarbon group including a ring in the structure thereof and the like.

The number of carbon atoms in the linear or branched aliphatic hydrocarbon group is preferably 1 or more and 10 or less, more preferably 1 or more and 8 or less, and even more preferably 1 or more and 5 or less.

As the linear aliphatic hydrocarbon group, a linear alkylene group is preferred. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like.

As the branched aliphatic hydrocarbon group, a branched alkylene group is preferred. Specific examples include alkyl alkylene groups such as alkyl methylene groups such as —CH(CH₃)—, —CH(CH₂CH₃)—, —C(CH₃)₂—, —C(CH₃) (CH₂CH₃)—, —C(CH₃)(CH₂CH₂CH₃)— and —C(CH₂CH₃)₂—; alkyl ethylene groups such as —CH(CH₃) CH₂—, —CH(CH₃) CH(CH₃)—, —C(CH₃)₂CH₂—, —CH(CH₂CH₃) CH₂— and —C(CH₂CH₃)₂—CH₂—; alkyl trimethylene groups such as —CH(CH₃) CH₂CH₂— and —CH₂CH(CH₃) CH₂—; alkyl tetramethylene groups such as —CH(CH₃)CH₂CH₂CH₂— and —CH₂CH(CH₃)CH₂CH₂—; and the like. As an alkyl group in the alkyl alkylene group, a linear alkyl group having 1 or more and 5 or less carbon atoms is preferred.

The above linear or branched aliphatic hydrocarbon group may or may not have a substituent (a group or atom other than a hydrogen atom) which substitutes a hydrogen atom. Examples of the substituent include a fluorine atom, a fluorinated alkyl group having 1 or more and 5 or less carbon atoms substituted with a fluorine atom, an oxo group (═O) and the like.

Examples of the above aliphatic hydrocarbon group including a ring in the structure thereof include a cyclic aliphatic hydrocarbon group optionally including a hetero atom in the ring structure (a group in which two hydrogen atoms are removed from an aliphatic hydrocarbon ring); a group in which the above cyclic aliphatic hydrocarbon group is attached to an end of a linear or branched aliphatic hydrocarbon group; a group in which the above cyclic aliphatic hydrocarbon group is present in a linear or branched aliphatic hydrocarbon group along the chain; and the like. Examples of the above linear or branched aliphatic hydrocarbon group include those similar to the above.

The number of carbon atoms in the cyclic aliphatic hydrocarbon group is preferably 3 or more and 20 or less, and more preferably 3 or more and 12 or less.

The cyclic aliphatic hydrocarbon group may be polycyclic, or may be monocyclic. As the monocyclic aliphatic hydrocarbon group, a group in which two hydrogen atoms are removed from monocycloalkane is preferred. The number of carbon atoms in the above monocycloalkane is preferably 3 or more and 6 or less. Specific examples include cyclopentane, cyclohexane and the like. As the polycyclic aliphatic hydrocarbon group, a group in which two hydrogen atoms are removed from polycycloalkane is preferred. The number of carbon atoms in the above polycycloalkane is preferably 7 or more and 12 or less. Specific examples include adamantane, norbornane, isobornane, tricyclodecane, tetracyclododecane and the like.

The cyclic aliphatic hydrocarbon group may or may not have a substituent which substitutes a hydrogen atom (a group or atom other than a hydrogen atom). Examples of the above substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and a methyl group, an ethyl group, a propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are more preferred, and a methoxy group and an ethoxy group are particularly preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

In the cyclic aliphatic hydrocarbon group, a part of carbon atoms constituting the ring structure thereof may be substituted with —O—, or —S—. As the substituent including the above hetero atom, preferred are —O—, —C(═O)—O—, —S—, —S(═O)₂— and —S(═O)₂—O—.

The aromatic hydrocarbon group as the divalent hydrocarbon group is a divalent hydrocarbon group having at least one aromatic ring, and may have a substituent. There is no particular limitation on the aromatic ring as long as it is a cyclic conjugated system having a 4n+2 π electrons, and it may be monocyclic or may be polycyclic. The number of carbon atoms in the aromatic ring is preferably 5 or more and 30 or less, more preferably 5 or more and 20 or less, further more preferably 6 or more and 15 or less, and particularly preferably 6 or more and 12 or less. However, the number of carbon atoms in a substituent shall not be included in the above number of carbon atoms.

Specifically, aromatic rings include aromatic hydrocarbon rings such as benzene, naphthalene, anthracene and phenanthrene; aromatic heterocycles in which a part of the carbon atoms constituting the above aromatic hydrocarbon ring is(are) substituted with hetero atom(s). Hetero atoms in the aromatic heterocycle include an oxygen atom, a sulfur atom, a nitrogen atom and the like. Specifically, aromatic heterocycles include a pyridine ring, a thiophene ring, and the like.

Specific examples of the aromatic hydrocarbon group as a divalent hydrocarbon group include a group in which two hydrogen atoms are removed from the above aromatic hydrocarbon ring or the above aromatic heterocycle (an arylene group or a heteroarylene group); a group in which two hydrogen atoms are removed from an aromatic compound including two or more aromatic rings (for example, biphenyl, fluorene and the like); a group in which one hydrogen atom from a group where one hydrogen atom is removed from the above aromatic hydrocarbon ring or the above aromatic heterocycle (an aryl group or a heteroaryl group) is substituted with an alkylene group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group and a 2-naphthylethyl group); and the like.

The number of carbon atoms in the above alkylene group bonded to an aryl group or a heteroaryl group is preferably 1 or more and 4 or less, more preferably 1 or more and 2 or less, and particularly preferably 1.

In the above aromatic hydrocarbon group, a hydrogen atom of the above aromatic hydrocarbon group may be substituted with a substituent. For example, a hydrogen atom attached to an aromatic ring in the above aromatic hydrocarbon group may be substituted with a substituent. Examples of the substituent include an alkyl group, an alkoxy group, a halogen atom, a halogenated alkyl group, a hydroxyl group, an oxo group (═O) and the like.

For an alkyl group as the above substituent, an alkyl group having 1 or more and 5 or less carbon atoms is preferred, and a methyl group, an ethyl group, an n-propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are preferred, and a methoxy group and an ethoxy group are more preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

### - Divalent Linking Group Including Hetero Atom

A hetero atom in the divalent linking group including a hetero atom is an atom other than a carbon atom and a hydrogen atom, and examples thereof include an oxygen atom, a nitrogen atom, a sulfur atom, a halogen atom and the like.

Specific examples of the divalent linking group including a hetero atom include non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N—, and combinations of at least one of these non-hydrocarbon based linking groups and a divalent hydrocarbon group and the like. Examples of the above divalent hydrocarbon group include those similar to the aforementioned divalent hydrocarbon groups optionally having a substituent, and linear or branched aliphatic hydrocarbon groups are preferred.

Among those described above, —NH— in —C(═O)—NH—, and H in —NH— and —NH—C(═NH)— may be substituted with a substituent such as an alkyl group or an acyl group, respectively. The number of carbon atoms in the above substituent is preferably 1 or more and 10 or less, more preferably 1 or more and 8 or less, and in particular preferably 1 or more and 5 or less.

As a divalent linking group in R^{12b}, a linear or branched alkylene group, a cyclic aliphatic hydrocarbon group, or a divalent linking group including a hetero atom is preferred.

In a case where the divalent linking group in R^{12b} is a linear or branched alkylene group, the number of carbon atoms in the above alkylene group is preferably 1 or more and 10 or less, more preferably 1 or more and 6 or less, in particular preferably 1 or more and 4 or less, and most preferably 1 or more and 3 or less. Specific examples include groups similar to the linear alkylene groups or branched alkylene groups recited as a linear and branched aliphatic hydrocarbon group in the description of the “divalent hydrocarbon group optionally having a substituent” as the aforementioned divalent linking group.

In a case where the divalent linking group in R^{12b} is a cyclic aliphatic hydrocarbon group, examples of the above cyclic aliphatic hydrocarbon group include groups similar to those recited as the “aliphatic hydrocarbon group including a ring in the structure” in the description of the “divalent hydrocarbon group optionally having a substituent” as the aforementioned divalent linking group.

As the above cyclic aliphatic hydrocarbon group, particularly preferred is a group in which two or more hydrogen atoms are removed from cyclopentane, cyclohexane, norbornane, isobornane, adamantane, tricyclodecane or tetracyclododecane.

In a case where the divalent linking group in R^{12b} is a divalent linking group including a hetero atom, groups preferred as the above linking groups include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O— and a group represented by the general formula —Y¹—O—Y²—, — [Y¹—C(═O)—O]_{m′}—Y²— or —Y¹—O—C(═O)—Y₂—[wherein Y¹ and Y² are divalent hydrocarbon groups each independently, optionally having a substituent, and O represents an oxygen atom, and m′ is an integer of 0 or more and 3 or less].

In a case where the divalent linking group in R^{12b} is —NH—, the hydrogen atom in —NH— may be substituted with a substituent such as an alkyl group or an acyl group. The number of carbon atoms in the above substituent (an alkyl group, an acyl group and the like) is preferably 1 or more and 10 or less, more preferably 1 or more and 8 or less, and in particular preferably 1 or more and 5 or less. Y¹ and Y² in the formula Y¹—O—Y²—, —[Y¹—C(═O)—O]_{n′}—Y²— or —Y¹—O—C(═O)—Y²— are divalent hydrocarbon groups each independently, optionally having a substituent. Examples of the above divalent hydrocarbon group include groups similar to the “divalent hydrocarbon group optionally having a substituent” recited in the description of the above divalent linking group.

As Y¹, a linear aliphatic hydrocarbon group is preferred, and a linear alkylene group is more preferred, and a linear alkylene group having 1 or more and 5 or less carbon atoms is more preferred, and a methylene group and an ethylene group are particularly preferred.

As Y², a linear or branched aliphatic hydrocarbon group is preferred, and a methylene group, an ethylene group and an alkylmethylene group are more preferred. The alkyl group in the above alkylmethylene group is preferably a linear alkyl group having 1 or more and 5 or less carbon atoms, more preferably a linear alkyl group having 1 or more and 3 or less carbon atoms, and particularly preferably a methyl group.

In a group represented by the formula —[Y¹—C(═O)—O]_{m′}—Y²—, m′ is an integer of 0 or more and 3 or less, preferably an integer of 0 or more and 2 or less, more preferably 0 or 1, and particularly preferably 1. In other words, as a group represented by the formula —[Y¹—C(═O)—O]_{n′}—Y²—, a group represented by the formula —Y¹—C(═O)—O—Y²— is particularly preferred. Among these, a group represented by the formula —(CH₂)_{a′}—C(═O)—O—(CH₂)_{b′}— is preferred. In the above formula, a′ is an integer of 1 or more and 10 or less, preferably an integer of 1 or more and 8 or less, more preferably an integer of 1 or more and 5 or less, even more preferably 1 or 2, and most preferably 1. b′ is an integer of 1 or more and 10 or less, preferably an integer of 1 or more and 8 or less, more preferably an integer of 1 or more and 5 or less, even more preferably 1 or 2, and most preferably 1.

With regard to the divalent linking group in R^{12b}, an organic group including a combination of at least one non-hydrocarbon group and a divalent hydrocarbon group is preferred as the divalent linking group including a hetero atom. Among these, a linear chain group having an oxygen atom as a hetero atom, for example, a group including an ether bond or an ester bond is preferred, and a group represented by the aforementioned formula —Y¹—O—Y²—, —[Y¹—C(═O)—O]_{m′}—Y²— or —Y¹—O—C(═O)—Y²— is more preferred, and a group represented by the aforementioned formula —[Y¹—C(═O)—O]_{m′}—Y²— or —Y¹—O—C(═O)—Y²— is particularly preferred.

As the divalent linking group in R^{12b}, a group including an alkylene group or an ester bond (—C(═O)—O—) is preferred.

The above alkylene group is preferably a linear or branched alkylene group. Suitable examples of the above linear aliphatic hydrocarbon group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like. Suitable examples of the above branched alkylene group include alkyl alkylene groups such as alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃)CH₂CH₂—.

As the divalent linking group including an ester bond, particularly preferred is a group represented by the formula: —R^{13b}—C(═O)—O— [wherein R^{13b} represents a divalent linking group]. In other words, the constituent unit (b-3-S) is preferably a constituent unit represented by the following formula (b-S1-1).

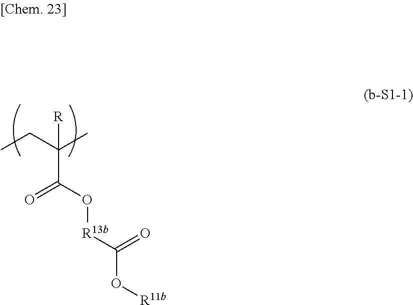

(In the formula, R and R^{11b} are each similar to the above, and R^{13b} represents a divalent linking group.)

There is no particular limitation for R^{13b}, examples thereof include groups similar to the aforementioned divalent linking group in R^{12b}. As the divalent linking group in R^{13b}, a linear or branched alkylene group, an aliphatic hydrocarbon group including a ring in the structure, or a divalent linking group including a hetero atom is preferred, and a linear or branched alkylene group or a divalent linking group including an oxygen atom as a hetero atom is preferred.

As the linear alkylene group, a methylene group or an ethylene group is preferred, and a methylene group is particularly preferred. As the branched alkylene group, an alkylmethylene group or an alkylethylene group is preferred, and —CH(CH₃)—, —C(CH₃)₂— or —C(CH₃)₂CH₂— is particularly preferred.

As the divalent linking group including an oxygen atom, a divalent linking group including an ether bond or an ester bond is preferred, and the aforementioned —Y¹—O—Y²—, —[Y¹—C(═O)—O]_{m′}—Y²— or —Y¹—O—C(═O)—Y²— is more preferred. Y¹ and Y² are each independently divalent hydrocarbon groups optionally having a substituent, and m′ is an integer of 0 or more and 3 or less. Among these, —Y¹—O—C(═O)—Y²— is preferred, and a group represented by —(CH₂)_{c}—O—C(═O)—(CH₂)_{d}— is particularly preferred. c is an integer of 1 or more and 5 or less, and 1 or 2 is preferred. d is an integer of 1 or more and 5 or less, and 1 or 2 is preferred.

As the constituent unit (b-3-S), in particular, one represented by the following formula (b-S1-11) or (b-S1-12) is preferred, and one represented by the formula (b-S1-12) is more preferred.

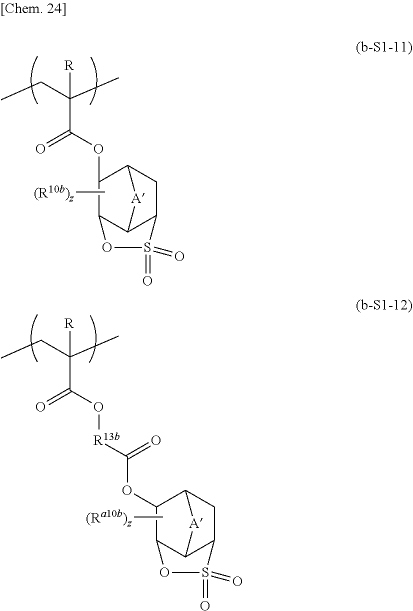

(In the formulae, R, A′, R^{10b}, z and R^{13b} are each the same as the above.)

In the formula (b-S1-11), A′ is preferably a methylene group, an oxygen atom (—O—) or a sulfur atom (—S—).

As R^{13b}, preferred is a linear or branched alkylene group or a divalent linking group including an oxygen atom. Examples of the linear or branched alkylene group and the divalent linking group including an oxygen atom in R^{13b} include those similar to the aforementioned linear or branched alkylene group and the aforementioned divalent linking group including an oxygen atom, respectively.

As the constituent unit represented by the formula (b-S1-12), particularly preferred is one represented by the following formula (b-S1-12a) or (b-S1-12b).

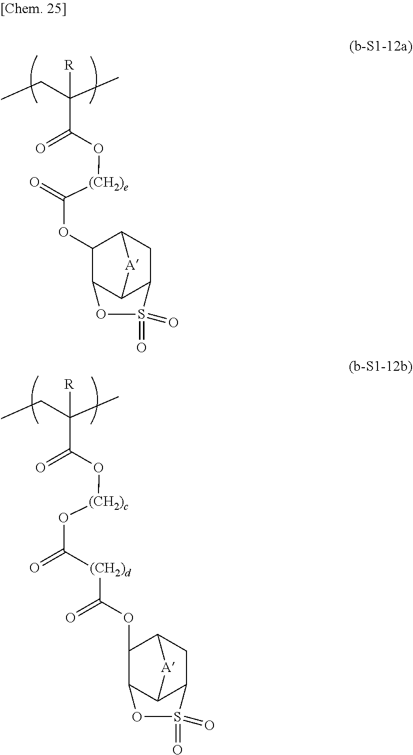

(In the formulae, R and A′ are each the same as the above, and c to e are each independently an integer of 1 or more and 3 or less.)
[Constituent Unit (b-3-L)]

Examples of the constituent unit (b-3-L) include, for example, a constituent unit in which R^{11b} in the aforementioned formula (b-S1) is substituted with a lactone-containing cyclic group. More specifically they include those represented by the following formulae (b-L1) to (b-L5).

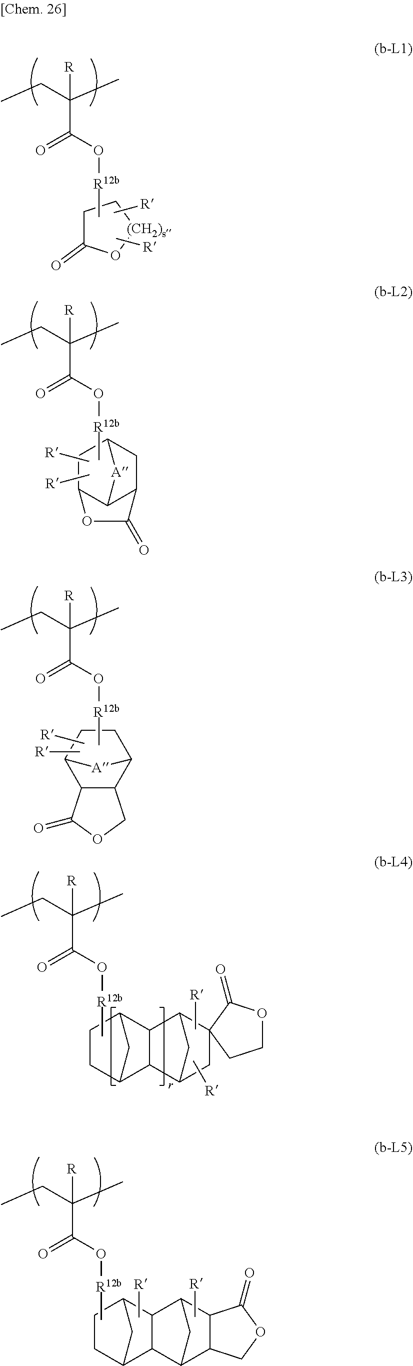

(In the formulae, R represents a hydrogen atom, an alkyl group having 1 or more and 5 or less carbon atoms or a halogenated alkyl group having 1 or more and 5 or less carbon atoms; R′ represents each independently a hydrogen atom, an alkyl group, an alkoxy group, a halogenated alkyl group, a hydroxyl group, —COOR″, —OC(═O)R″, a hydroxyalkyl group or a cyano group, and R″ represents a hydrogen atom or an alkyl group; R^{12b} represents a single bond or divalent linking group, and s″ is an integer of 0 or more and 2 or less; A″ represets an alkylene group having 1 or more and 5 or less carbon atoms optionally including an oxygen atom or a sulfur atom, an oxygen atom or a sulfur atom; and r is 0 or 1.)

R in the formulae (b-L1) to (b-L5) is the same as the above. Examples of the alkyl group, the alkoxy group, the halogenated alkyl group, —COOR″, —OC(═O)R″ and the hydroxyalkyl group in R′ include groups similar to those described for the alkyl group, the alkoxy group, the halogenated alkyl group, —COOR″, —OC(═O)R″ and the hydroxyalkyl group recited as a substituent which the —SO₂-containing cyclic group may have, respectively.

R′ is preferably a hydrogen atom in view of easy industrial availability and the like. The alkyl group in R″ may be any of a linear, branched or cyclic chain. In a case where R″ is a linear or branched alkyl group, the number of carbon atoms is preferably 1 or more and 10 or less, and more preferably 1 or more and 5 or less. In a case where R″ is a cyclic alkyl group, the number of carbon atoms is preferably 3 or more and 15 or less, more preferably 4 or more and 12 or less, and most preferably 5 or more and 10 or less. Specific examples include a group in which one or more hydrogen atoms are removed from monocycloalkane and polycycloalkane such as bicycloalkane, tricycloalkane, tetracycloalkane and the like optionally substituted with a fluorine atom or a fluorinated alkyl group. Specific examples include a group in which one or more hydrogen atoms are removed from monocycloalkane such as cyclopentane and cyclohexane; and polycycloalkane such as adamantane, norbornane, isobornane, tricyclodecane and tetracyclododecane; and the like. Examples of A″ include groups similar to A′ in the aforementioned formula (3-1). A″ is preferably an alkylene group having 1 to 5 carbon atoms, an oxygen atom (—O—) or a sulfur atom (—S—), more preferably an alkylene group having 1 or more and 5 or less carbon atoms or —O—. As the alkylene group having 1 or more and 5 or less carbon atoms, a methylene group or a dimethylmethylene group is more preferred, and a methylene group is most preferred.

R^{12b} is similar to R^{12b} in the aforementioned formula (b-S1). In the formula (b-L1), s″ is preferably 1 or 2. Below, specific examples of the constituent units represented by the aforementioned formulae (b-L1) to (b-L3) will be illustrated. In each of the following formulae, Ra represents a hydrogen atom, a methyl group or a trifluoromethyl group.

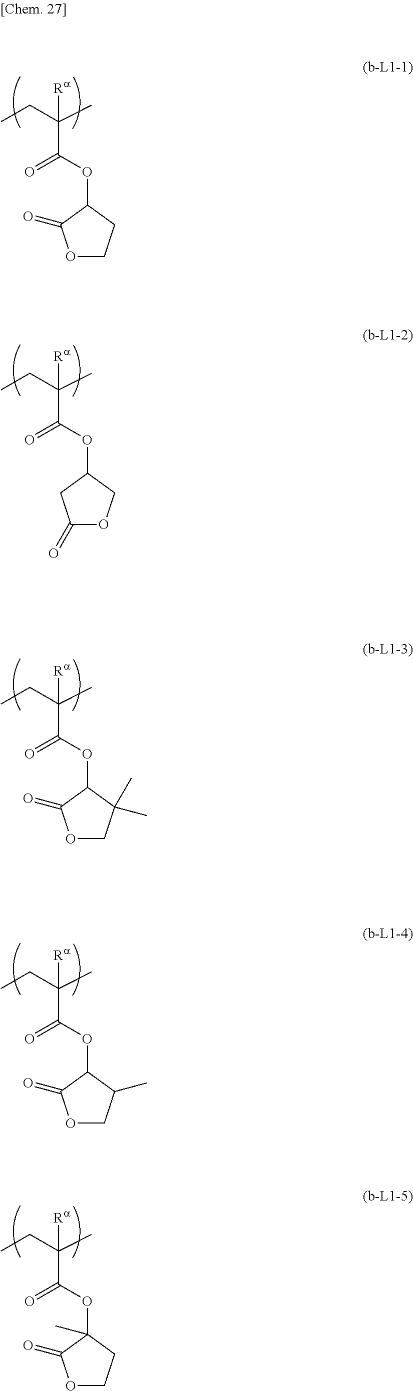

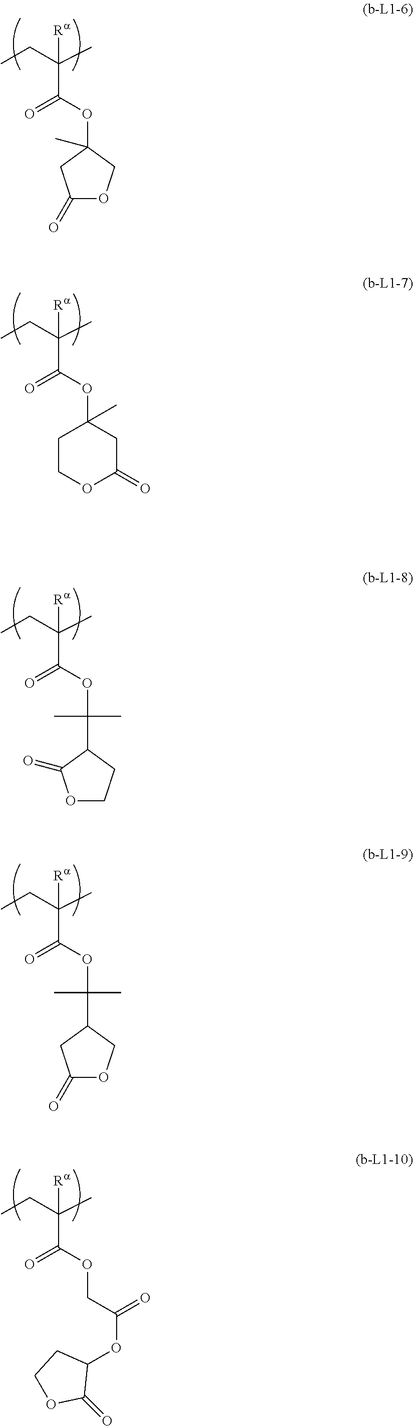

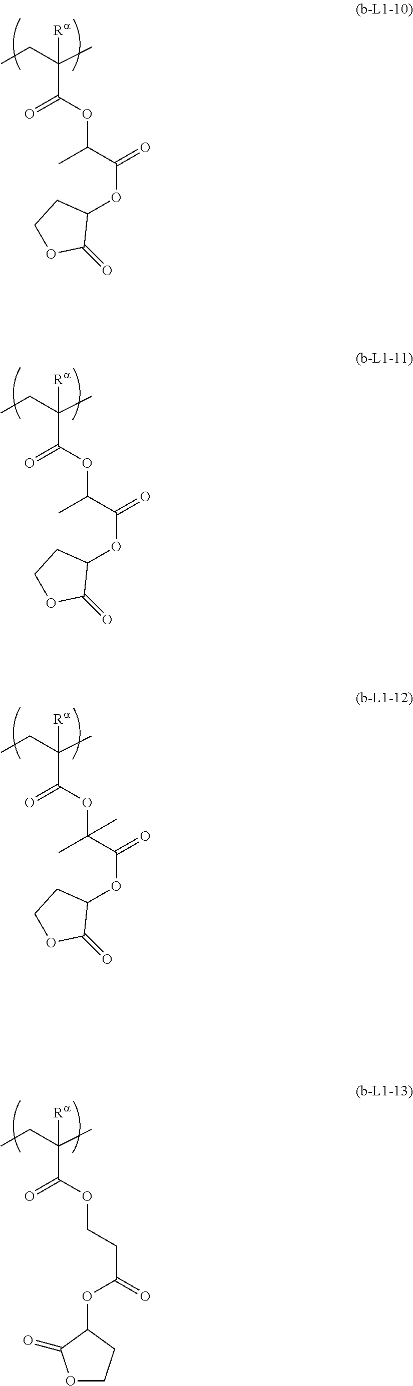

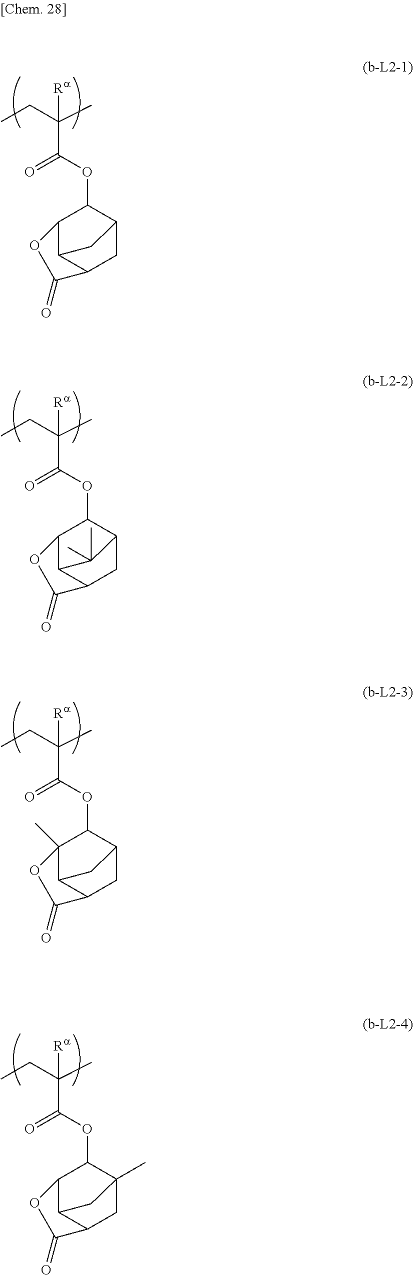

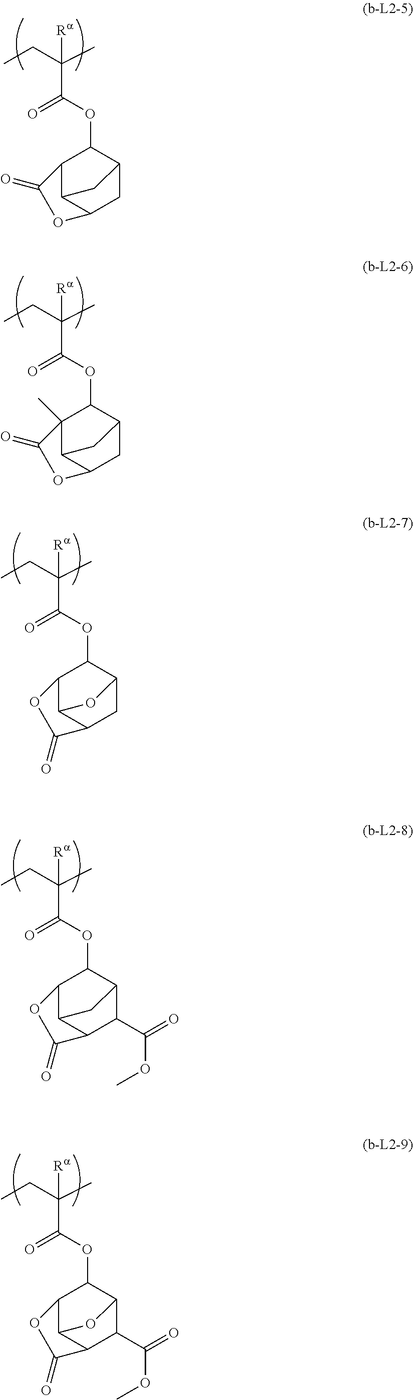

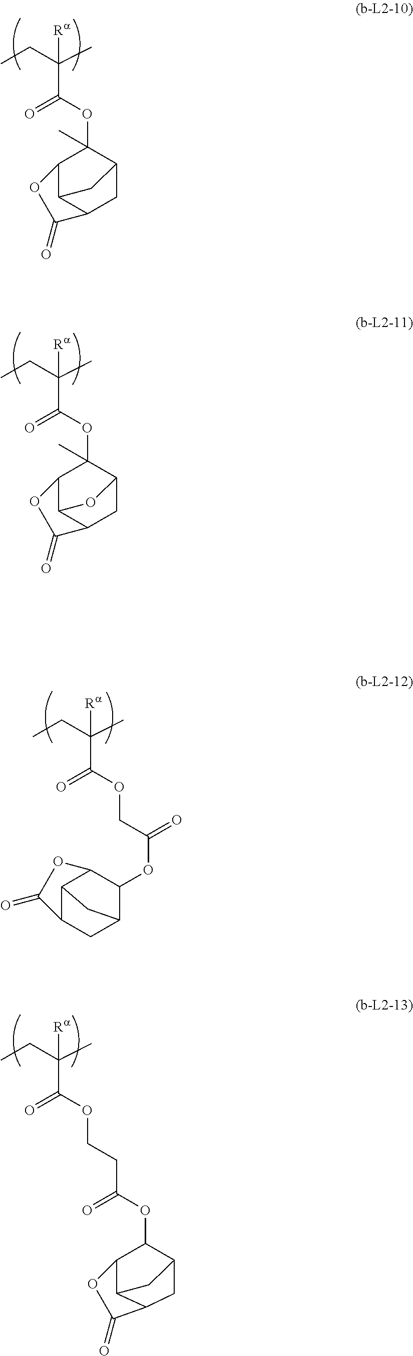

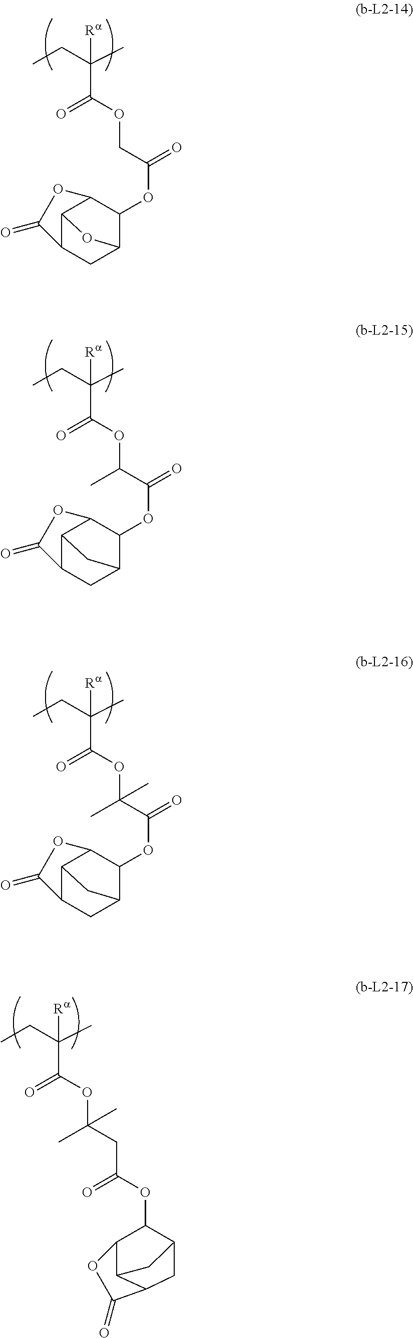

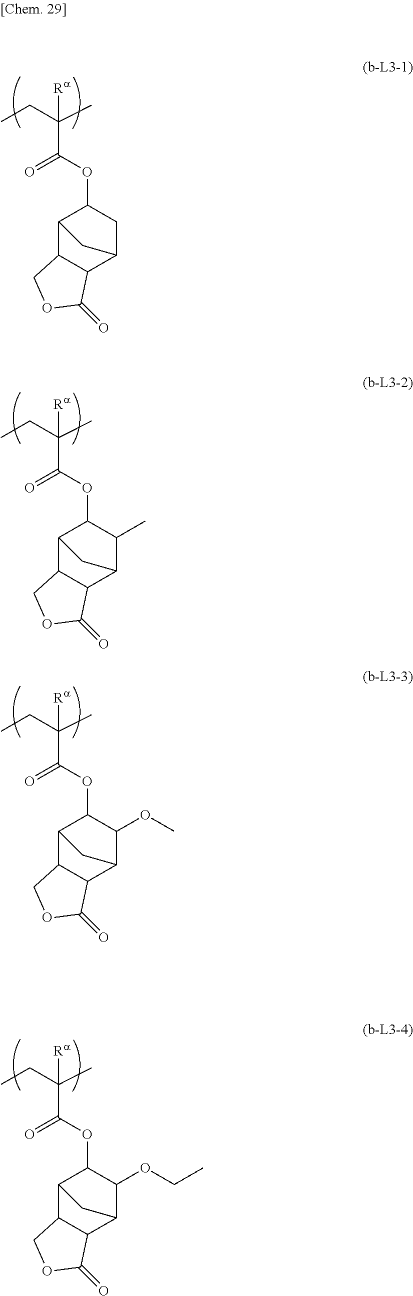

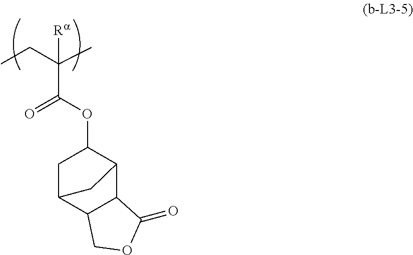

As the constituent unit (b-3a-L), at least one selected from the group consisting of the constituent units represented by the aforementioned formulae (b-L1) to (b-L5) is preferred, and at least one selected from the group consisting of the constituent units represented by the formulae (b-L1) to (b-L3) is more preferred, and at least one selected from the group consisting of the constituent units represented by the aforementioned formula (b-L1) or (b-L3) is particularly preferred. Among these, at least one selected from the group consisting of the constituent units represented by the aforementioned formulae (b-L1-1), (b-L1-2), (b-L2-1), (b-L2-7), (b-L2-12), (b-L2-14), (b-L3-1) and (b-L3-5) is preferred.

Further, as the constituent unit (b-3-L), the constituent units represented by following formulae (b-L6) to (b-L7) are also preferred.

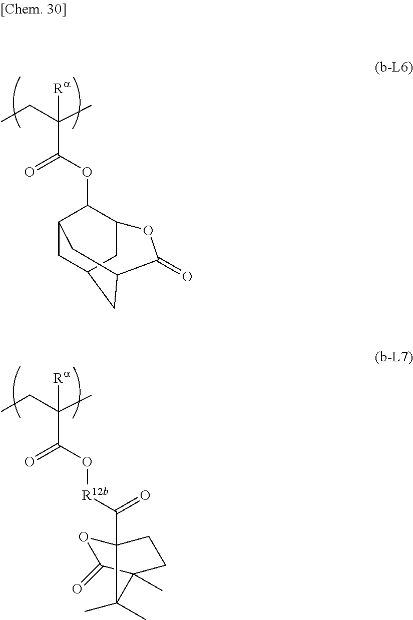

R and R^{12b} in the formulae (b-L6) and (b-L7) are the same as the above.

Further, the acrylic resin (B3) includes constituent units represented by the following formulae (b5) to (b7), having an acid dissociable group, as constituent units that enhance the solubility of the acrylic resin (B3) in alkali under the action of acid.

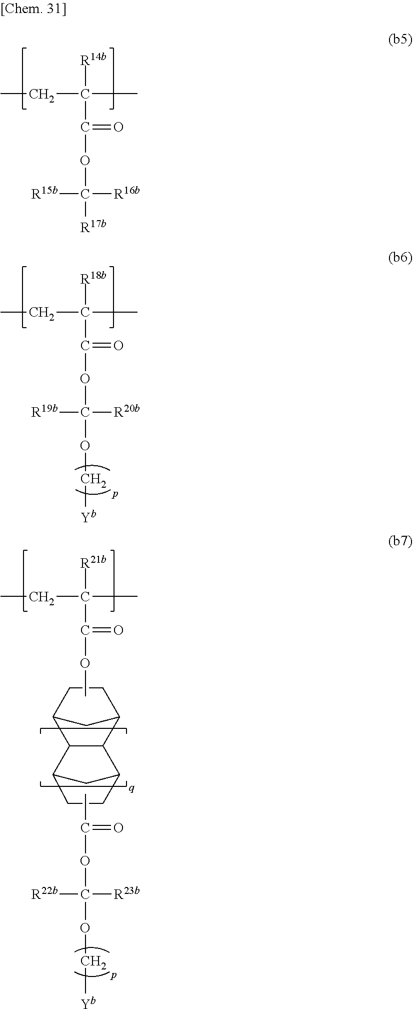

In the above formulae (b5) to (b7), R^{14b} and R^{18b} to R^{23b} each independently represent a hydrogen atom, a linear or branched alkyl group having 1 or more and 6 or less carbon atoms, a fluorine atom, or a linear or branched fluorinated alkyl group having 1 or more and 6 or less carbon atoms; R^{15b} to R^{17b} each independently represent a linear or branched alkyl group having 1 or more and 6 or less carbon atoms, a linear or branched fluorinated alkyl group having 1 or more and 6 or less carbon atoms, or an aliphatic cyclic group having 5 or more and 20 or less carbon atoms, and each independently represent a linear or branched alkyl group having 1 or more and 6 or less carbon atoms, or a linear or branched fluorinated alkyl group having 1 or more and 6 or less carbon atoms; and R^{16b} and R^{17b} may be bonded to each other to form a hydrocarbon ring having 5 or more and 20 or less carbon atoms together with the carbon atom to which both the groups are bonded; Y^{b} represents an optionally substituted aliphatic group or alkyl group; p is an integer of 0 or more and 4 or less; and q is 0 or 1.

Note here that examples of the linear or branched alkyl group include a methyl group, ethyl group, propyl group, isopropyl group, n-butyl group, isobutyl group, tert-butyl group, pentyl group, isopentyl group, neopentyl group, and the like. Furthermore, the fluorinated alkyl group refers to the abovementioned alkyl groups of which the hydrogen atoms are partially or entirely substituted with fluorine atoms. Specific examples of aliphatic cyclic groups include groups obtained by removing one or more hydrogen atoms from monocycloalkanes or polycycloalkanes such as bicycloalkanes, tricycloalkanes, and tetracycloalkanes. Specifically, groups obtained by removing one hydrogen atom from a monocycloalkane such as cyclopentane, cyclohexane, cycloheptane, or cyclooctane, or a polycycloalkane such as adamantane, norbornane, isobornane, tricyclodecane, or tetracyclododecane may be mentioned. In particular, groups obtained by removing one hydrogen atom from cyclohexane or adamantane (which may further be substituted) are preferred.

When R^{16b} and R^{17b} do not combine with each other to form a hydrocarbon ring, the above R^{15b}, R^{16b}, and R^{17b} represent preferably a linear or branched alkyl group having 1 or more and 4 or less carbon atoms, and more preferably a linear or branched alkyl group having 2 or more and 4 or less carbon atoms, for example, from the viewpoints of a high contrast and favorable resolution and depth of focus. The above R^{19b}, R^{20b}, R^{22b}, and R^{23b} preferably represent a hydrogen atom or a methyl group.

The above R^{16b} and R^{17b} may form an aliphatic cyclic group having 5 or more and 20 or less carbon atoms together with a carbon atom to which the both are attached. Specific examples of such an alicyclic group are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane and polycycloalkanes such as adamantane, norbornane, isobornane, tricyclodecane and tetracyclododecane from which one or more hydrogen atoms are removed. Particularly preferable are the groups of cyclohexane and adamantane from which one or more hydrogen atoms are removed (that may further have a substituent).

Further, in a case where an aliphatic cyclic group to be formed with the above R^{16b} and R^{17b} has a substituent on the ring skeleton thereof, examples of the substituent include a polar group such as a hydroxyl group, a carboxyl group, a cyano group and an oxygen atom (═O), and a linear or branched alkyl group having 1 or more and 4 or less carbon atoms. As the polar group, an oxygen atom (═O) is particularly preferred.

The above Y^{b} is an alicyclic group or an alkyl group; and examples thereof are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane, and polycycloalkanes such as adamantane, norbornane, isobornane, tricyclodecane and tetracyclododecane from which one or more hydrogen atoms are removed. Particularly preferable is the group of adamantane from which one or more hydrogen atoms are removed (that may further have a substituent).

When the alicyclic group of the above Y^{b} has a substituent on the ring skeleton, the substituent is exemplified by polar groups such as a hydroxyl group, carboxyl group, cyano group and oxygen atom (═O), and linear or branched alkyl groups having 1 or more and 4 or less carbon atoms. The polar group is preferably an oxygen atom (═O) in particular.

When Y^{b} is an alkyl group, it is preferably a linear or branched alkyl group having 1 or more and 20 or less carbon atoms, and more preferably 6 or more and 15 or less carbon atoms. The alkyl group is an alkoxyalkyl group particularly preferable. Examples of such an alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the constituent unit represented by the above formula (b5) include those represented by the following formulae (b5-1) to (b5-33).

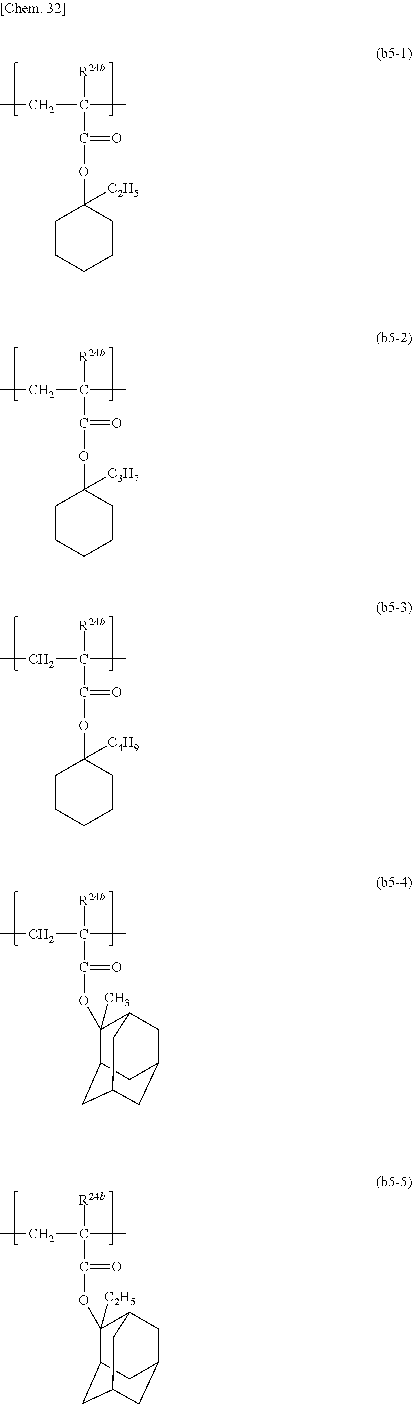

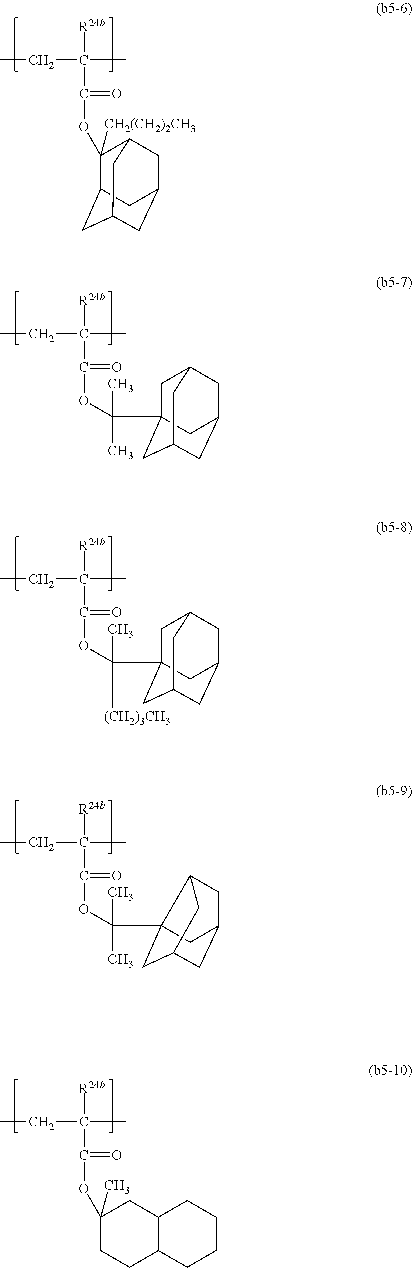

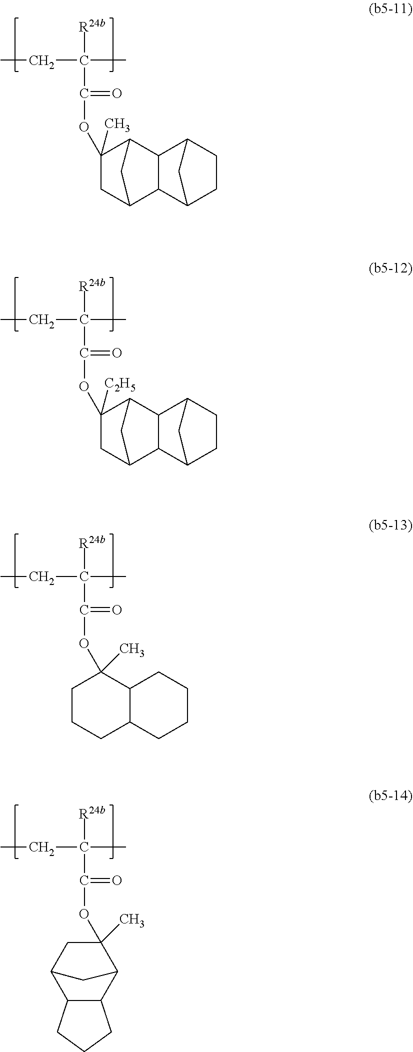

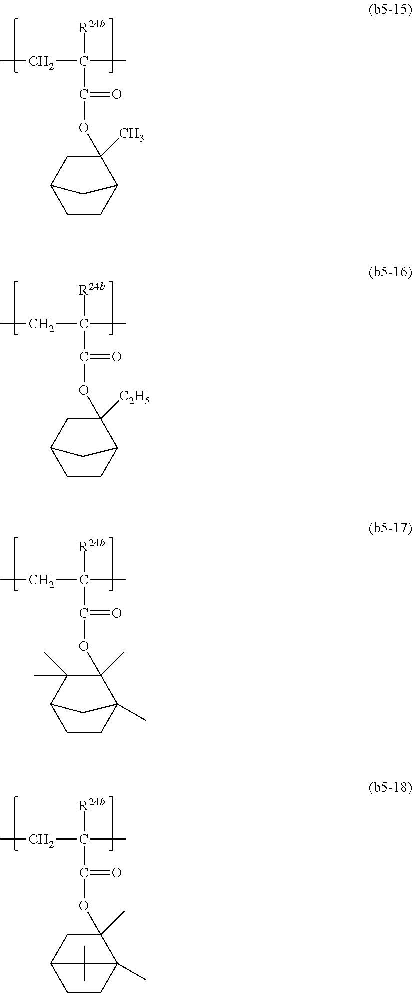

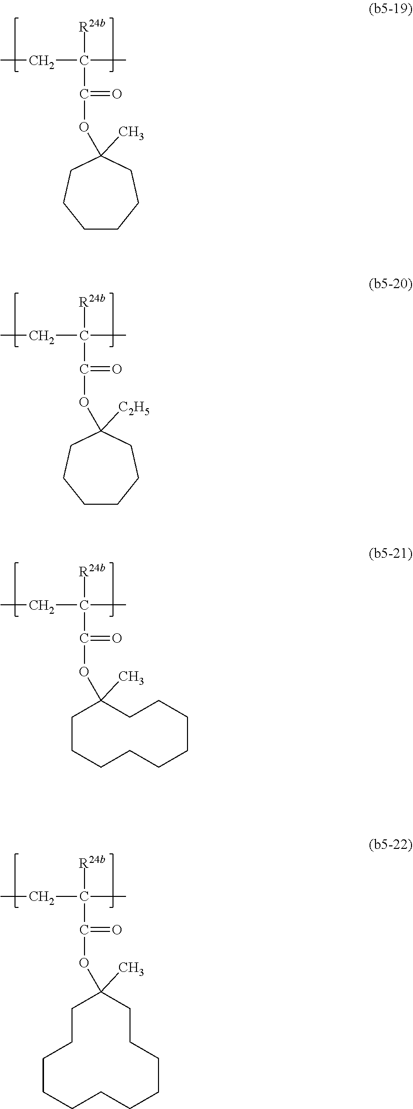

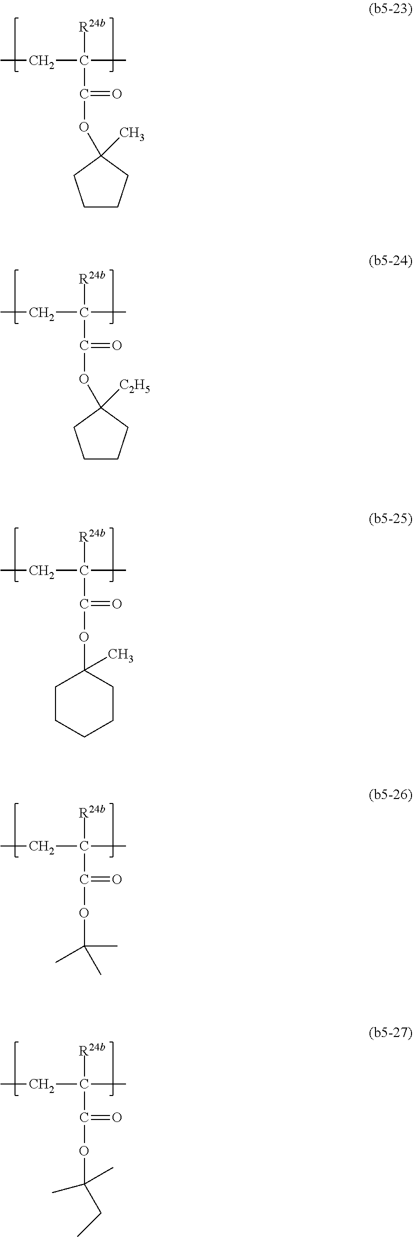

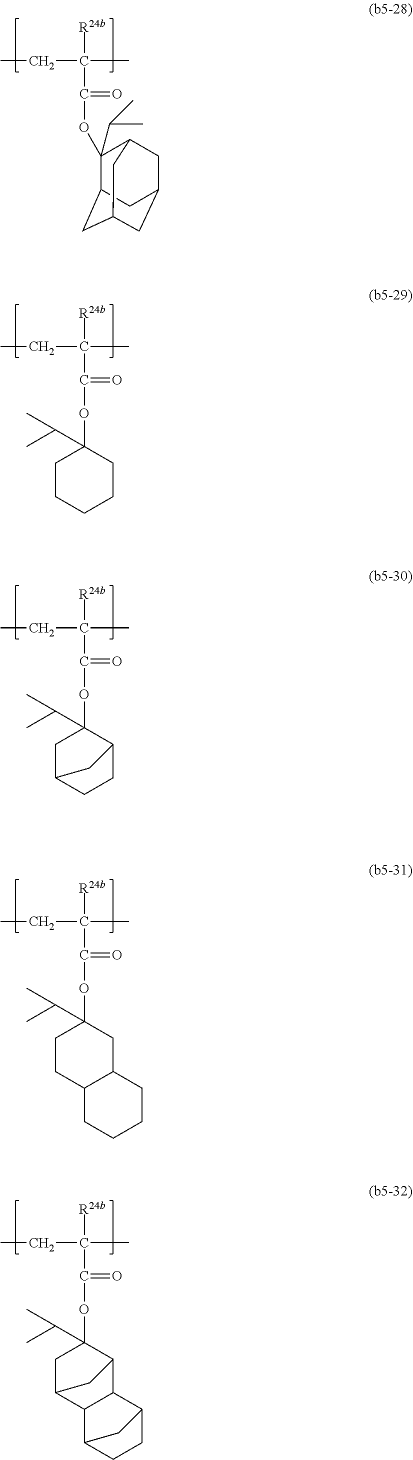

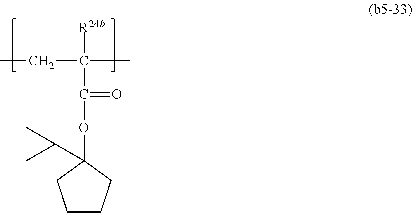

In the above formulae (b5-1) to (b5-33), R^{24b} represents a hydrogen atom or a methyl group.

Preferable specific examples of the constituent unit represented by the above formula (b6) include those represented by the following formulae (b6-1) to (b6-26).

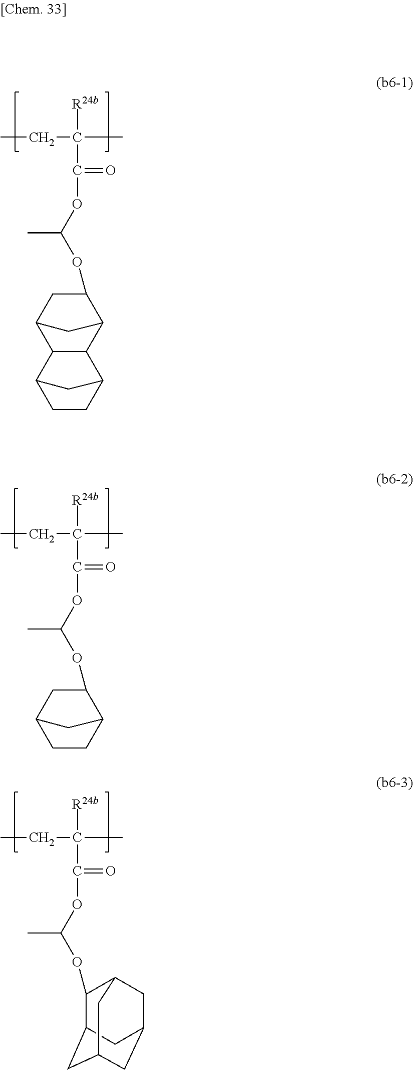

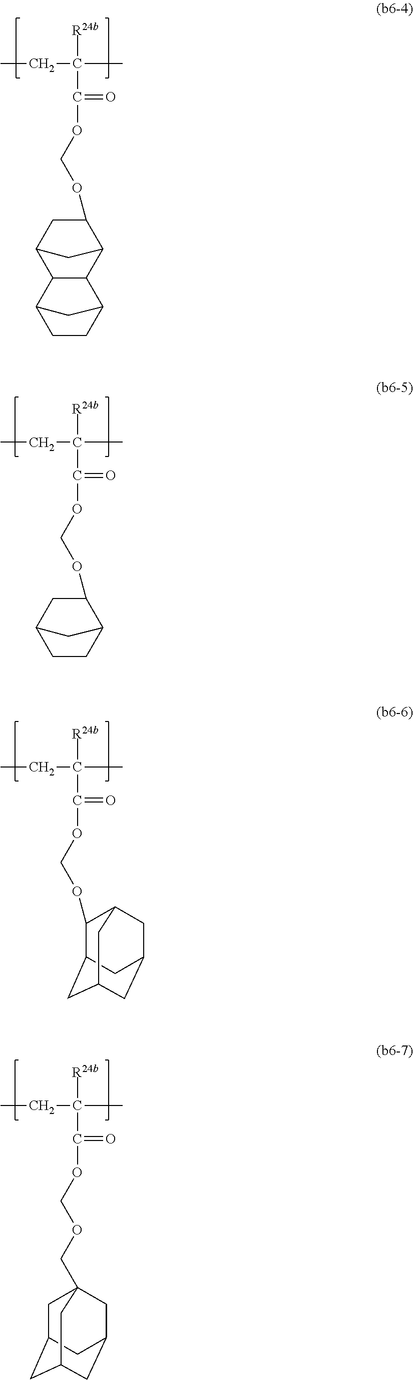

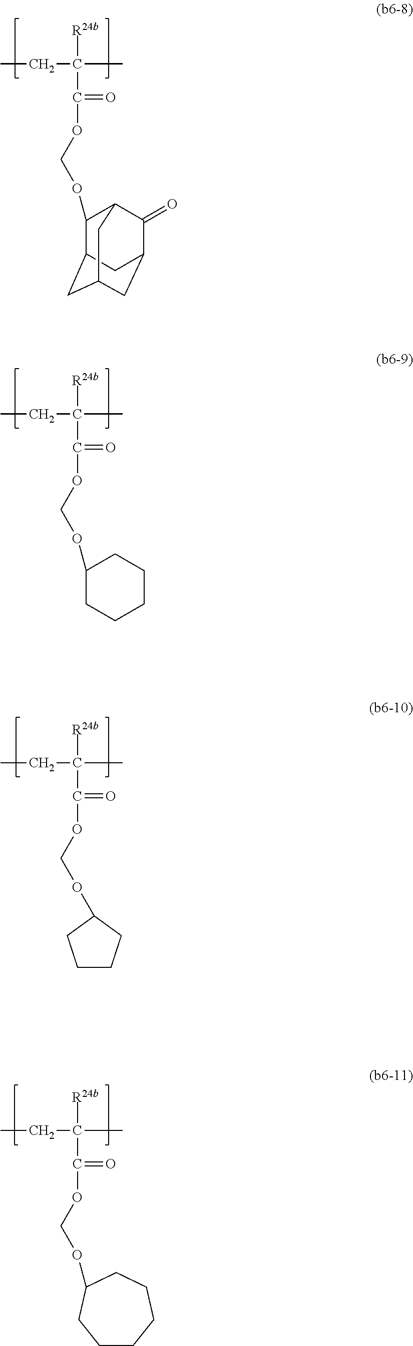

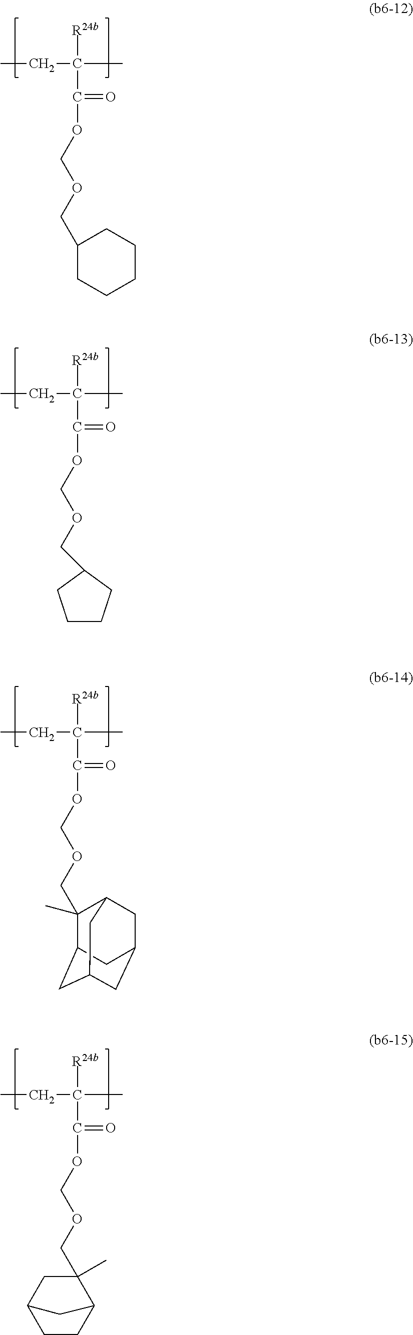

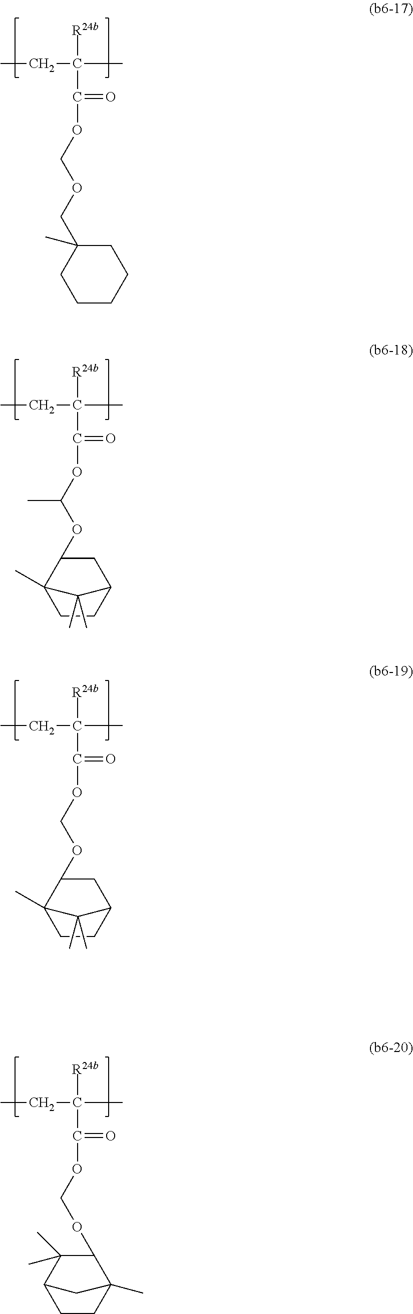

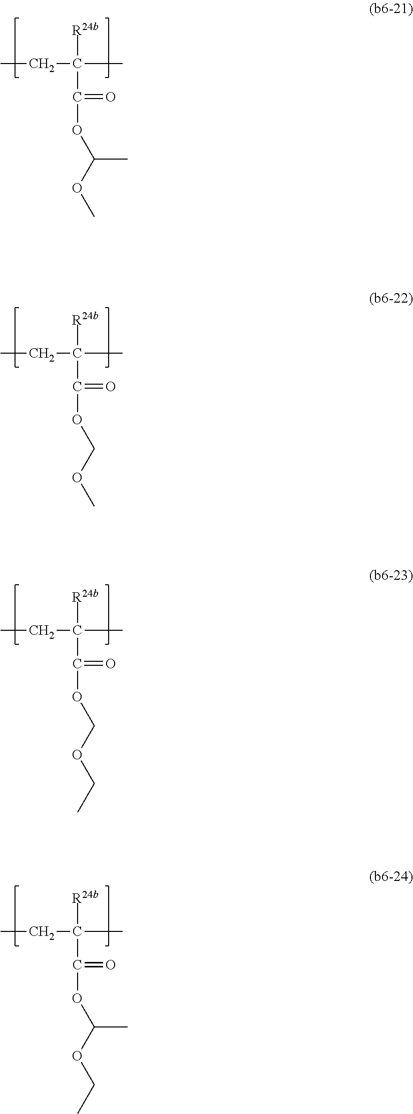

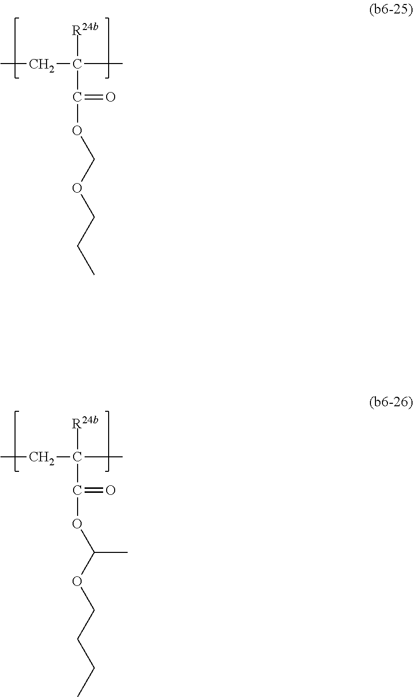

In the above formulae (b6-1) to (b6-26), R^{24b} represents a hydrogen atom or a methyl group.

Preferable specific examples of the constituent unit represented by the above formula (b7) include those represented by the following formulae (b7-1) to (b7-15).

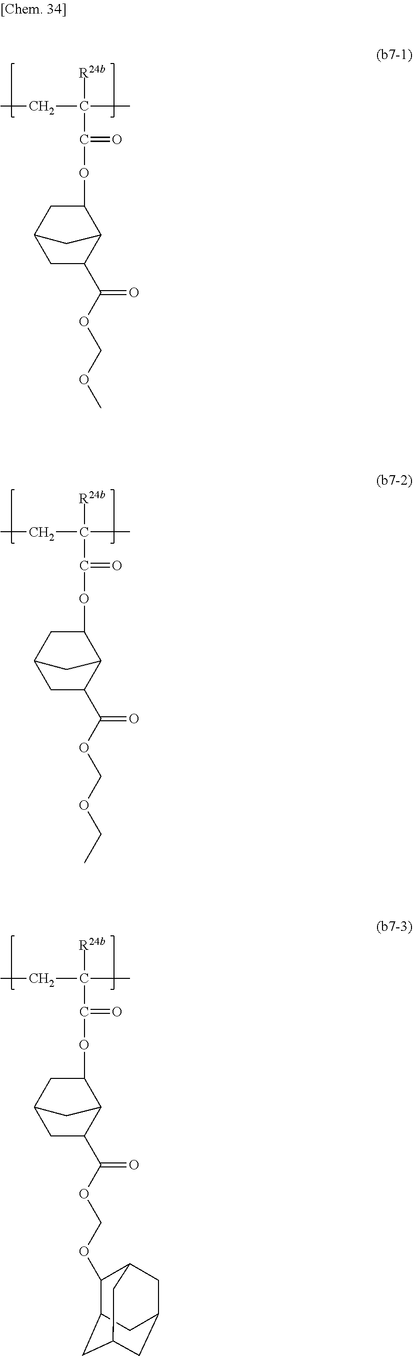

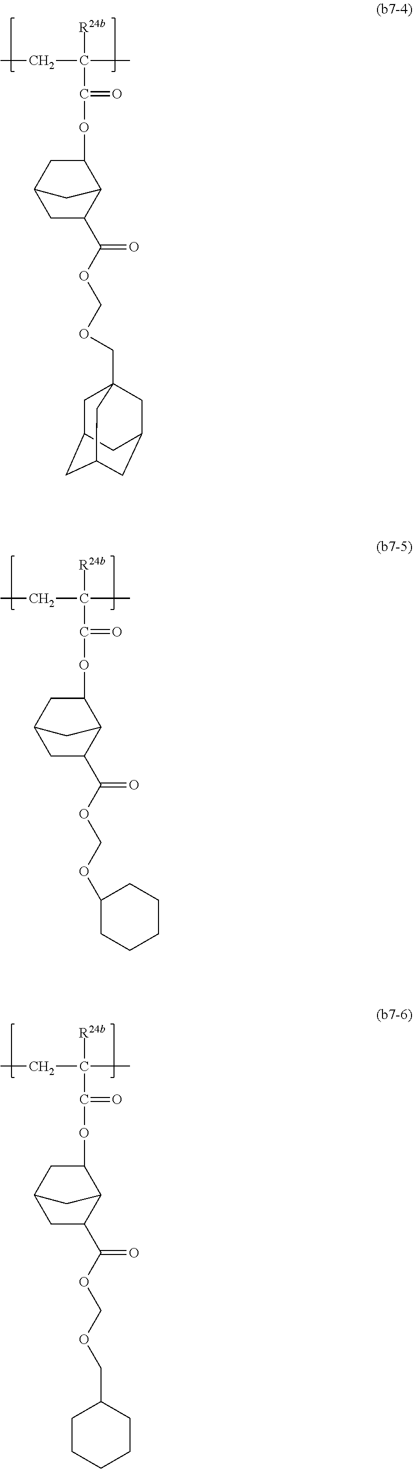

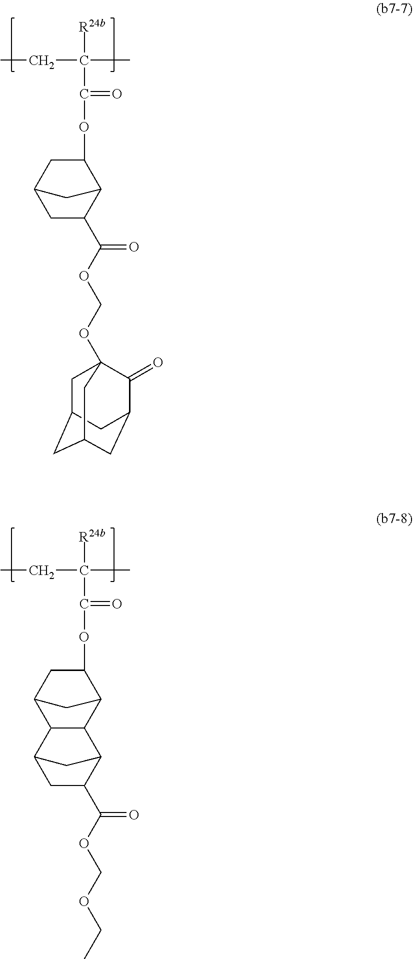

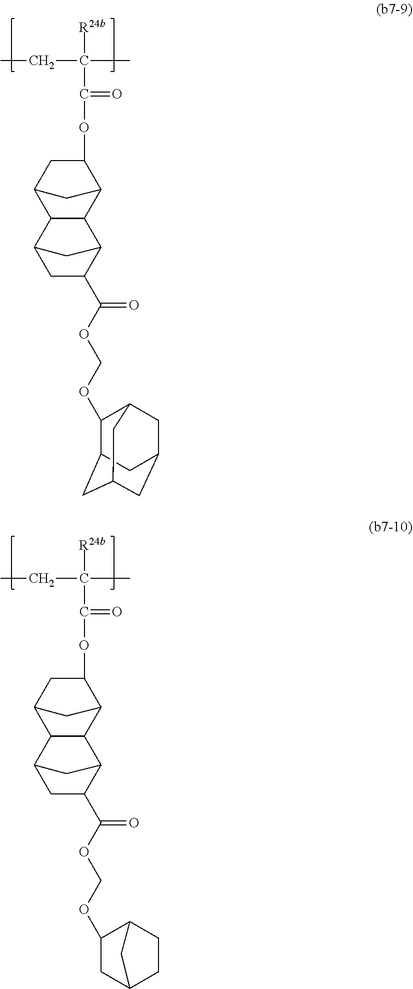

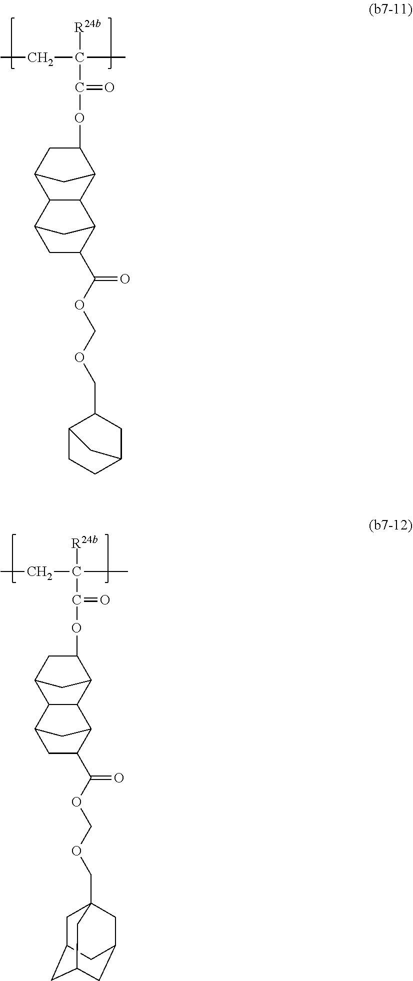

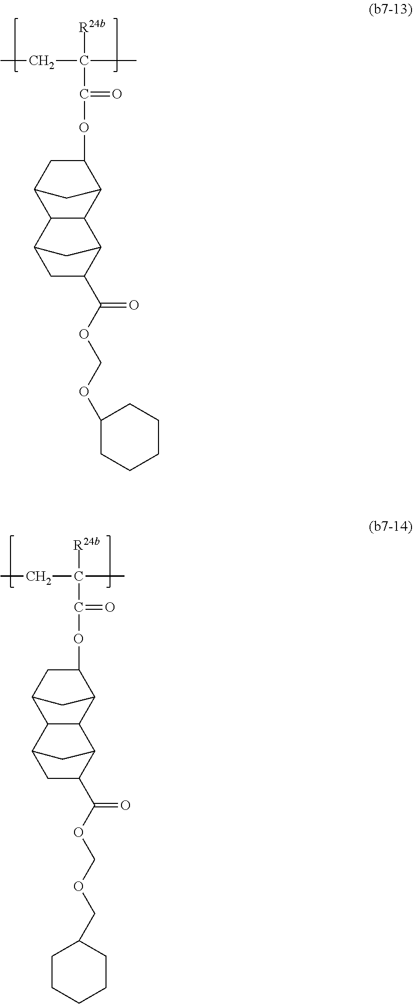

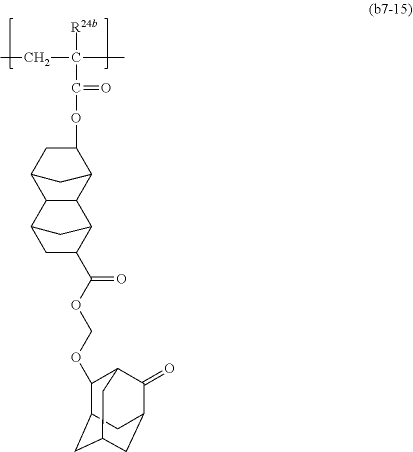

In the above formulae (b7-1) to (b7-15), R^{24b} represents a hydrogen atom or a methyl group.

Among the constituent units represented by the formulae (b5) to (b7) described above, those represented by the formula (b6) are preferred in that they can be easily synthesized and relatively easily sensitized. Further, among the constituent units represented by the formula (b6), those in which Y^{b} is an alkyl group are preferred, and those in which one or both of R^{19b} and R^{20b} are alkyl groups are preferred.

Further, the acrylic resin (B3) is preferably a resin including a copolymer including a constituent unit derived from a polymerizable compound having an ether bond together with a constituent unit represented by the above formulae (b5) to (b7).

Illustrative examples of the polymerizable compound having an ether bond include radical polymerizable compounds such as (meth)acrylic acid derivatives having an ether bond and an ester bond, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate, and the like. Also, the above polymerizable compound having an ether bond is preferably, 2-methoxyethyl (meth)acrylate, 2-ethoxyethyl (meth)acrylate, or methoxytriethylene glycol (meth)acrylate. These polymerizable compounds may be used alone, or in combinations of two or more thereof.

Furthermore, the acrylic resin (B3) may include another polymerizable compound as a constituent unit in order to moderately control physical or chemical properties. The polymerizable compound is exemplified by conventional radical polymerizable compounds and anion polymerizable compounds.

Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl(meth)acrylate, butyl(meth)acrylate and cyclohexyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described above, the acrylic resin (B3) may include a constituent unit derived from a polymerizable compound having a carboxy group such as the above monocarboxylic acids and dicarboxylic acids. However, it is preferable that the acrylic resin (B3) does not substantially include a constituent unit derived from a polymerizable compound having a carboxyl group, since a resist pattern including a nonresist portion having a more favorable rectangular sectional shape can easily be formed. Specifically, the proportion of a constituent unit derived from a polymerizable compound having a carboxyl group in the acrylic resin (B3) is preferably 20% by mass or less, more preferably 15% by mass or less, and particularly preferably 10% by mass or less. In acrylic resin (B3), acrylic resin including a relatively large amount of constituent unit derived from a polymerizable compound having a carboxy group is preferably used in combination with an acrylic resin that includes only a small amount of constituent unit derived from a polymerizable compound having a carboxy group or does not include this constituent unit.

Furthermore, examples of the polymerizable compound include (meth)acrylic acid esters having a non-acid-dissociable aliphatic polycyclic group, and vinyl group-containing aromatic compounds and the like. As the non-acid-dissociable aliphatic polycyclic group, particularly, a tricyclodecanyl group, an adamantyl group, a tetracyclododecanyl group, an isobornyl group, a norbornyl group, and the like are preferred in view of easy industrial availability and the like. These aliphatic polycyclic groups may have a linear or branched alkyl group having 1 or more and 5 or less carbon atoms as a substituent.

Specific examples of the (meth)acrylic acid esters having a non-acid-dissociable aliphatic polycyclic group include those having structures represented by the following formulae (b8-1) to (b8-5).

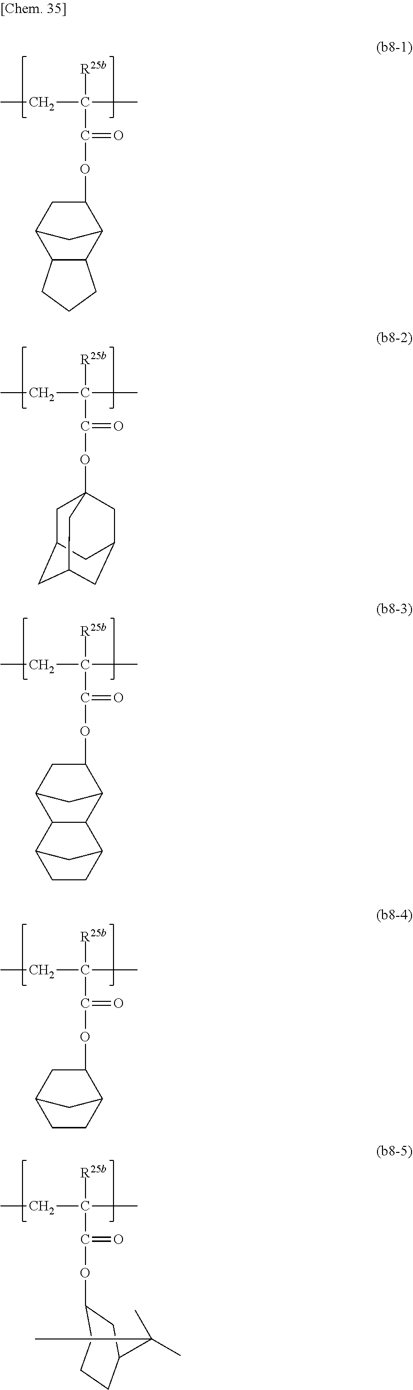

In the formulae (b8-1) to (b8-5), R^{25b} represents a hydrogen atom or a methyl group.

When the acrylic resin (B3) includes the constituent unit (b-3) including a —SO₂-containing cyclic group or a lactone-containing cyclic group, the content of the constituent unit (b-3) in the acrylic resin (B3) is preferably 5% by mass or more, more preferably 10% by mass or more, and particularly preferably 10% by mass or more and 50% by mass or less, and most preferably 10% by mass or more and 30% by mass or less. In a case where the positive-type photosensitive composition includes the constituent unit (b-3) having the above-mentioned range of amount, both good developing property and a good pattern shape can be easily achieved simultaneously.

Further, in the acrylic resin (B3), a constituent unit represented by the aforementioned formulae (b5) to (b7) is preferably included in an amount of 5% by mass or more, more preferably 10% by mass or more, and particularly preferably 10% by mass or more and 50% by mass or less.

The acrylic resin (B3) preferably includes the above constituent unit derived from a polymerizable compound having an ether bond. The content of the constituent unit derived from a polymerizable compound having an ether bond in the acrylic resin (B3) is preferably 0% by mass or more and 50% by mass or less, more preferably 5% by mass or more and 40% by mass or less, and further more preferably 5% by mass or more and 30% by mass or less.

The acrylic resin (B3) preferably includes the above constituent unit derived from (meth)acrylic acid esters having a non-acid-dissociable aliphatic polycyclic group. The content of the constituent unit derived from (meth)acrylic acid esters having a non-acid-dissociable aliphatic polycyclic group in the acrylic resin (B3) is preferably 0% by mass or more and 60% by mass or less, more preferably 5% by mass or more and 50% by mass or less, and further more preferably 5% by mass or more and 30% by mass or less.

As long as the positive-type photosensitive composition contains a predetermined amount of the acrylic resin (B3), an acrylic resin other than the acrylic resin (B3) described above can also be used as the resin (B). There is no particular limitation for such an acrylic resin other than the acrylic resin (B3) as long as it includes a constituent unit represented by the aforementioned formulae (b5) to (b7).

The mass-average molecular weight of the resin (B) described above in terms of polystyrene is preferably 10,000 or more and 600,000 or less, more preferably 20,000 or more and 400,000 or less, and even more preferably 30,000 or more and 300,000 or less. A mass-average molecular weight within these ranges allows a photosensitive layer made of a positive-type photosensitive composition to maintain sufficient strength without reducing detachability from a substrate, and can further prevent a swelled profile and crack generation when plating.

It is also preferred that the resin (B) has a dispersivity of 1.05 or more. Dispersivity herein indicates a value of a mass average molecular weight divided by a number average molecular weight. A dispersivity in the range described above can avoid problems with respect to stress resistance on intended plating or possible swelling of metal layers resulting from the plating process.

The content of the resin (B) is preferably 5% by mass or more and 60% by mass or less with respect to the total mass of the positive-type photosensitive composition. Furthermore, the content of the resin (B) is preferably 5% by mass or more and 98% by mass or less, and more preferably 10% by mass or more and 95% by mass or less with respect to the total solid mass of the positive-type photosensitive composition.

### <Sulfur-Containing Compound (C)>

The sulfur-containing compound (C) included in the positive-type photosensitive composition is solid at room temperature (25° C.). The sulfur-containing compound (C) is a compound containing a sulfur atom to coordinate, for example, to a metal. When forming a resist pattern for use as a template for plating on a surface made of a metal such as Cu, a defect of the cross-sectional shape such as footing easily occurs. However, when the positive photosensitive composition contains the sulfur-containing compound (C), even when a resist pattern is formed on a surface made of metal in a substrate, it is easy to suppress occurrence of a defect in a cross-sectional shape such as footing. Note here that the “footing” is a phenomenon in which the width of the bottom is narrower than that of the top in a non-resist section, because a resist portion extends toward the non-resist portion in the vicinity of the contacting surface between the substrate surface and the resist pattern.

However, when a photosensitive composition containing a sulfur-containing compound (C), the sulfur-containing compound (C) being solid at room temperature, is used, a foreign matter is often contained in the photosensitive composition or is often generated in the obtained resist pattern. This foreign matter is derived from the sulfur-containing compound included in the chemically amplified resist composition. When a resist pattern including a foreign matter is used as a template for forming a plated article or etching mask, it is difficult to form a plated article or etched product having the desired shape. In addition, when a foreign matter derived from a sulfur-containing compound is removed by filtration, there is a risk that a desired effect of improving the shape of a resist pattern may be impaired due to a reduction in the content of the sulfur-containing compound in the chemically amplified resist composition. Although described later in detail, in the manufacturing method of the present invention, the sulfur-containing compound (C) is dissolved in a specific solvent (S1) in advance to form a solution of the sulfur-containing compound (C), and this solution of the sulfur-containing compound (C) is blended with the acid generating agent (A) and the solvent (S2), whereby a photosensitive composition including a foreign matter derived from the sulfur-containing compound (C) in a reduced amount can be produced even though the sulfur-containing compound (C), the sulfur-containing compound being solid at room temperature, is contained.

Examples of the sulfur-containing compound (C) include a compound represented by the following formula (c1-1) or (c1-2) and a tautomer thereof.

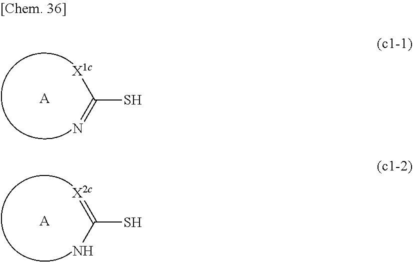

(In the formulae (c1-1) and (c1-2), ring A is a monocyclic ring having the number of ring constituting atoms of 4 or more and 8 or less, or a polycyclic ring having the number of ring constituting atoms of 5 or more and 20 or less;
X^{1c} is —CR^{11c}R^{12c}—, —NR^{13c}—, —O—, —S—, —Se—, —Te—, ═CR^{14c}—, or ═N—;
X^{2c} is —CR^{11c}═ or —N═; and
R^{11c}, R^{12c}, R^{13c}, and R^{14c} are each independently a hydrogen atom, an optionally substituted alkyl group having 1 or more and 8 or less carbon atoms, an optionally substituted alkenyl group having 1 or more and 8 or less carbon atoms, an optionally substituted alkynyl group having 1 or more and 8 or less carbon atoms, an optionally substituted aromatic group having 4 or more and 20 or less carbon atoms, or a carboxyl group.)

The tautomer of the compound represented by the above formula (c1-1) is, for example, a compound represented by the following formula (c1-1′). The tautomer of the compound represented by the above formula (c1-2) is, for example, a compound represented by the following formula (c1-2′).

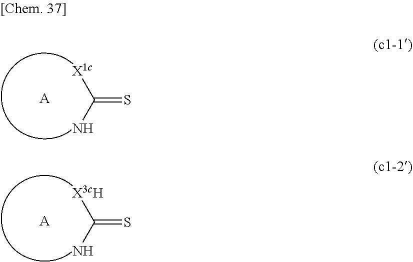

(In the formulae (c1-1′) and (c1-2′), ring A, X^{1c}, R^{11c}, R^{12c}, R^{13c}, and R^{14c} are the same as in the formulae (c1-1) and (c1-2), respectively, and X^{3c}H is —CR^{11c}H— or —NH—.)

Ring A may be an aromatic heterocycle or an aliphatic heterocycle. When ring A is a monocyclic ring, the number of ring-constituting atoms is preferably 5 or more and 7 or less, and more preferably 5 or 6. Examples of ring A which is a monocyclic ring include a pyrrole ring, an imidazoline ring, an imidazole ring, a triazole ring, a pyridine ring, a pyrimidine ring, a pyridazine ring, a pyrazine ring, a triazine ring, and a thiadiazole ring. When ring A is a polycyclic ring, the number of monocyclic rings constituting the polycyclic ring is preferably 1 or more and 3 or less, and more preferably 1 or 2. Examples of ring A which is a polycyclic ring include an indole ring, a benzimidazole ring, a purine ring, a quinoline ring, an isoquinoline ring, a quinazoline ring, a naphthyridine ring, and a pteridine ring. Ring A may have a substituent. Examples of substituents optionally possessed by ring A include a hydroxy group, an amino group, an amide group, an imide group, a carboxy group, an alkoxy group, a carboxylate ester group, a halogen atom, a saturated or unsaturated hydrocarbon group, and an aromatic group optionally substituted with a substituent such as a hydroxy group.

Examples of the optionally substituted alkyl group having 1 or more and 8 or less carbon atoms as R^{11c}, R^{12c}, R^{13c}, and R^{14c} include a methyl group, an ethyl group, an n-propyl group, an isopropyl group, an n-butyl group, an isobutyl group, a sec-butyl group, a tert-butyl group, an n-pentyl group, an isopentyl group, a neopentyl group, etc. Examples of the optionally substituted alkenyl group having 1 or more and 8 or less carbon atoms as R^{11c}, R¹², R^{13c}, and R^{14c} include a 3-butenyl group, a pentenyl group, a hexenyl group, a heptenyl group, an octenyl group, etc. Examples of the optionally substituted alkynyl group having 1 or more and 8 or less carbon atoms as R^{11c}, R^{12c}, R^{13c}, and R^{14c} include a pentynyl group, a hexynyl group, a heptynyl group, an octynyl group, etc. Examples of the optionally substituted aromatic group having 4 or more and 20 or less carbon atoms as R^{11c}, R^{12c}, R^{13c}, and R^{14c} include an aryl group such as a phenyl group and a naphthyl group, and a heteroaryl group such as a furyl group and a thienyl group. Examples of the substituent optionally possessed by the alkyl group having 1 or more and 8 or less carbon atoms, the alkenyl group having 1 or more and 8 or less carbon atoms, the alkynyl group having 1 or more and 8 or less carbon atoms, or the aromatic group having 4 or more and 20 or less carbon atoms as R^{11c}, R^{12c}, R^{13c}, and R^{14c} include a halogen atom, a cyano group, an oxoalkoxy group, a hydroxy group, an amino group, a nitro group, an aryl group, and an alkyl group substituted with a halogen atom.

In the formula (c1-1), X^{1c} is preferably —NR^{13c}— or ═N—.

Examples of the compound represented by the formula (c1-1) or (c1-2) include mercaptopyridine, mercaptopyrimidine, mercaptopyridazine, mercaptopyrazine, mercaptotriazine, mercaptoimidazole, mercaptoindazole, mercaptotriazole, mercaptothiadiazole, mercaptobenzimidazole, and the like, each of which may be substituted.

Examples of the compound represented by the formula (c1-1) or (c1-2) include 2-mercaptopyridine, 2-mercaptonicotinic acid, 2-mercaptopyrimidine, 4-mercaptopyrimidine, 3-mercaptopyridazine, 2-mercaptopyradine, 2-mercapto-1,3,5-triazine, 3-mercapto-1,2,4-triazine, 2-mercaptoimidazole, 2-mercapto-1,3,4-thiadiazole, 2-mercaptobenzoimidazole and compounds represented by the following formulae.

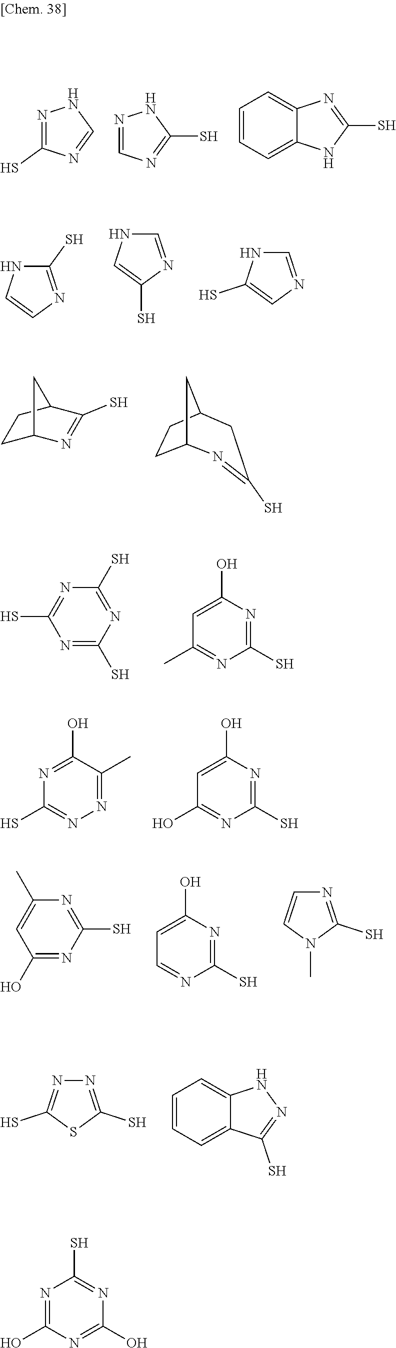

Examples of the compound represented by the formula (c1-1′) or (c1-2′) include the following thiouracil derivatives: 2-thiouracil, 5-methyl-2-thiouracil, 5,6-dimethyl-2-thiouracil, 6-ethyl-S-methyl-2-thiouracil, 6-methyl-S-n-propyl-2-thiouracil, 5-ethyl-2-thiouracil, 5-n-propyl-2-thiouracil, 5-n-butyl-2-thiouracil, 5-n-hexyl-2-thiouracil, 5-n-butyl-6-ethyl-2-thiouracil, 5-hydroxy-2-thiouracil, 5,6-dihydroxy-2-thiouracil, 5-hydroxy-6-n-propyl-2-thiouracil, 5-methoxy-2-thiouracil, 5-n-butoxy-2-thiouracil, 5-methoxy-6-n-propyl-2-thiouracil, 5-bromo-2-thiouracil, 5-chloro-2-thiouracil, 5-fluoro-2-thiouracil, 5-amino-2-thiouracil, 5-amino-6-methyl-2-thiouracil, 5-amino-6-phenyl-2-thiouracil, 5,6-diamino-2-thiouracil, 5-allyl-2-thiouracil, 5-allyl-3-ethyl-2-thiouracil, 5-allyl-6-phenyl-2-thiouracil, 5-benzyl-2-thiouracil, 5-benzyl-6-methyl-2-thiouracil, 5-acetamido-2-thiouracil, 6-methyl-5-nitro-2-thiouracil, 6-amino-2-thiouracil, 6-amino-5-methyl-2-thiouracil, 6-amino-5-n-propyl-2-thiouracil, 6-bromo-2-thiouracil, 6-chloro-2-thiouracil, 6-fluoro-2-thiouracil, 6-bromo-5-methyl-2-thiouracil, 6-hydroxy-2-thiouracil, 6-acetamide-2-thiouracil, 6-n-octyl-2-thiouracil, 6-dodecyl-2-thiouracil, 6-tetradodecyl-2-thiouracil, 6-hexadecyl-2-thiouracil, 6-(2-hydroxyethyl)-2-thiouracil, 6-(3-isopropyloctyl)-5-methyl-2-thiouracil, 6-(m-nitrophenyl)-2-thiouracil, 6-(m-nitrophenyl)-5-n-propyl-2-thiouracil, 6-α-naphthyl-2-thiouracil, 6-α-naphthyl-5-t-butyl-2-thiouracil, 6-(p-chlorophenyl)-2-thiouracil, 6-(p-chlorophenyl)-2-ethyl-2-thiouracil, 5-ethyl-6-eicosyl-2-thiouracil, 6-acetamide-5-ethyl-2-thiouracil, 6-eicosyl-5-allyl-2-thiouracil, 5-amino-6-phenyl-2-thiouracil, 5-amino-6-(p-chlorophenyl)-2-thiouracil, 5-methoxy-6-phenyl-2-thiouracil, 5-ethyl-6-(3,3-dimethyloctyl)-2-thiouracil, 6-(2-bromoethyl)-2-thiouracil, and the like.

Examples of the sulfur-containing compound (C) include a compound represented by the following formula (c2):

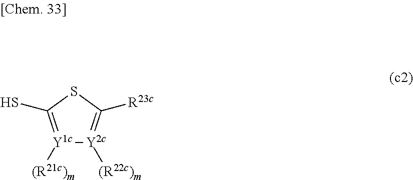

(In the formula (c2), Y^{1c} and Y^{2c} are each independently a nitrogen atom or a carbon atom; R^{21c} and R^{22c} are each independently a hydrogen atom, an aliphatic hydrocarbon group having 1 or more and 10 or less carbon atoms, an aromatic hydrocarbon group having 6 or more and 14 or less carbon atoms, and an alicyclic hydrocarbon group having 3 or more and 18 or less carbon atoms, R^{23c} is a hydrogen atom, an aliphatic hydrocarbon group having 1 or more and 10 or less carbon atoms, an aromatic hydrocarbon group having 6 or more and 14 or less carbon atoms, an alicyclic hydrocarbon group having 3 or more and 18 or less carbon atoms, —SR^{24c}, or —NR^{25c}R^{26c}; R^{24c}, R^{25c}, and R^{26c} are each independently a hydrogen atom, an aliphatic hydrocarbon group having 1 or more and 10 or less carbon atoms, an alicyclic hydrocarbon group having 3 or more and 10 or less carbon atoms, an aromatic hydrocarbon group having 6 or more and 14 or less carbon atoms, or an acyl group having 1 or more and 12 or less carbon atoms; a hydrogen atom of the aliphatic hydrocarbon group, the alicyclic hydrocarbon group, the aromatic hydrocarbon group, and the acyl group in R^{25c} and R^{26c} may be replaced with a hydroxy group; and n and m are each independently 0 or 1; when Y^{1c} is a nitrogen atom, n is 0; when Y^{1c} is a carbon atom, n is 1; when Y^{2c} is a nitrogen atom, m is 0; and when Y^{2c} is a carbon atom, m is 1.)

Examples of the aliphatic hydrocarbon group having 1 or more and 10 or less carbon atoms as R^{21c} and R^{22c} include an alkyl group such as a methyl group, an ethyl group, a propyl group, a butyl group, a pentyl group, a hexyl group, a heptyl group, an octyl group, and the like. Examples of the aromatic hydrocarbon group having 6 or more and 14 or less carbon atoms as R^{21c} and R^{22c} include an aryl group such as a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, a 2-methyl-6-ethylphenyl group. Examples of the alicyclic hydrocarbon group having 3 or more and 18 or less carbon atoms as R^{21c} and R^{22c} include a monocyclic alicyclic hydrocarbon group, i.e., cycloalkyl group, such as a cyclopentyl group, a cyclohexyl group, a cycloheptyl group, a cyclooctyl group, etc.; and a polycyclic alicyclic hydrocarbon group such as a decahydronaphthyl group, an adamantyl group, a norbornyl group. etc.

Examples of the aliphatic hydrocarbon group having 1 or more and 10 or less carbon atoms, the aromatic hydrocarbon group having 6 or more and 14 or less carbon atoms, and the alicyclic hydrocarbon group having 3 or more and 18 or less carbon atoms as R^{23c} include the same groups as the aliphatic hydrocarbon group having 1 or more and 10 or less carbon atoms, the aromatic hydrocarbon group having 6 or more and 14 or less carbon atoms, and the alicyclic hydrocarbon group having 3 or more and 18 or less carbon atoms mentioned as R^{21c} and R^{22c} above.

Examples of the aliphatic hydrocarbon group having 1 or more and 10 or less carbon atoms and the aromatic hydrocarbon group having 6 or more and 14 or less carbon atoms as R^{24c}, R^{25c}, and R^{26c} include the same as the aliphatic hydrocarbon group having 1 or more and 10 or less carbon atoms and the aromatic hydrocarbon group having 6 or more and 14 or less carbon atoms mentioned as R^{21c} and R^{22c} above. Examples of the alicyclic hydrocarbon group having 3 or more and 10 or less carbon atoms as R^{24c}, R^{25c}, and R^{26c} include a monocyclic alicyclic hydrocarbon group, i.e., cycloalkyl group, such as a cyclopentyl group, a cyclohexyl group, a cycloheptyl group, a cyclooctyl group, etc.; and a polycyclic alicyclic hydrocarbon group such as a decahydronaphthyl group, an adamantyl group, a norbornyl group, etc. Examples of the acyl group having 1 or more and 12 or less carbon atoms as R^{24c}, R^{25c}, and R^{26c} include an acetyl group, a propionyl group, a butyryl group, a valeryl group, a hexylcarbonyl group, a heptylcarbonyl group, an octylcarbonyl group, a decylcarbonyl group, a dodecylcarbonyl group, and a benzoyl group.

In the formula (c2), Y^{1c} and Y^{2c} are preferably nitrogen atoms.

Examples of the compound represented by the formula (c2) include compounds represented by the following formulae.

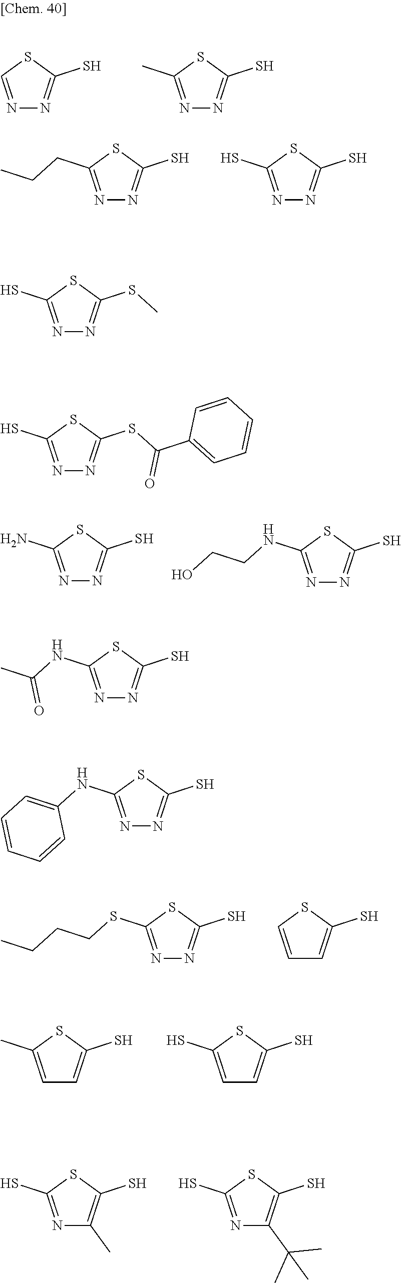

The sulfur-containing compound (C) is preferably used in a range of 0.01 parts by mass or more and 5 parts by mass or less, more preferably in a range of 0.01 parts by mass or more and 3 parts by mass or less, and most preferably in a range of 0.03 parts by mass or more and 2 parts by mass or less, with respect to 100 parts by mass of the total mass of the resin (B) and an alkali-soluble resin (D) described below.

Note that, although a sulfur-containing compound which is liquid at room temperature may be contained, the content of the sulfur-containing compound (C) which is solid at room temperature is preferably 50% by mass or more, more preferably 80% by mass or more, and most preferably 100% by mass, with respect to the total of the sulfur-containing compound (C) which is solid at room temperature and the sulfur-containing compound which is liquid at room temperature.

### <Alkali-Soluble Resin (D)>

It is preferable that the positive-type photosensitive composition further contains an alkali-soluble resin (D) in order to improve crack resistance. Here, the alkali-soluble resin refers to a resin such that when a resin film having a film thickness of 1 μm formed on a substrate by using a resin solution (solvent: propylene glycol monomethyl ether acetate) having a resin concentration of 20% by mass is immersed in an aqueous TMAH solution of 2.38% by mass for 1 minute, the resin film dissolves by 0.01 μm or more. The alkali-soluble resin (D) is preferably at least one type of resins selected from the group consisting of a novolac resin (D1), a polyhydroxystyrene resin (D2), and an acrylic resin (D3).

### [Novolac Resin (D1)]

The novolac resin can be obtained, for example, by subjecting an aromatic compound (hereinafter, simply referred to as “phenols”) having a phenolic hydroxy group and an aldehyde to addition condensation under an acid catalyst.

Examples of the above-mentioned phenols include: phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglycinol, hydroxydiphenyl, bisphenol A, gallic acid, gallate esters, α-naphthol, β-naphthol, etc. Examples of the aldehyde include formaldehyde, furfural, benzaldehyde, nitrobenzaldehyde, and acetaldehyde. The catalyst in the addition condensation reaction is not particularly limited, and for example, as an acid catalyst, hydrochloric acid, nitric acid, sulfuric acid, formic acid, oxalic acid, acetic acid, and the like are used.

Note that it is possible to further improve the flexibility of the novolac resin by using o-cresol, replacing a hydrogen atom of a hydroxy group in the resin with another substituent, or using a bulky aldehyde.

The mass average molecular weight of a novolac resin (D1) is not particularly limited within a range not inhibiting the objects of the present invention, but is preferably 1,000 or more and 50,000 or less.

### [Polyhydroxystyrene Resin (D2)]

Examples of hydroxystyrene-based compounds constituting the polyhydroxystyrene resin (D2) include p-hydroxystyrene, α-methylhydroxystyrene, α-ethylhydroxystyrene, etc. Furthermore, a copolymer of the polyhydroxystyrene resin (D2) with a styrene resin is preferable. Examples of the styrene-based compound constituting such a styrene resin include styrene, chlorostyrene, chloromethylstyrene, vinyltoluene, α-methylstyrene, etc.

The mass average molecular weight of the polyhydroxystyrene resin (D2) is not particularly limited within a range not inhibiting the objects of the present invention, but is preferably 1,000 or more and 50,000 or less.

### [Acrylic Resin (D3)]

The acrylic resin (D3) preferably includes a constitutional unit derived from a polymerizable compound having an ether bond and a constitutional unit derived from a polymerizable compound having a carboxy group.

As the polymerizable compound having an ether bond, the following (meth) acrylic acid derivatives having an ether bond and an ester bond can be exemplified: 2-methoxyethyl (meth)acrylate, methoxytriethylene glycol (meth)acrylate, 3-methoxybutyl (meth)acrylate, ethyl carbitol (meth)acrylate, phenoxypolyethylene glycol (meth)acrylate, methoxypolypropylene glycol (meth)acrylate, tetrahydrofurfuryl (meth) acrylate, etc. The polymerizable compound having an ether bond is preferably 2-methoxyethyl acrylate or methoxytriethylene glycol acrylate. These polymerizable compounds may be used alone, or two or more of them may be used in combination.

As the polymerizable compound having a carboxy group, monocarboxylic acids, such as acrylic acid, methacrylic acid, crotonic acid, etc.; dicarboxylic acids, such as maleic acid, fumaric acid, itaconic acid, etc.; and compounds each having both a carboxy group and an ester bond, such as 2-methacryloyloxyethyl succinate, 2-methacryloyloxyethyl maleate, 2-methacryloyloxyethyl phthalate, 2-methacryloyloxyethyl hexahydrophthalate, etc. can be exemplified. The polymerizable compound having a carboxy group is preferably acrylic acid or methacrylic acid. These polymerizable compounds may be used alone, or two or more of them may be used in combination.

The mass average molecular weight of the acrylic resin (D3) is not particularly limited within a range not inhibiting the objects of the present invention, but is preferably 50,000 or more and 800,000 or less.

The content of the alkali-soluble resin (D) is preferably 0 parts by mass or more and 80 parts by mass or less, and more preferably 0 parts by mass or more and 60 parts by mass or less, when the total of the resin (B) and the alkali-soluble resin (D) is set to 100 parts by mass. By setting the content of the alkali-soluble resin (D) within the above range, crack resistance tends to be improved, and film reduction during development tends to be prevented.

### <Acid Diffusion Inhibiting Agent (F)>

It is preferable that the positive-type photosensitive composition further includes an acid diffusion inhibiting agent (F) for improving a shape of a resist pattern, preservation stability of the photosensitive resin film, and the like. As the acid diffusion inhibiting agent (F), a nitrogen-containing compound (F1) is preferred, and further, if necessary, an organic carboxylic acid or an oxo acid of phosphorus or a derivative thereof (F2) can be contained.

### [Nitrogen-Containing Compound (F1)]

Examples of the nitrogen-containing compound (F1) include trimethylamine, diethylamine, triethylamine, di-n-propylamine, tri-n-propylamine, tri-n-pentylamine, tribenzylamine, diethanolamine, triethanolamine, n-hexylamine, n-heptyl amine, n-octyl amine, n-nonyl amine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3,-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane and pyridine, and pyridines. These may be used alone, or in combinations of two or more thereof.

Furthermore, commercially available hindered amine compounds such as ADK Stab LA-52, ADK Stab LA-57, ADK Stab LA-63P, ADK Stab LA-68, ADK Stab LA-72, ADK Stab LA-77Y, ADK Stab LA-77G, Adeka Stab LA-81, ADK Stab LA-82, and ADK Stab LA-87 (all manufactured by ADEKA), and a 4-hydroxy-1,2,2,6,6-pentamethylpiperidine derivative, and the like, and pyridine having 2 and 6 positions substituted with a substituent such as a hydrocarbon group, e.g., 2,6-diphenyl pyridine and 2,6-di-tert-butyl pyridine, can be used as the nitrogen-containing compound (F1).

The nitrogen-containing compound (F1) may be used in an amount typically in the range of 0 parts by mass or more and 5 parts by mass or less, and particularly preferably in the range of 0 parts by mass or more and 3 parts by mass or less, with respect to 100 parts by mass of total mass of the above resin (B) and the above alkali-soluble resin (D).

### [Organic Carboxylic Acid or Oxo Acid of Phosphorus or Derivative Thereof (F2)]

Among the organic carboxylic acid, or the oxo acid of phosphorus or the derivative thereof (F2), preferred examples of the organic carboxylic acid include malonic acid, citric acid, malic acid, succinic acid, benzoic acid, salicylic acid and the like, and salicylic acid is particularly preferred.

Examples of the oxo acid of phosphorus or derivatives thereof include: phosphoric acid and derivatives thereof, such as di-n-butyl phosphate, diphenyl phosphate, etc.; phosphonic acid and derivatives thereof such as phosphonic acid, dimethyl phosphonate, di-n-butyl phosphonate, phenylphosphonic acid, diphenyl phosphonate, dibenzyl phosphonate, etc.; and phosphinic acid and derivatives thereof such as phosphinic acid, phenylphosphinic acid, etc.; and the like. Among these, phosphonic acid is particularly preferred. These may be used alone, or in combinations of two or more thereof.

The organic carboxylic acid or oxo acid of phosphorus or derivative thereof (F2) may be used in an amount usually in the range of 0 parts by mass or more and 5 parts by mass or less, and particularly preferably in the range of 0 parts by mass and 3 parts by mass or less, with respect to 100 parts by mass of total mass of the above resin (B) and the above alkali-soluble resin (D).

Moreover, in order to form a salt to allow for stabilization, the organic carboxylic acid, or the oxo acid of phosphorous or the derivative thereof (F2) is preferably used in an amount equivalent to that of the above nitrogen-containing compound (F1).

### <Organic Solvent (S)>

The photosensitive composition includes an organic solvent (S). The photosensitive composition of the present invention includes, as the solvent (S), a solvent (S1) having a Hansen solubility parameter in which a polar term δp is 10 (MPa^{0.5}) or more, and a solvent (S2), the solvent (S2) being a different solvent from the solvent (S1). In the manufacturing method of the present invention, a solution (premix solution) of the sulfur-containing compound (C) is prepared by dissolving the sulfur-containing compound (C) in the solvent (S1) having a Hansen solubility parameter in which a polar term δp is 10 (MPa^{0.5}) or more, and this solution of the sulfur-containing compound (C) is blended with the acid generating agent (A) and the solvent (S2), whereby a photosensitive composition including a foreign matter derived from the sulfur-containing compound (C) in a reduced amount can be manufactured.

δp, the polarity term of the Hansen solubility parameter (a term for energy by dipole interaction), can be obtained using software (software name: Hansen Solubility Parameter in Practice (HSPiP)) developed by Charles Hansen. The polarity term δp of the Hansen solubility parameter is preferably 12 (MPa^{0.5}) or more, and more preferably 16 (MPa^{0.5}) or more.

The boiling point of the solvent (S1) is preferably 180° C. or more, and more preferably 200° C. or more. Note that the boiling point refers to a boing point under atmospheric pressure.

Examples of the solvent (S1) include γ-butyrolactone (δp: 16.6 MPa^{0.5}, boiling point: 204 to 205° C.), dimethyl sulfoxide (δp: 16.4 MPa^{0.5}, boiling point: 189° C.), and N-methyl-2-pyrrolidone (δp: 12.3 MPa^{0.5}, boiling point: 202° C.).

There is no particular limitation on the types of the organic solvent (S2) as long as the objects of the present invention are not impaired, and an organic solvent appropriately selected from those conventionally used for positive-type photosensitive compositions can be used. A desired photosensitive composition can be obtained by using an organic solvent which has been conventionally used in positive-type photosensitive compositions.

Specific examples of the organic solvent (S2) include ketones such as acetone, methyl ethyl ketone, cyclohexanone, methyl isoamyl ketone, and 2-heptanone; polyhydric alcohols and derivatives thereof such as ethylene glycol monoacetate, diethylene glycol, diethylene glycol monoacetate, propylene glycol, propylene glycol monoacetate, dipropylene glycol, and a monomethyl ether, a monoethyl ether, a monopropyl ether, a monobutyl ether, and a monophenyl ether of dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate, and 3-methyl-3-methoxybutyl acetate; aromatic hydrocarbons such as toluene and xylene; and the like. These may be used alone, or as a mixture of two or more thereof.

Furthermore, examples of the organic solvent (S2) include N-methylformamide, N,N-dimethylformamide, N-methylformanilide, N-methylacetamide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, ethylene carbonate, propylene carbonate, phenyl cellosolve acetate, and the like.

In the photosensitive composition, the content of the solvent (S1) is preferably more than 0% by mass and less than 20% by mass, more preferably more than 0% by mass and less than 10% by mass, and most preferably more than 0% by mass and less than 5% by mass, with respect to the mass of the solvent (S1) and the mass of the solvent (S2). Note that the photosensitive composition including the solvent (S1) in a content of more than 0% by mass and less than 5% by mass with respect to the total of the mass of the solvent (S1) and the mass of the solvent (S2) is the chemically amplified photosensitive composition of the present invention and is a novel photosensitive composition.

The content of the organic solvent (S), that is, the total of the solvent (S1) and the solvent (S2), is not particularly limited, as long as the objects of the present invention are not impaired. In a case where the photosensitive composition is used for a thick-film application such that a photosensitive layer obtained by a spin coating method and the like has a film thickness of 2 μm or more, the organic solvent (S) is preferably used in a range such that the photosensitive composition has a solid content concentration of 30% by mass or more, and more preferably a solid content of 30% by mass or more and 55% by mass or less.

### <Other Components>

The photosensitive composition may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

The photosensitive composition may contain a Lewis acidic compound. When the photosensitive composition includes a Lewis acidic compound, a photosensitive composition with high sensitivity is easily obtained, so that a resist pattern whose cross-sectional shape is rectangular is more easily formed using a positive-type photosensitive composition. Furthermore, when a pattern is formed using the photosensitive composition, when time required for each process at the time of pattern formation or time required between the processes is long, a pattern having a desired shape and dimension may not be easily formed, or developing property may be deteriorated. However, when a Lewis acidic compound is blended into the photosensitive composition, such adverse effects on the pattern shape or the developing property can be mitigated or a process margin can be widened.

The Lewis acidic compound herein represents “a compound that acts as an electron-pair receptor having an empty orbital capable of receiving at least one electron pair.” The Lewis acidic compound is not particularly limited as long as it corresponds to the above definition, and is a compound which is recognized as the Lewis acidic compound by a person skilled in the art. As the Lewis acidic compound, a compound that does not correspond to a Bronsted acid (proton acid) is preferably used. Specific examples of the Lewis acidic compound include boron fluoride, ether complexes of boron fluoride (for example, BF₃.Et₂O, BF₃.Me₂O, BF₃.THF, etc., Et represents an ethyl group, Me represents a methyl group, and THF represents tetrahydrofuran), organic boron compounds (for example, tri-n-octyl borate, tri-n-butyl borate, triphenyl borate, triphenylboron, etc.), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethanesulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, stannous tartrate, and the like. Furthermore, other specific examples of the Lewis acidic compound include chloride, bromide, sulfate, nitrate, carboxylate, or trifluoromethanesulfonate, of the rare earth metal element, and cobalt chloride, ferrous chloride, yttrium chloride, and the like. Examples of the rare earth metal element herein include lanthanum, cerium, praseodymium, neodymium, samarium, europium, gadolinium, terbium, dysprosium, holmium, erbium, thulium, ytterbium, and lutetium.

From the viewpoint of easiness in availability and favorable effect by addition thereof, it is preferable that the Lewis acidic compound contains a Lewis acidic compound including elements belonging to Group 13 of the periodic table. Herein, examples of the elements belonging to Group 13 include boron, aluminum, gallium, indium, and thallium. Among the above elements belonging to Group 13, boron is preferable from the viewpoint that the Lewis acidic compound is easily available and addition effect is particularly excellent. In other words, it is preferable that the Lewis acidic compound contains a Lewis acidic compound including boron.

Examples of the Lewis acidic compound containing boron include boron fluoride, ether complexes of boron fluoride, boron halides such as boron chloride and boron bromide, and various organic boron compounds. As the Lewis acidic compound including boron, an organic boron compound is preferable because the content ratio of halogen atoms in the Lewis acidic compound is small and the photosensitive composition is easily applicable to an application requiring a low halogen content.

Preferable examples of the organic boron compound include a boron compound represented by the following formula (f1):

B(R^{f1})ₜ₁(OR^{f2})₍₃₋ₜ₁₎ . . . (f1)

(In the formula (f1), R^{f1} and R^{f2} each independently represent a hydrocarbon group having 1 or more and 20 or less carbon atoms; the hydrocarbon group may have one or more substituents; t1 is an integer of 0 or more and 3 or less; when a plurality of R^{f1} exists, two of the plurality of R^{f1} may be bonded to each other to form a ring; and when a plurality of OR^{f2} is present, two of the plurality of OR^{f2} may be bonded to each other to form a ring). The photosensitive composition preferably includes one or more boron compounds represented by the above formula (f1) as the Lewis acidic compound mentioned above.

In the formula (f1), R^{f1} and R^{f2} are a hydrocarbon group, the number of carbon atoms of the hydrocarbon group is 1 or more and 20 or less. The hydrocarbon group having 1 or more and 20 or less carbon atoms may be an aliphatic hydrocarbon group, or an aromatic hydrocarbon group, a hydrocarbon group having a combination of an aliphatic group and an aromatic group. As the hydrocarbon group having 1 or more and 20 or less carbon atoms, a saturated aliphatic hydrocarbon group, or an aromatic hydrocarbon group is preferable. The number of carbon atoms of the hydrocarbon group as R^{f1} and R^{f2} is preferably 1 or more and 10 or less. When the hydrocarbon group is an aliphatic hydrocarbon group, the number of carbon atoms thereof is preferably 1 or more and 6 or less, and particularly preferably 1 or more and 4 or less. The hydrocarbon group as R^{f1} and R^{f2} may be a saturated hydrocarbon group, or an unsaturated hydrocarbon group, and a saturated hydrocarbon group is preferable. When the hydrocarbon group as R^{f1} and R^{f2} is an aliphatic hydrocarbon group, the aliphatic hydrocarbon group may be linear, branched or cyclic or combination thereof.

Suitable specific examples of aromatic hydrocarbon groups include a phenyl group, a naphthalene-1-yl group, a naphthalene-2-yl group, a 4-phenylphenyl, 3-phenylphenyl, and 2-phenylphenyl. Among them, a phenyl group is preferable.

The saturated aliphatic hydrocarbon group is preferably an alkyl group. Suitable examples of alkyl groups include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethyl hexyl group, an n-nonyl group, and an n-decyl group.

The hydrocarbon group as R^{f1} and R^{f2} may have one or more substituents. Examples of the substituent include a halogen atom, a hydroxyl group, an alkyl group, an aralkyl group, an alkoxy group, a cycloalkyloxy group, an aryloxy group, an aralkyloxy group, an alkylthio group, a cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group and a cyano group. The number carbon atoms in the substituent is not particularly limited within a range where the objects of the present invention are not impaired, but the number is preferably 1 or more and 10 or less, and more preferably 1 or more and 6 or less.

Suitable specific examples of the organic boron compound represented by the above formula (f1) include the following compounds. Note here that in the following formulae, Pen represents a pentyl group, Hex represents a hexyl group, Hep represents a heptyl group, Oct represents an octyl group, Non represents a nonyl group, and Dec represents a decyl group.

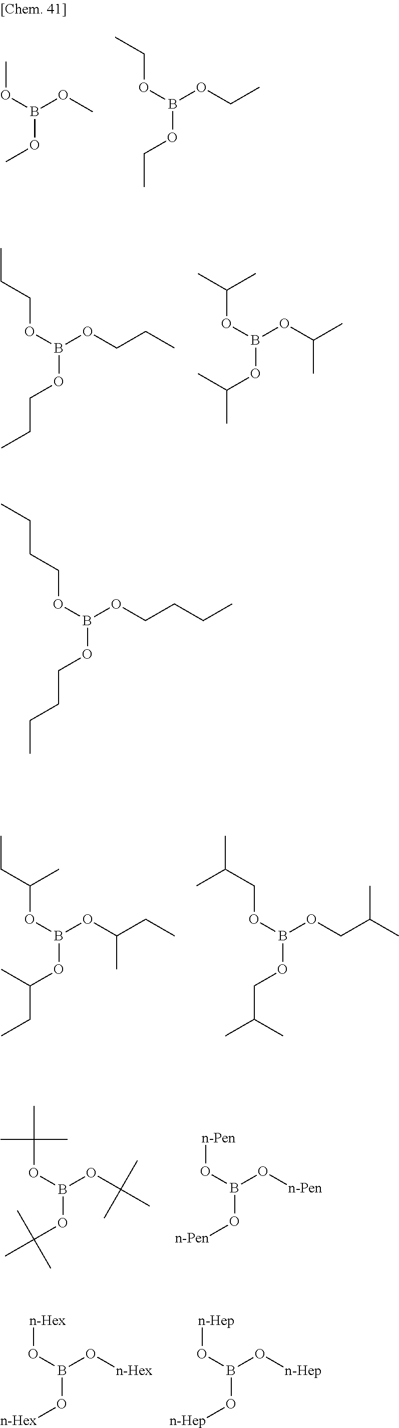

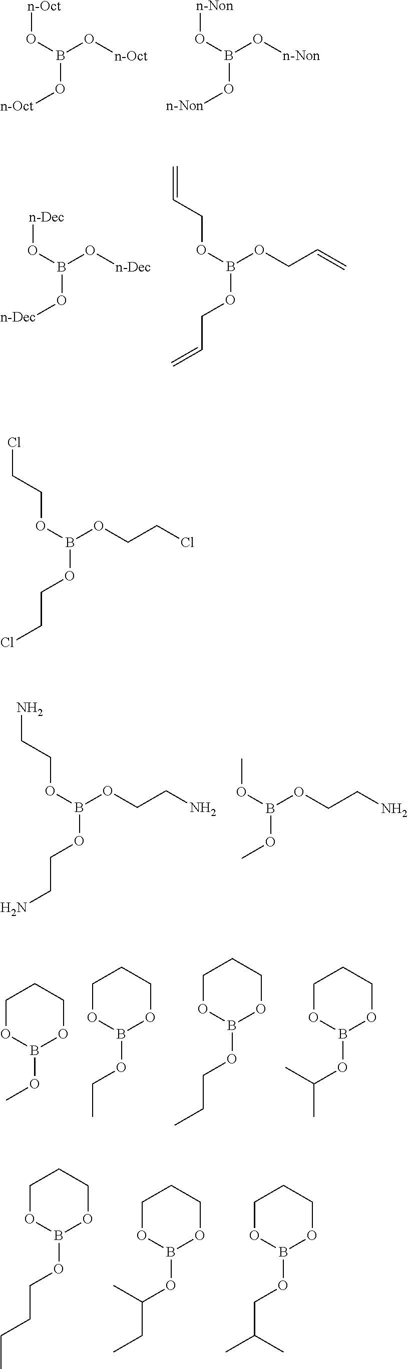

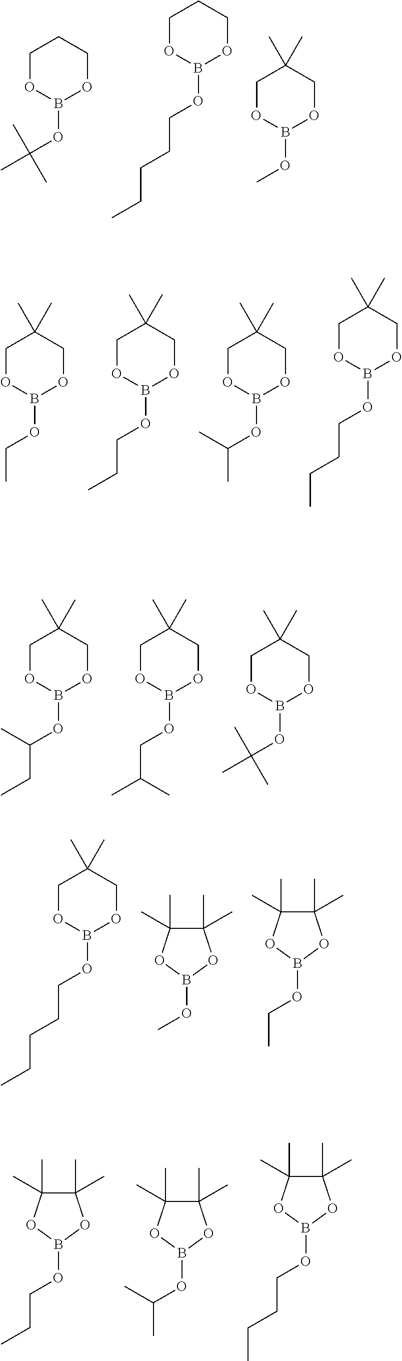

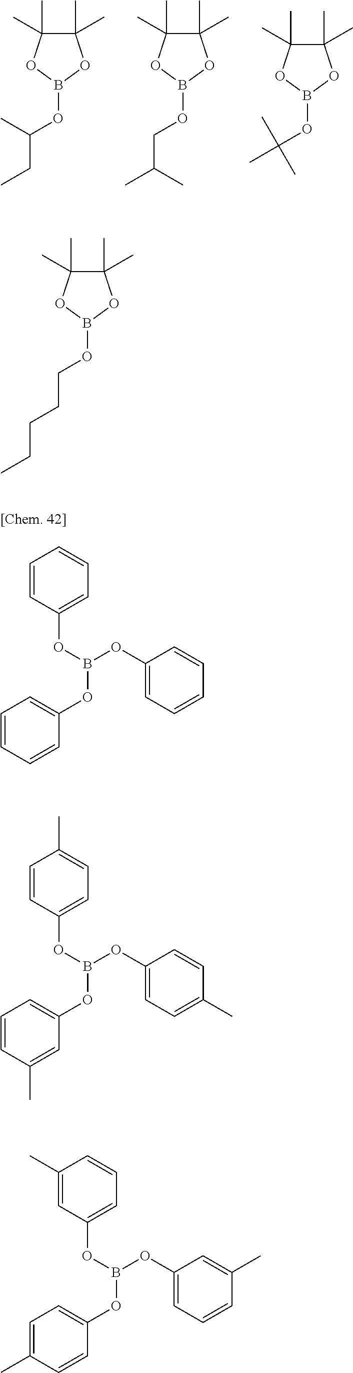

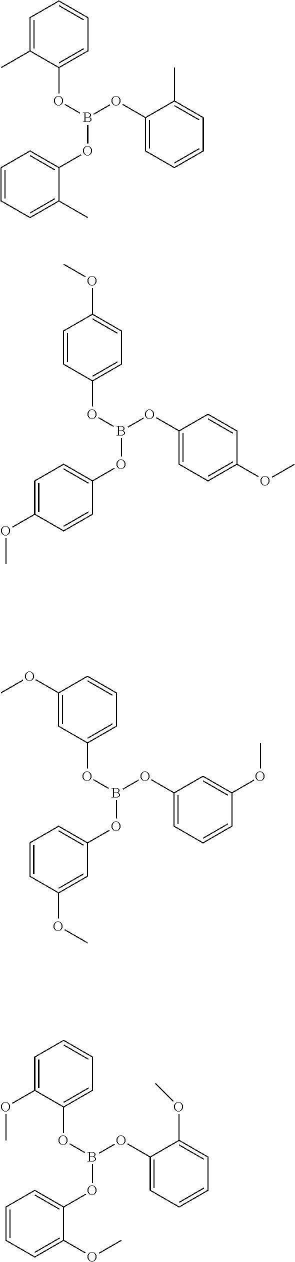

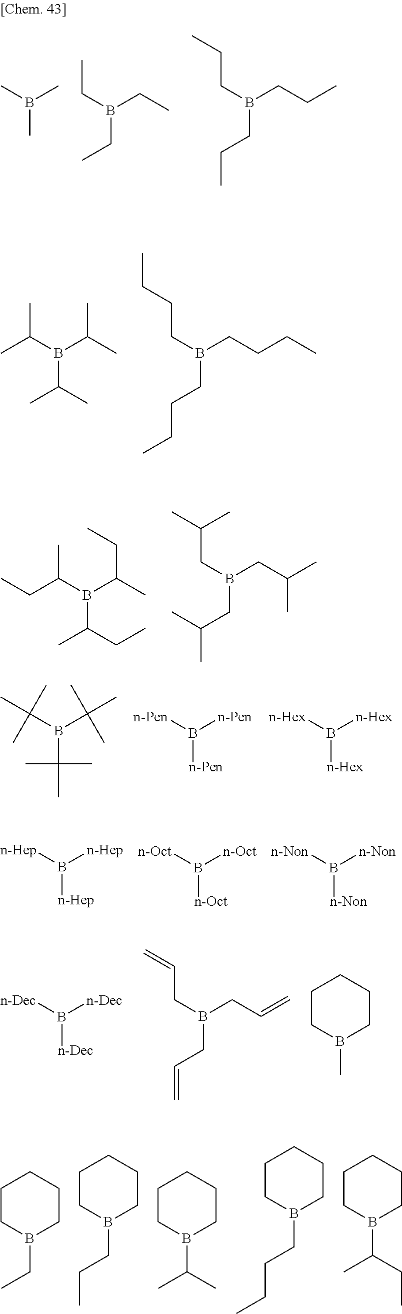

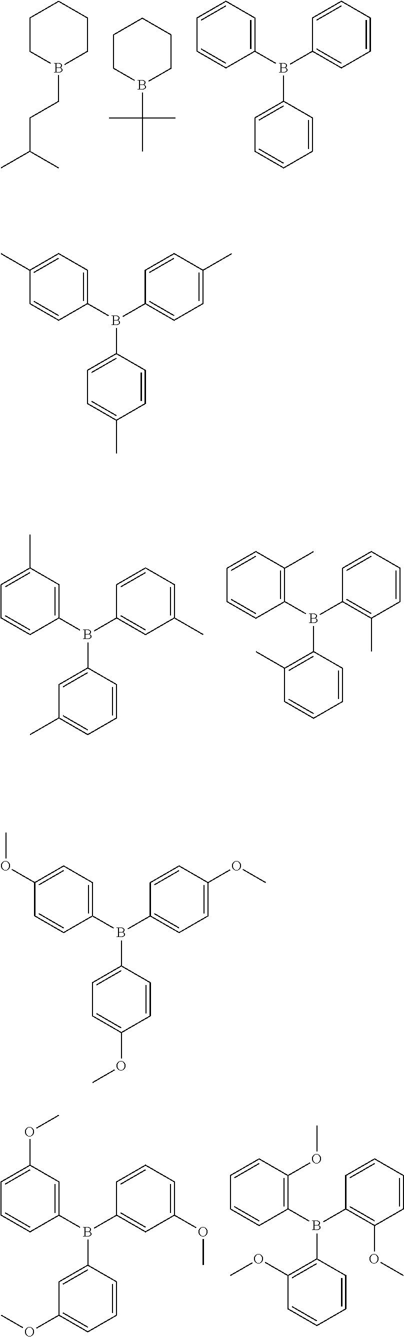

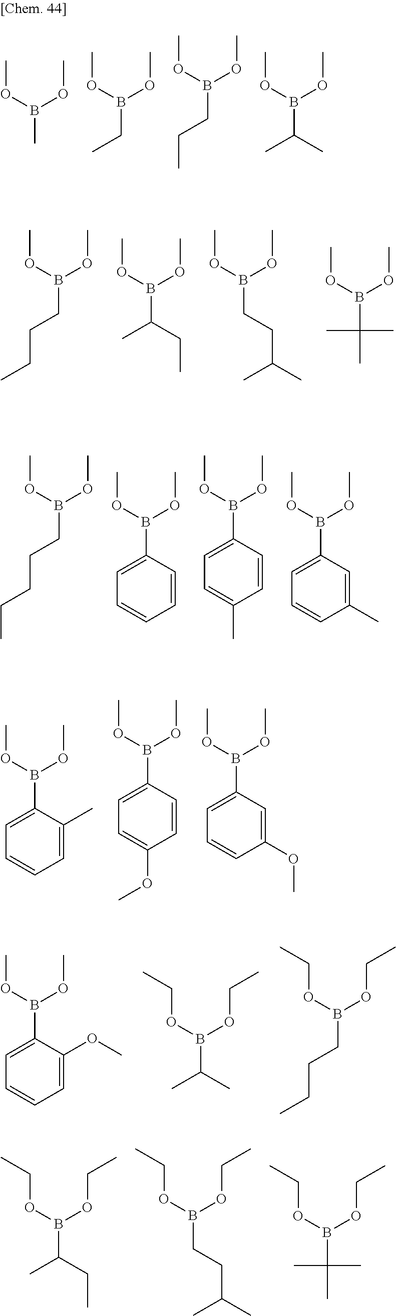

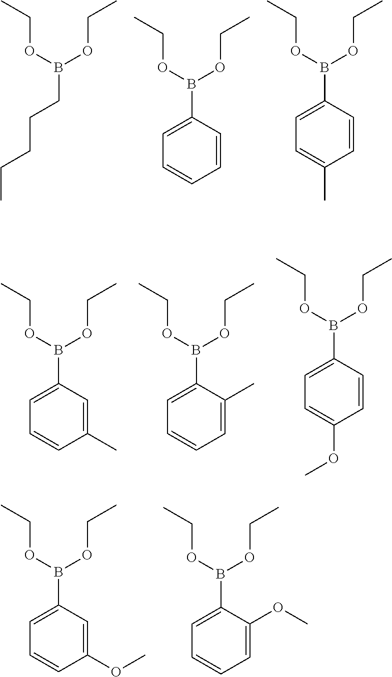

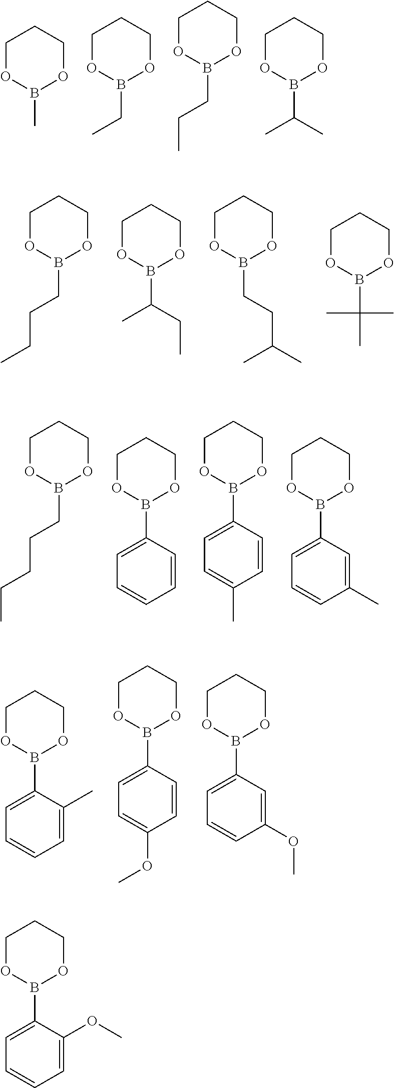

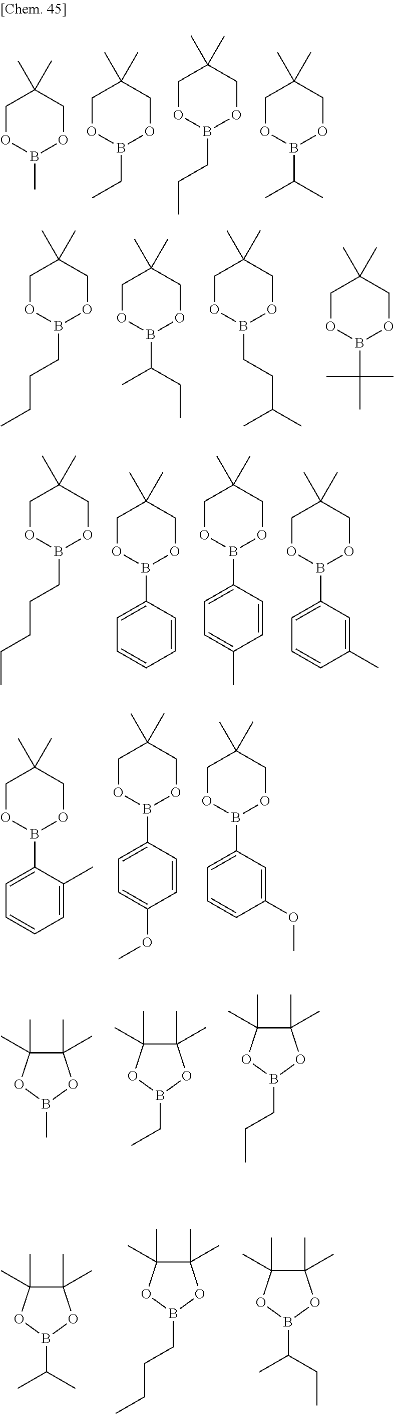

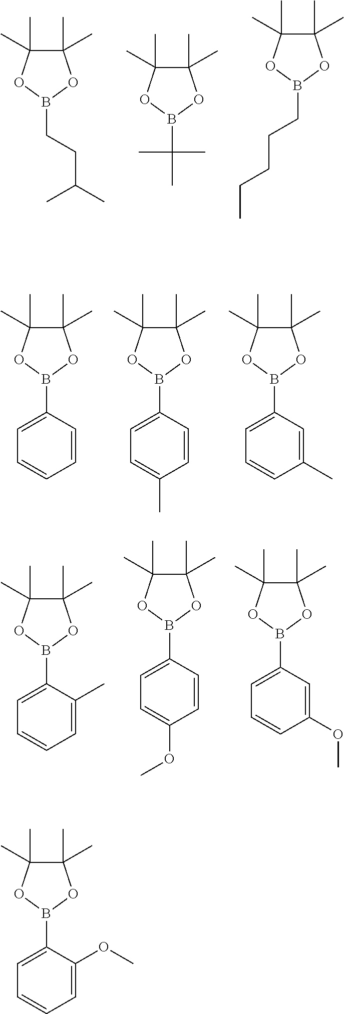

The Lewis acidic compound is used in the amount in a range of preferably 0.01 parts by mas or more and 5 parts by mass or less, more preferably 0.01 parts by mass or more and 3 parts by mass or less, further preferably 0.05 part by mass or more and 2 parts by mass or less, relative to 100 parts by mass of the total mass of the above resin (B) and the above alkali-soluble resin (D).

Further, when the photosensitive composition is used for forming pattern serving as a template for forming a plated article, the photosensitive composition may also contain an adhesive auxiliary agent in order to improve the adhesiveness between a template formed with the photosensitive composition and a metal substrate.

Also, the photosensitive composition may further contain a surfactant for improving coating characteristics, defoaming characteristics, leveling characteristics, and the like. As the surfactant, for example, a fluorine-based surfactant or a silicone-based surfactant is preferably used. Specific examples of the fluorine-based surfactant include commercially available fluorine-based surfactants such as BM-1000 and BM-1100 (both manufactured by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) and the like, but not limited thereto. As the silicone-based surfactant, an unmodified silicone-based surfactant, a polyether modified silicone-based surfactant, a polyester modified silicone-based surfactant, an alkyl modified silicone-based surfactant, an aralkyl modified silicone-based surfactant, a reactive silicone-based surfactant, and the like, can be preferably used. As the silicone-based surfactant, commercially available silicone-based surfactant can be used. Specific examples of the commercially available silicone-based surfactant include Paintad M (manufactured by Dow Corning Toray Co., Ltd.), Topica K1000, Topica K2000, and Topica K5000 (all manufactured by Takachiho Industry Co., Ltd.), XL-121(polyether modified silicone-based surfactant, manufactured by Clariant Co.), BYK-310 (polyester modified silicone-based surfactant, manufactured by BYK), and the like.

Additionally, in order to finely adjust the solubility in a developing solution, the photosensitive composition may further contain an acid or an acid anhydride.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic anhydride, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Moreover, the photosensitive composition may further contain a well-known sensitizer for improving the sensitivity.

### <Manufacturing Method>

In the manufacturing method of a photosensitive composition according to the present invention, the photosensitive composition is manufactured. The manufacturing method of a photosensitive composition includes: preparing a solution of the sulfur-containing compound (C) by dissolving the sulfur-containing compound (C) in the solvent (S1), and blending the solution of the sulfur-containing compound (C), the acid generating agent (A), and the solvent (S2).

In the step of preparing the solution of the sulfur-containing compound (C) by dissolving the sulfur-containing compound (C) in the solvent (S1), it is sufficient that the sulfur-containing compound (C) can be dissolved. As a solvent for dissolving the sulfur-containing compound (C), only the solvent (S1) may be used, or a solvent (S2) may be used together with the solvent (S1). The content of the solvent (S1) in the solvent in which the sulfur-containing compound (C) is dissolved, that is, the content of the solvent (S1) in the solvent contained in the solution of the sulfur-containing compound (C), is preferably 50% by mass or more, more preferably 70% by mass or more, more preferably 85% by mass or more, and most preferably 100% by mass, with respect to the total of the solvent (S1) and the solvent (S2). Note that the solution of the sulfur-containing compound (C) obtained in this step is a premix solution for preparing the chemically amplified photosensitive composition of the present invention.

Then, the obtained solution of the sulfur-containing compound (C) (premix solution for preparing a chemically amplified photosensitive composition), the acid generating agent (A), and the solvent (S2) are mixed. Further, a component to be contained as necessary, such as a resin (B) or an alkali-soluble resin (D), is also mixed. The order in which these are mixed is not particularly limited, and for example, the solution of the sulfur-containing compound (C), the acid generating agent (A), and the solvent (S2) may be mixed simultaneously, or the solution of the sulfur-containing compound (C) and the solvent (S2) are mixed, and then the acid generating agent (A) may be mixed.

As described above, in the present invention, the sulfur-containing compound (C) is dissolved in a specific solvent (S1) in advance to form the solution of the sulfur-containing compound (C), and the solution of the sulfur-containing compound (C) is mixed with the acid generating agent (A) and the solvent (S2), so that the sulfur-containing compound (C) dissolves in the obtained photosensitive composition and does not remain. Further, since the sulfur-containing compound (C) dissolves in the specific solvent (S1), even when the sulfur-containing compound (C) is subsequently mixed with other components afterward, the sulfur-containing compound (C) hardly precipitates. Therefore, even though the sulfur-containing compound (C) is solid at room temperature, the photosensitive composition including a foreign matter derived from the sulfur-containing compound in a reduced amount can be obtained. By using the photosensitive composition including a foreign matter in a reduced amount, a resist pattern including a foreign matter in a reduced amount can be formed. Then, when using the resist pattern including a foreign matter in a reduced amount as a template for forming a plated article or etching mask, it is possible to form a plated article or etched product with a desired shape. Further, even when the photosensitive composition is filtered, since the sulfur-containing compound (C) is dissolved, the sulfur-containing compound (C) is not removed by filtration. There is not a risk that the content of the sulfur-containing compound (C) in the photosensitive composition is decreased.

Further, since the specific solvent (S1) is used, the sulfur-containing compound (C) can be dissolved in a short time, and the production time can be shortened.

On the other hand, as in Patent Documents 3 to 5, when a sulfur-containing compound is mixed as powder without preparing a solution of the sulfur-containing compound in advance, the sulfur-containing compound does not dissolve and remains. Therefore, a significant amount of foreign matter derived from the sulfur-containing compound occurs in the obtained photosensitive composition, and a significant amount of foreign matter occurs in the resist pattern formed using the photosensitive composition.

There is no particular limitation on the method of mixing each component, and mixing, stirring, or the like may be performed according to an ordinary method. Examples of apparatuses to be used when mixing and stirring each of the above components include a dissolver, a homogenizer, a three roll mill, and the like. After uniformly mixing each component, the obtained mixture may be further filtered using a mesh, a membrane filter, or the like. When the photosensitive composition includes a foreign matter derived from the sulfur-containing compound (C) in a state before filtration, there is a risk that the foreign matter derived from the sulfur-containing compound (C) may be removed by filtration, this resulting in a decrease in the content of the sulfur-containing compound (C) in the photosensitive composition. However, in the present invention, since the sulfur-containing compound (C) is dissolved in the specific solvent (S1), the sulfur-containing compound (C) is hardly removed by filtration. Therefore, even when the photosensitive composition is filtered, the content of the sulfur-containing compound (C) is hardly decreased, and the effect of the desired sulfur-containing compound (C) is obtained.

### <<Manufacturing Method of Photosensitive Dry Film>>

A photosensitive dry film includes a substrate film, and a photosensitive layer formed on the surface of the substrate film. The photosensitive layer is made of the aforementioned photosensitive compositions.

As the substrate film, a film having optical transparency is preferable. Specifically, a polyethylene terephthalate (PET) film, a polypropylene (PP) film, a polyethylene (PE) film, and the like. In view of excellent balance between the optical transparency and the breaking strength, a polyethylene terephthalate (PET) film is preferable.

The aforementioned photosensitive composition is applied on the substrate film to form a photosensitive layer, and thereby a photosensitive dry film is manufactured. When the photosensitive layer is formed on the substrate film, a photosensitive composition is applied and dried on the substrate film using an applicator, a bar coater, a wire bar coater, a roller coater, a curtain flow coater, and the like, so that a film thickness after drying is preferably 0.5 μm or more and 300 μm or less, more preferably 1 μm or more and 300 μm or less, and particularly preferably 3 μm or more and 100 μm or less.

The photosensitive dry film may have a protective film on the photosensitive layer. Examples of the protective film include a polyethylene terephthalate (PET) film, a polypropylene (PP) film, a polyethylene (PE) film, and the like.

<<Method of Producing Patterned Resist Film, and Substrate with Template>>

There is no particular limitation on a method of forming a patterned resist film on a substrate using the photosensitive composition described above. Such a patterned resist film is suitably used as an insulating film, an etching mask, and a template for forming a plated article, and the like. A suitable method includes a manufacturing method of a patterned resist film, the method including: laminating a photosensitive layer on a substrate, the layer being formed from a photosensitive composition; exposing the photosensitive layer through irradiation with an active ray or radiation in a position-selective manner; and developing the exposed photosensitive layer. A method of forming a substrate with a template for forming a plated article is the same method as the method of manufacturing a patterned resist film except that the method includes laminating a photosensitive layer on a metal surface of the substrate having a metal surface, and a template for forming a plated article is produced by developing in the developing step.

The substrate on which the photosensitive layer is laminated is not particularly limited, and conventionally known substrates can be used. Examples thereof include a substrate for an electronic component, and the substrate on which a predetermined wiring pattern is formed. As the substrate, a silicon substrate, glass substrate, or the like, can be used. When a substrate with a template for forming a plated article is manufactured, for the substrate, a substrate having a metal surface is used. As metal species constituting a metal surface, copper, gold and aluminum are preferred, and copper is more preferred. When a resist pattern is formed on a substrate having a metal surface, a defect in a cross-sectional shape such as footing tends to occur. However, since the above photosensitive composition contains the sulfur-containing compound (C), occurrence of the defect in a cross-sectional shape such as footing can be suppressed, and a resist pattern having a desired cross-sectional shape can be formed. Further, since the above-described photosensitive composition includes a decreased amount of a foreign matter derived from the sulfur-containing compound (C), a resist pattern having a desired shape can be formed. Further, in the above-described photosensitive composition, since the sulfur-containing compound (C) is hardly removed by filtration, the effect of the desired sulfur-containing compound (C) is obtained.

The photosensitive layer is laminated on the substrate, for example, as follows. In other words, a liquid photosensitive composition is coated onto a substrate, and the coating is heated to remove the solvent and thus to form a photosensitive layer having a desired thickness. The thickness of the photosensitive layer is not particularly limited as long as it is possible to form a resist pattern which has a desired thickness. The thickness of the photosensitive layer is not particularly limited, and is preferably 0.5 μm or more, more preferably 0.5 μm or more and 300 μm or less, more preferably 0.5 μm or more and 150 μm or less, and most preferably 0.5 μm or more and 200 μm or less. The upper limit of the film thickness may be, for example, 100 μm or less. The lower limit of the film thickness may be, for example, 1 μm or more, and may be 3 μm or more.

As a method of applying a photosensitive composition onto a substrate, methods such as the spin coating method, the slit coat method, the roll coat method, the screen printing method and the applicator method can be employed. Pre-baking is preferably performed on a photosensitive layer. The conditions of pre-baking may differ depending on the components in a photosensitive composition, the blending ratio, the thickness of a coating film and the like. They are usually about 2 minutes or more and 120 minutes or less at 70° C. or more and 200° C. or less, and preferably 80° C. or more and 150° C. or less.

The photosensitive layer formed as described above is selectively irradiated (exposed) with an active ray or radiation, for example, an ultraviolet radiation or visible light with a wavelength of 300 nm or more and 500 nm or less through a mask having a predetermined pattern.

Low pressure mercury lamps, high pressure mercury lamps, super high pressure mercury lamps, metal halide lamps, argon gas lasers, etc. can be used for the light source of the radiation. The radiation may include micro waves, infrared rays, visible lights, ultraviolet rays, X-rays, γ-rays, electron beams, proton beams, neutron beams, ion beams, etc. The irradiation dose of the radiation may vary depending on the constituent of the photosensitive composition, the film thickness of the photosensitive layer, and the like. For example, when an ultra-high-pressure mercury lamp is used, the dose may be 100 mJ/cm² or more and 10,000 mJ/cm² or less. The radiation includes a light ray to activate the acid generating agent (A) in order to generate an acid.

After the exposure, the diffusion of acid is promoted by heating the photosensitive layer using a known method to change the alkali solubility of the photosensitive layer in developing solution such as an alkali developing solution at an exposed portion in the photosensitive resin film.

Subsequently, the exposed photosensitive layer is developed in accordance with a conventionally known method, and an unnecessary portion is dissolved and removed to form a predetermined resist pattern or a template for forming plated articles. At this time, as the developing solution, an alkaline aqueous solution is used.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene or 1,5-diazabicyclo[4.3.0]-5-nonane can be used. Also, an aqueous solution prepared by adding an adequate amount of a water-soluble organic solvent such as methanol or ethanol, or a surfactant to the above aqueous solution of the alkali can be used as the developing solution. Furthermore, depending on the composition of the photosensitive composition, developing by an organic solvent can be applied.

The developing time may vary depending on the composition of the photosensitive composition, the film thickness of the photosensitive layer, and the like. Usually, the developing time is 1 minute or more and 30 minutes or less. The method of the development may be any one of a liquid-filling method, a dipping method, a paddle method, a spray developing method, and the like.

After development, it is washed with running water for 30 seconds or more and 90 seconds or less, and then dried with an air gun, an oven, and the like. In this manner, it is possible to form a resist pattern, which has been patterned in a predetermined pattern on a metal surface of a substrate having a metal surface. Also, in this manner, it is possible to manufacture a substrate with a resist pattern on a metal surface of a substrate having a metal surface.

### <<Method of Manufacturing Plated Article>>

A conductor such as a metal may be embedded, by plating, into a nonresist portion (a portion removed with a developing solution) in the template formed by the above method on the substrate to form a plated article, for example, like a contacting terminal such as a bump and a metal post, or Cu redistribution. Note here that there is no particular limitation on the method of plate processing, and various conventionally known methods can be used. As a plating liquid, in particular, a solder plating liquid, a copper plating liquid, a gold plating liquid, and a nickel plating liquid are suitably used. The remaining template is removed with a stripping liquid and the like in accordance with a conventional method.

### EXAMPLES

The present invention will be described in more detail below by way of Examples, but the present invention is not limited to these Examples.

### Examples 1 to 29 and Comparative Examples 1 to 29

In Examples 1 to 29 and Comparative Examples 1 to 29, as the sulfur-containing compound (C), compounds C1 to C5 of the following formulae were used.

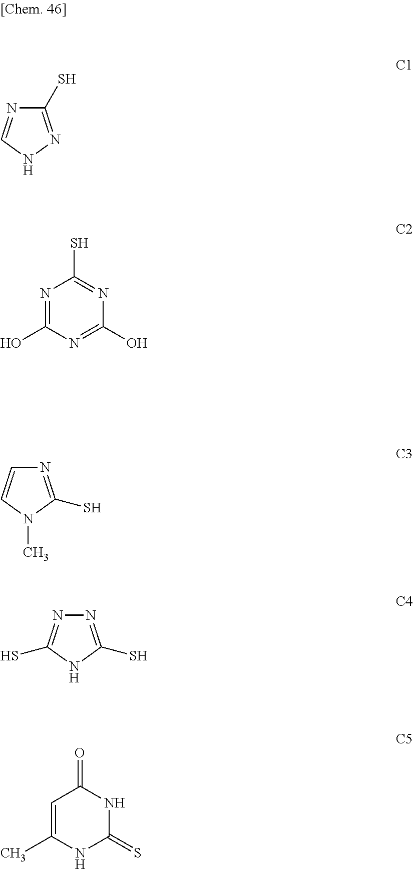

In Examples 1 to 29 and Comparative Examples 1 to 29, as the acid generating agent (A), PAG A1 and PAG A4 of the following formulae were used.

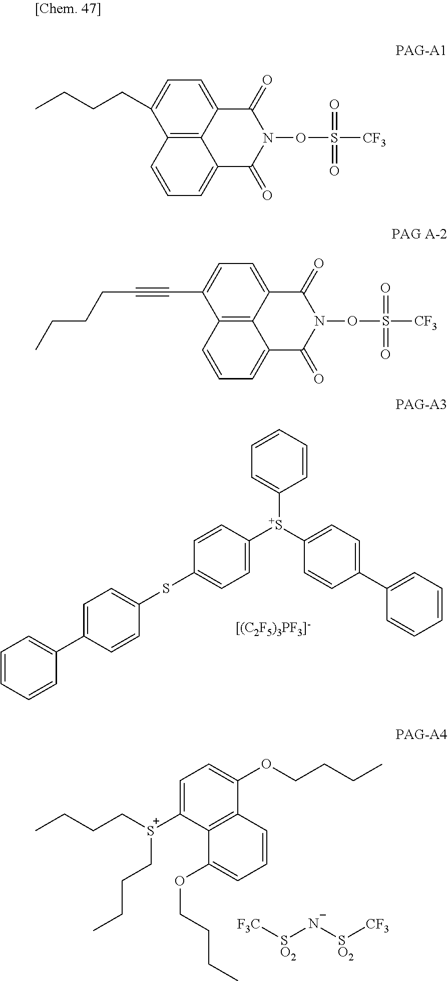 [SMILES: CCCCc1ccc2c3c(cccc13)C(=O)N(OS(=O)(=O)C(F)(F)F)C2=O ; CCCCC#Cc1ccc2c3c(cccc13)C(=O)N(OS(=O)(=O)C(F)(F)F)C2=O ; c1ccc(-c2ccc(Sc3ccc([S+](c4ccccc4)c4ccc(-c5ccccc5)cc4)cc3)cc2)cc1 ; CCCCOc1ccc([S+](CCCC)CCCC)c2c(OCCCC)cccc12 ; O=S(=O)([N-]S(=O)(=O)C(F)(F)F)C(F)(F)F]

In Examples 1 to 29 and Comparative Examples 1 to 29, the following Resin A1 to Resin A5 were used as the resin having an alkali solubility that increases under action of an acid (resin (B)). The number at the lower right of the parentheses in each constituent unit in the following structural formula represents the content (% by mass) of the constituent unit in each resin. Resin A1 has a mass average molecular weight Mw of 40,000 and dispersivity Mw/Mn) of 2.6. Resin A2 has a mass average molecular weight Mw of 40,000 and dispersivity (Mw/Mn) of 2.6. Resin A3 has a number average molecular weight Mn of 98,000. Resin A4 has a number average molecular weight Mn of 98,000. Resin A5 has a number average molecular weight Mn of 98,000.

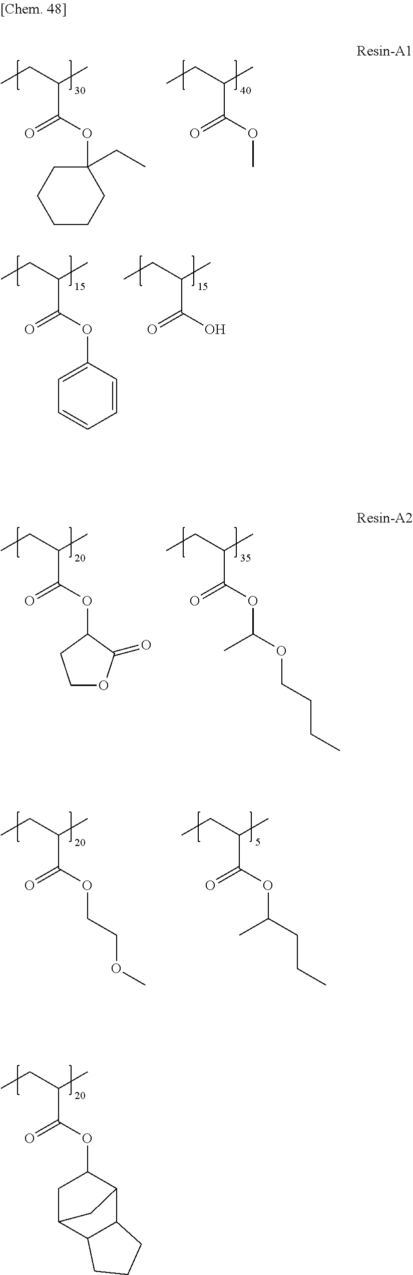

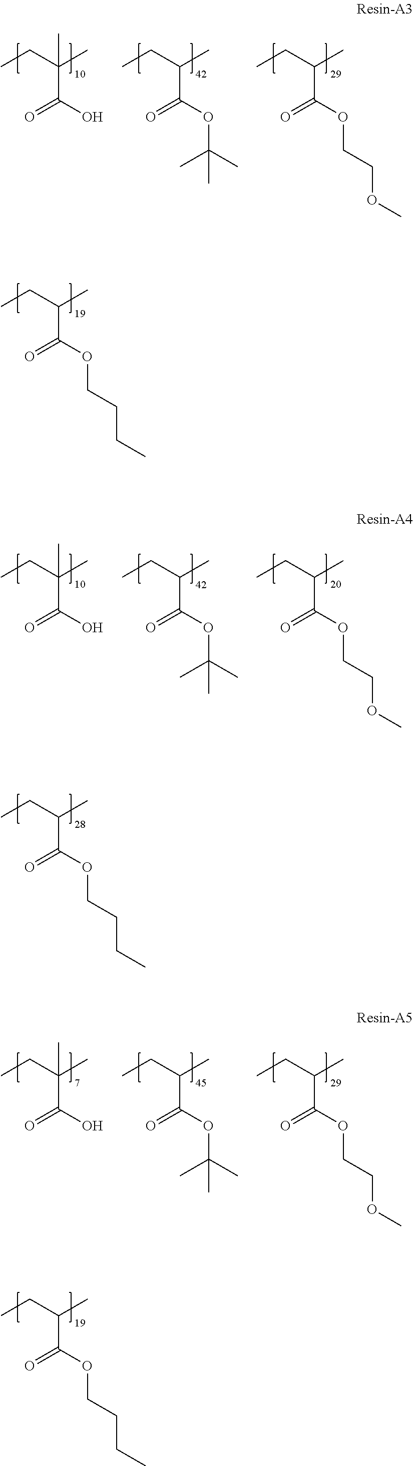

In Examples 1 to 29 and Comparative Examples 1 to 29, the following Resin B1 (polyhydroxystyrene resin) and Resin C (novolac resin (m-cresol mono-condensate)) were used as the alkali-soluble resin (D). The number at the lower right of the parentheses in each constituent unit in the following structural formula represents the content (% by mass) of the constituent unit in each resin. Resin B1 has a mass average molecular weight (Mw) of 2,500, and dispersivity (Mw/Mn) of 2.4. Resin C has a mass average molecular weight (Mw) of 8,000.

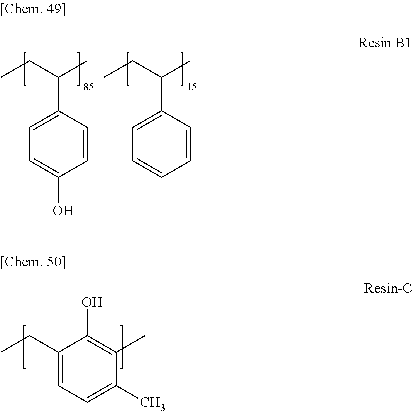

As the acid diffusion inhibiting agent (F), the following Amine-1 to Amine-3 were used.

Amine-1: ADK STAB LA-63P (manufactured by ADEKA)
Amine-2: diphenylpyridine
Amine-3: triphenylpyridine

### Examples 1 to 27

A γ-butyrolactone (GBL) solution (premix solution) in which each of the sulfur-containing compounds (C) described in Table 1 and Table 2 was dissolved so that the content of the sulfur-containing compound (C) was 1% by mass, was obtained. Visually, it was confirmed that the sulfur-containing compound (C) was completely dissolved. In addition, each of the acid generating agents (A), the resins (B), the alkali-soluble resins (D), and the acid diffusion inhibiting agents (F) of types and amounts described in Table 1 and Table 2 and 0.05 parts by mass of a surfactant (BYK310, manufactured by Byk Chemie Co., Ltd.) were dissolved in 3-methoxybutyl acetate (MA, δp: 4.1 MPa^{0.5}, boiling point: 172° C.) so that the solid content was 53% by mass, and then the obtained solution was filtered through a membrane filter having a pore diameter of 1 μm. To each of the solutions after filtration, the γ-butyrolactone solution (premix solution) was added so that the sulfur-containing compound (C) had the values described in Table 1 and Table 2, and the mixture was stirred for 30 minutes and allowed to stand for 4 hours to obtain positive type chemically amplified photosensitive compositions of Examples 1 to 27.

### Example 28

A positive-type chemically amplified photosensitive composition of Example 28 was obtained by carrying out the same procedures as in Example 1, except that dimethyl sulfoxide (DMSO) was used instead of γ-butyrolactone.

### Example 29

A positive chemically amplified photosensitive composition of Example 29 was obtained by carrying out the same procedures as in Example 1, except that N-methyl-2-pyrrolidone (NMP) was used instead of γ-butyrolactone.

### Comparative Examples 1 to 27

Each of the acid generating agents (A), the resins (B), the alkali-soluble resins (D), and the acid diffusion inhibiting agents (F) of types and amounts described in Table 3 and Table 4 and 0.05 parts by mass of a surfactant (BYK310, manufactured by Byk Chemie Co., Ltd.) were dissolved in 3-methoxybutyl acetate (MA) so that the solid content was 53% by mass, and then the obtained solution was filtered through a membrane filter having a pore diameter of 1 μm. To each of the solutions after filtration, the sulfur-containing compound (C) was added so that the sulfur-containing compound (C) had the values described in Table 3 and Table 4, and the mixture was stirred for 30 minutes and allowed to stand for 4 hours to obtain positive-type chemically amplified photosensitive compositions of Comparative Examples 1 to 27.

### Comparative Example 28

A positive-type chemically amplified photosensitive composition of Comparative Example 28 was obtained by carrying out the same procedures as in Example 1, except that methyl ethyl ketone (MEK, δp: 9.0 MPa^{0.5}, boiling point: 80° C.) was used instead of γ-butyrolactone. The methyl ethyl ketone solution (premix solution) in which the sulfur-containing compound (C) was dissolved so that the content of the sulfur-containing compound (C) was 1% by mass was a suspension in which the sulfur-containing compound (C) was not dissolved, and the obtained positive-type chemically amplified photosensitive composition was also a suspension.

### Comparative Example 29

A positive-type chemically amplified photosensitive composition of Comparative Example 29 was obtained by carrying out the same procedures as in Example 1, except that 3-methoxybutyl acetate (MA) was used instead of γ-butyrolactone. The 3-methoxybutyl acetate solution (premix solution) in which the sulfur-containing compound (C) was dissolved so that the content of the sulfur-containing compound (C) was 1% by mass was a suspension in which the sulfur-containing compound (C) was not dissolved, and the obtained positive-type chemically amplified photosensitive composition was also a suspension.

The obtained positive-type chemically amplified photosensitive compositions were evaluated according to the following method. The evaluation results are described in Tables 1 to 4.

### [Evaluation for Foreign Matter]

Silicon substrates having a diameter of 8 inches were provided, each of the substrate including a copper layer formed by sputtering on a surface thereof. The chemically amplified photosensitive compositions of Examples and Comparative Examples were each applied on the copper layer of each of the substrates to form a photosensitive layer (coated film of the chemically amplified photosensitive composition) having a thickness of 55 μm. Then, the photosensitive layer was pre-baked at 130° C. for 5 minutes. After the pre-baking, using a mask having a line-and-space pattern having a line width of 2.0 μm and a space width of 2.0 μm, and Canon PLA501F Hardcontact (manufactured by Canon Inc.), pattern exposure was performed with an ultraviolet ray having a wavelength of 365 nm at an exposure dose greater by 1.2 times than the minimum exposure dose capable of forming a pattern having a predetermined size. Subsequently, the substrate was mounted on a hot plate and post-exposure baking (PEB) was performed at 90° C. for 1.5 minutes. Subsequently, an aqueous 2.38% by weight solution of tetramethylammonium hydroxide (TMAH) (developing solution, NMD-3, manufactured by Tokyo Ohka Kogyo Co., Ltd.) was added dropwise to the exposed photosensitive layer, and the photosensitive layer was allowed to stand at 23° C. for 30 seconds. This operation was repeated three times in total. Subsequently, the surface of the resist pattern was washed (rinsed) with running water, and blown with nitrogen to obtain a resist pattern. For the obtained resist pattern (line and space pattern), 50 locations were randomly observed under an optical microscope (magnification: 10×magnification) to confirm the presence or absence of a foreign matter (the sulfur-containing compound (C) remaining without being dissolved). The resist pattern in which 3 or less foreign matters were observed was evaluated as excellent (indicated by bullseye symbol (⊙)), the resist pattern in which 4 or more and 9 or less foreign matters were observed was evaluated as good (indicated by circle symbol (∘)), and the resist pattern in which 10 or more and 19 or less foreign matters were observed was evaluated as poor (indicated by cross symbol (×)), and the resist pattern in which 20 or more foreign matters were observed was evaluated as bad (indicated by double cross symbol (××)). Note that the observed foreign matters had a size of 10 μm or more and 1 mm or less. Furthermore, since filtration was performed before addition of the sulfur-containing compound (C), the foreign matters observed are considered to be only those derived from the sulfur-containing compound (C).

TABLE 1

| | | Resin (B) and | | Acid diffusion | | |
|---|---|---|---|---|---|---|
| | Acid generating | alkali-soluble | Sulfur-containing | inhibiting | | |
| | agent (A) | resin (D) | compound (C) | agent (F) | Solvent | Evaluation |
| | Type/part(s) | Type/part(s) | Type/part(s) | Type/part(s) | (S1) | Foreign |
| | by mass | by mass | by mass | by mass | Type | matter |
| Example 1 | PAG-A1/0.3 | Resin-A1/40 | C1/0.1 | Amine-1/0.15 | GBL | ⊙ |
| Example 2 | | Resin-B1/20 | C2/0.1 | | | ⊙ |
| Example 3 | | Resin-C/40 | C3/0.1 | | | ⊙ |
| Example 4 | | | C4/0.1 | | | ⊙ |
| Example 5 | | | C5/0.1 | | | ⊙ |
| Example 6 | | | C1/0.03 | | | ⊙ |
| Example 7 | | | C2/0.03 | | | ⊙ |
| Example 8 | | | C1/0.3 | | | ⊙ |
| Example 9 | | | C2/0.3 | | | ⊙ |
| Example 10 | PAG-A2/0.3 | | C1/0.1 | Amine-1/1.5 | | ⊙ |
| Example 11 | | | C2/0.1 | | | ⊙ |
| Example 12 | PAG-A3/1.5 | | C1/0.1 | Amine-2/0.1 | | ⊙ |
| Example 13 | | | C2/0.1 | Amine-3/0.1 | | ⊙ |
| Example 14 | PAG-A4/1.5 | | C1/0.1 | | | ⊙ |
| Example 15 | | | C2/0.1 | | | ⊙ |

TABLE 2

| | | Resin (B) and | | Acid diffusion | | |
|---|---|---|---|---|---|---|
| | Acid generating | alkali-soluble | Sulfur-containing | inhibiting | | |
| | agent (A) | resin (D) | compound (C) | agent (F) | Solvent | Evaluation |
| | Type/part(s) | Type/part(s) | Type/part(s) | Type/part(s) | (S1) | Foreign |
| | by mass | by mass | by mass | by mass | Type | matter |
| Example 16 | PAG-A1/0.3 | Resin-A1/40 | C1/0.1 | Amine-1/1.5 | GBL | ⊙ |
| Example 17 | | Resin-B1/20 | C2/0.1 | | | ⊙ |
| | | Resin-C/40 | | | | |
| Example 18 | | Resin-A2/40 | C1/0.1 | | | ⊙ |
| Example 19 | | Resin-B1/20 | C2/0.1 | | | ⊙ |
| | | Resin-C/40 | | | | |
| Example 20 | | Resin-A3/40 | C1/0.1 | | | ⊙ |
| Example 21 | | Resin-B1/20 | C2/0.1 | | | ⊙ |
| | | Resin-C/40 | | | | |
| Example 22 | | Resin-A4/40 | C1/0.1 | | | ⊙ |
| Example 23 | | Resin-B1/20 | C2/0.1 | | | ⊙ |
| | | Resin-C/40 | | | | |
| Example 24 | | Resin-A5/40 | C1/0.1 | | | ⊙ |
| Example 25 | | Resin-B1/20 | C2/0.1 | | | ⊙ |
| | | Resin-C/40 | | | | |
| Example 26 | PAG-A3/1.5 | Resin-A2/100 | C1/0.1 | Amine-2/0.1 | | ⊙ |
| Example 27 | | | C2/0.1 | Amine-3/0.1 | | ⊙ |
| Example 28 | PAG-A1/0.3 | Resin-A1/40 | C1/0.1 | Amine-1/0.15 | DMSO | ⊙ |
| Example 29 | | Resin-B1/20 | | | NMP | ⊙ |
| | | Resin-C/40 | | | | |

TABLE 3

| | Acid generating | Resin (B) and | Sulfur-containing | Acid diffusion | |
|---|---|---|---|---|---|
| | agent | alkali-soluble | compound | inhibiting agent | |
| | (A) | resin (D) | (C) | (F) | Evaluation |
| | Type/part(s) | Type/part(s) | Type/part(s) | Type/part(s) | Foreign |
| | by mass | by mass | by mass | by mass | matter |
| Comparative Example 1 | PAG-A1/0.3 | Resin-A1/40 | C1/0.1 | Amine-1/0.15 | xx |
| Comparative Example 2 | | Resin-B1/20 | C2/0.1 | | xx |
| Comparative Example 3 | | Resin-C/40 | C3/0.1 | | xx |
| Comparative Example 4 | | | C4/0.1 | | xx |
| Comparative Example 5 | | | C5/0.1 | | xx |
| Comparative Example 6 | | | C1/0.03 | | xx |
| Comparative Example 7 | | | C2/0.03 | | xx |
| Comparative Example 8 | | | C1/0.3 | | xx |
| Comparative Example 9 | | | C2/0.3 | | xx |
| Comparative Example 10 | PAG-A2/0.3 | | C1/0.1 | Amine-1/1.5 | xx |
| Comparative Example 11 | | | C2/0.1 | | xx |
| Comparative Example 12 | PAG-A3/1.5 | | C1/0.1 | Amine-2/0.1 | xx |
| Comparative Example 13 | | | C2/0.1 | Amine-3/0.1 | xx |
| Comparative Example 14 | PAG-A4/1.5 | | C1/0.1 | | xx |
| Comparative Example 15 | | | C2/0.1 | | xx |

TABLE 4

| | Acid generating | Resin (B) and | Sulfur-containing | Acid diffusion | |
|---|---|---|---|---|---|
| | agent | alkali-soluble | compound | inhibiting agent | |
| | (A) | resin (D) | (C) | (F) | Evaluation |
| | Type/part(s) | Type/part(s) | Type/part(s) | Type/part(s) | Foreign |
| | by mass | by mass | by mass | by mass | matter |
| Comparative Example 16 | PAG-A1/0.3 | Resin-A1/40 | C1/0.1 | Amine-1/1.5 | xx |
| Comparative Example 17 | | Resin-B1/20 | C2/0.1 | | xx |
| | | Resin-C/40 | | | |
| Comparative Example 18 | | Resin-A2/40 | C1/0.1 | | xx |
| Comparative Example 19 | | Resin-B1/20 | C2/0.1 | | xx |
| | | Resin-C/40 | | | |
| Comparative Example 20 | | Resin-A3/40 | C1/0.1 | | xx |
| Comparative Example 21 | | Resin-B1/20 | C2/0.1 | | xx |
| | | Resin-C/40 | | | |
| Comparative Example 22 | | Resin-A4/40 | C1/0.1 | | xx |
| Comparative Example 23 | | Resin-B1/20 | C2/0.1 | | xx |
| | | Resin-C/40 | | | |
| Comparative Example 24 | | Resin-A5/40 | C1/0.1 | | xx |
| Comparative Example 25 | | Resin-B1/20 | C2/0.1 | | xx |
| | | Resin-C/40 | | | |
| Comparative Example 26 | PAG-A3/1.5 | Resin-A2/100 | C1/0.1 | Amine-2/0.1 | xx |
| Comparative Example 27 | | | C2/0.1 | Amine-3/0.1 | xx |
| Comparative Example 28 | PAG-A1/0.3 | Resin-A1/40 | C1/0.1 | Araine-1/0.15 | x |
| Comparative Example 29 | | Resin-B1/20 | | | x |
| | | Resin-C/40 | | | |

According to Examples 1 to 29, it can be seen that in the resist patterns formed of the chemically amplified photosensitive compositions prepared by dissolving in advance the sulfur-containing compound (C), the sulfur-containing compound (C) being solid at room temperature, in the solvent (S1) having a Hansen solubility parameter in which the polar term δp is 10 (MPa^{0.5}) or more, and then mixing with other components, fewer foreign matters occurred. Furthermore, it can be seen that the chemically amplified photosensitive compositions of Examples 1 to 29 included fewer foreign matters, since there were fewer foreign matters in the resist patterns formed.

Contrary to this, it can be seen from Comparative Examples 1 to 29 that, in the resist patterns formed of the chemically amplified photosensitive compositions of Comparative Examples 1 to 27 prepared by adding the sulfur-containing compound (C), the sulfur-containing compound (C) being solid at room temperature, as powder (solid) or in the resist patterns formed of the chemically amplified photosensitive compositions of Comparative Examples 28 and 29 prepared by dissolving in advance the sulfur-containing compound (C) in a solvent having a Hansen solubility parameter in which the polar term δp is less than 10 (MPa^{0.5}) and then mixing with other components, significant number of foreign matters occurred.

1. A method for manufacturing a chemically amplified photosensitive composition, the composition comprising:
an acid generating agent (A) to generate an acid by irradiation with an active ray or radiation,
a sulfur-containing compound (C), the sulfur-containing compound (C) being solid at room temperature,
a solvent (S1) having a Hansen solubility parameter in which a polar term δp is 10 (MPa^{0.5}) or more, and
a solvent (S2), the solvent (S2) being a different solvent from the solvent (S1), the method comprising:
preparing a solution of the sulfur-containing compound (C) by dissolving the sulfur-containing compound (C) in the solvent (S1), and
blending the solution of the sulfur-containing compound (C), the acid generating agent (A), and the solvent (S2).

2. The method for manufacturing a chemically amplified photosensitive composition according to claim 1, wherein the sulfur-containing compound (C) comprises at least one selected from the group consisting of a compound represented by the following formula (c1-1) or (c1-2) or a tautomer thereof and a compound represented by the following formula (c2): 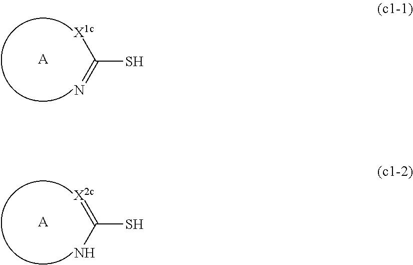
wherein ring A is a monocyclic ring in which the number of ring constituting atoms is 4 or more and 8 or less, or a polycyclic ring in which the number of ring constituting atoms is 5 or more and 20 or less;
X^{1c} is —CR^{11c}R^{12c}—, —NR^{13c}—, —O—, —S—, —Se—, —Te—, ═CR^{14c}—, or ═N—;
X^{2c} is —CR^{11c}═ or —N═;
R^{11c}, R^{12c}, R^{13c} and R^{14c} are each independently a hydrogen atom, an optionally substituted alkyl group having 1 or more and 8 or less carbon atoms, an optionally substituted alkenyl group having 1 or more and 8 or less carbon atoms, an optionally substituted alkynyl group having 1 or more and 8 or less carbon atoms, an optionally substituted aromatic group having 4 or more and 20 or less carbon atoms, or a carboxyl group, and 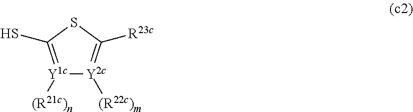
wherein Y^{1c} and Y^{2c} are each independently a nitrogen atom or a carbon atom;
R^{21c} and R^{22c} are each independently a hydrogen atom, an aliphatic hydrocarbon group having 1 or more and 10 or less carbon atoms, an aromatic hydrocarbon group having 6 or more and 14 or less carbon atoms, and an alicyclic hydrocarbon group having 3 or more and 18 or less carbon atoms;
R^{23c} is a hydrogen atom, an aliphatic hydrocarbon group having 1 or more and 10 or less carbon atoms, an aromatic hydrocarbon group having 6 or more and 14 or less carbon atoms, an alicyclic hydrocarbon group having 3 or more and 18 or less carbon atoms, —SR^{24c}, or —NR^{25c}R^{26c};
R^{24c}, R^{25c}, and R^{26c} are each independently a hydrogen atom, an aliphatic hydrocarbon group having 1 or more and 10 or less carbon atoms, an alicyclic hydrocarbon group having 3 or more and 10 or less carbon atoms, an aromatic hydrocarbon group having 6 or more and 14 or less carbon atoms, or an acyl group having 1 or more and 12 or less carbon atoms;
a hydrogen atom of the aliphatic hydrocarbon group, the alicyclic hydrocarbon group, the aromatic hydrocarbon group, and the acyl group in R^{25c} and R^{26c} may be replaced with a hydroxy group; and
n and m are each independently 0 or 1; when Y^{1c} is a nitrogen atom, n is 0; when Y^{1c} is a carbon atom, n is 1; when Y^{2c} is a nitrogen atom, m is 0; and when Y^{2c} is a carbon atom, m is 1.

3. The method for manufacturing a chemically amplified photosensitive composition according to claim 2, wherein, in the formula (c1-1), X^{1c} is —NR^{13c}— or ═N— and in the formula (c2), Y^{1c} and Y^{2c} are nitrogen atoms.

4. The method for manufacturing a chemically amplified photosensitive composition according to claim 1, wherein the solvent (S1) is γ-butyrolactone, dimethyl sulfoxide, or N-methyl-2-pyrrolidone.

5. The method for manufacturing a chemically amplified photosensitive composition according to claim 1, wherein the chemically amplified photosensitive composition is a positive type.

6. The method for manufacturing a chemically amplified photosensitive composition according to claim 5, wherein the chemically amplified photosensitive composition comprises a resin (B) having an alkali solubility that increases under action of an acid.

7. The method for manufacturing a chemically amplified photosensitive composition according to claim 5, wherein the chemically amplified photosensitive composition further comprises an alkali-soluble resin (D).

8. The method for manufacturing a chemically amplified photosensitive composition according to claim 7, wherein the alkali-soluble resin (D) comprises at least one selected from the group consisting of a novolac resin (D1), a polyhydroxystyrene resin (D2), and an acrylic resin (D3).

9. A premix solution for preparing a chemically amplified photosensitive composition, comprising:
a sulfur-containing compound (C), the sulfur-containing compound (C) being solid at room temperature, and
a solvent (S1) having a Hansen solubility parameter in which a polar term δp is 10 (MPa^{0.5}) or more,
wherein the sulfur-containing compound (C) is dissolved in the solvent (S1).

10. The premix solution for preparing a chemically amplified photosensitive composition according to claim 9, wherein the sulfur-containing compound (C) comprises at least one selected from the group consisting of a compound represented by the following formula (c1-1) or (c1-2) or a tautomer thereof and a compound represented by the following formula (c2): 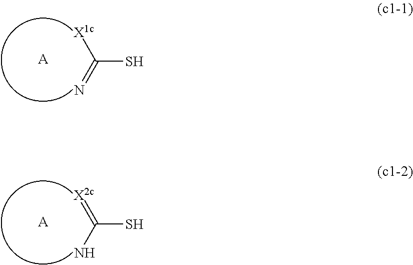
wherein ring A is a monocyclic ring having the number of ring constituting atoms of 4 or more and 8 or less, or a polycyclic ring having the number of ring constituting atoms of 5 or more and 20 or less;
X^{1c} is —CR^{11c}R^{12c}—, —NR^{13c}—, —O—, —S—, —Se—, —Te—, ═CR^{14c}—, or ═N—;
X^{2c} is —CR^{11c}═ or —N═;
R^{11c}, R^{12c}, R^{13c} and R^{14c} are each independently a hydrogen atom, an optionally substituted alkyl group having 1 or more and 8 or less carbon atoms, an optionally substituted alkenyl group having 1 or more and 8 or less carbon atoms, an optionally substituted alkynyl group having 1 or more and 8 or less carbon atoms, an optionally substituted aromatic group having 4 or more and 20 or less carbon atoms, or a carboxyl group, and 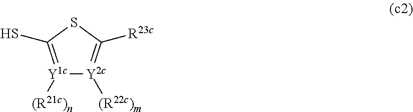
wherein
Y^{1c} and Y^{2c} are each independently a nitrogen atom or a carbon atom;
R^{21c} and R^{22c} are each independently a hydrogen atom, an aliphatic hydrocarbon group having 1 or more and 10 or less carbon atoms, an aromatic hydrocarbon group having 6 or more and 14 or less carbon atoms, and an alicyclic hydrocarbon group having 3 or more and 18 or less carbon atoms;
R^{23c} is a hydrogen atom, an aliphatic hydrocarbon group having 1 or more and 10 or less carbon atoms, an aromatic hydrocarbon group having 6 or more and 14 or less carbon atoms, an alicyclic hydrocarbon group having 3 or more and 18 or less carbon atoms, —SR^{24c}, or —NR^{25c}R^{26c};
R^{24c}, R^{25c}, and R^{26c} are each independently a hydrogen atom, an aliphatic hydrocarbon group having 1 or more and 10 or less carbon atoms, an alicyclic hydrocarbon group having 3 or more and 10 or less carbon atoms, an aromatic hydrocarbon group having 6 or more and 14 or less carbon atoms, or an acyl group having 1 or more and 12 or less carbon atoms;
a hydrogen atom of the aliphatic hydrocarbon group, the alicyclic hydrocarbon group, the aromatic hydrocarbon group, and the acyl group in R^{25c} and R^{26c} may be replaced with a hydroxy group; and
n and m are each independently 0 or 1; when Y^{1c} is a nitrogen atom, n is 0; when Y^{1c} is a carbon atom, n is 1; when Y^{2c} is a nitrogen atom, m is 0; and when Y^{2c} is a carbon atom, m is 1.

11. The premix solution for manufacturing a chemically amplified photosensitive composition according to claim 10, wherein, in the formula (c1-1), X^{1c} is —NR^{13c}— or ═N— and in the formula (c2), Y^{1c} and Y^{2c} are nitrogen atoms.

12. The premix solution for manufacturing a chemically amplified photosensitive composition according to claim 9, wherein the solvent (S1) is γ-butyrolactone, dimethyl sulfoxide, or N-methyl-2-pyrrolidone.

13. A chemically amplified photosensitive composition, comprising:
an acid generating agent (A) which generates an acid by irradiation with an active ray or radiation,
a sulfur-containing compound (C) which is a solid at room temperature,
a solvent (S1) having a Hansen solubility parameter in which a polar term δp is 10 (MPa^{0.5}) or more, and
a solvent (S2) that is different than the solvent (S1),
wherein the chemically amplified photosensitive composition has a content of the solvent (S1) of greater than 0% by mass and less than 5% by mass, with respect to a total mass of the solvent (S1) and the solvent (S2).

14. The chemically amplified photosensitive composition according to claim 13, wherein the sulfur-containing compound (C) comprises at least one selected from the group consisting of a compound represented by the following formula (c1-1) or (c1-2) or a tautomer thereof and a compound represented by the following formula (c2): 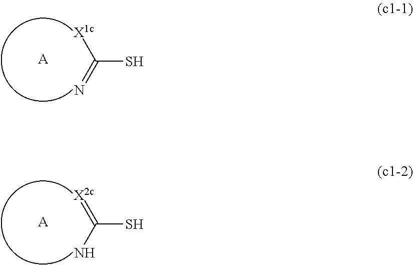
wherein ring A is a monocyclic ring in which the number of ring constituting atoms is 4 or more and 8 or less, or a polycyclic ring in which the number of ring constituting atoms is 5 or more and 20 or less;
X^{1c} is —CR^{11c}R^{12c}—, —NR^{13c}—, —O—, —S—, —Se—, —Te—, ═CR^{14c}—, or ═N—,
X²c is —CR^{11c}═ or —N═,
R^{11c}, R^{12c}, R^{13c}, and R^{14c} are each independently a hydrogen atom, an optionally substituted alkyl group having 1 or more and 8 or less carbon atoms, an optionally substituted alkenyl group having 1 or more and 8 or less carbon atoms, an optionally substituted alkynyl group having 1 or more and 8 or less carbon atoms, an optionally substituted aromatic group having 4 or more and 20 or less carbon atoms, or a carboxyl group, and 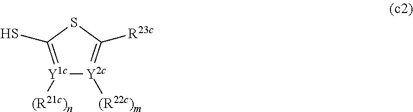
wherein Y^{1c} and Y^{2c} are each independently a nitrogen atom or a carbon atom;
R^{21c} and R^{22c} are each independently a hydrogen atom, an aliphatic hydrocarbon group having 1 or more and 10 or less carbon atoms, an aromatic hydrocarbon group having 6 or more and 14 or less carbon atoms, and an alicyclic hydrocarbon group having 3 or more and 18 or less carbon atoms,
R^{23c} is a hydrogen atom, an aliphatic hydrocarbon group having 1 or more and 10 or less carbon atoms, an aromatic hydrocarbon group having 6 or more and 14 or less carbon atoms, an alicyclic hydrocarbon group having 3 or more and 18 or less carbon atoms, —SR^{24c}, or —NR^{25c}R^{26c}; R^{24c}, R^{25c}, and R^{26c} are each independently a hydrogen atom, an aliphatic hydrocarbon group having 1 or more and 10 or less carbon atoms, an alicyclic hydrocarbon group having 3 or more and 10 or less carbon atoms, an aromatic hydrocarbon group having 6 or more and 14 or less carbon atoms, or an acyl group having 1 or more and 12 or less carbon atoms;
a hydrogen atom of the aliphatic hydrocarbon group, the alicyclic hydrocarbon group, the aromatic hydrocarbon group, and the acyl group in R^{25c} and R^{26c} may be replaced with a hydroxy group; and
n and m are each independently 0 or 1; when Y^{1c} is a nitrogen atom, n is 0; when Y^{1c} is a carbon atom, n is 1; when Y^{2c} is a nitrogen atom, m is 0; and when Y^{2c} is a carbon atom, m is 1.

15. The chemically amplified photosensitive composition according to claim 14, wherein, in the formula (c1-1), X^{1c} is —NR^{13c}— or ═N— and in the formula (c2), Y^{1c} and Y^{2c} are nitrogen atoms.

16. The chemically amplified photosensitive composition according to claim 13, wherein the solvent (S1) is γ-butyrolactone, dimethyl sulfoxide, or N-methyl-2-pyrrolidone.

17. The chemically amplified photosensitive composition according to claim 13, wherein the chemically amplified photosensitive composition is a positive type.

18. The chemically amplified photosensitive composition according to claim 17, further comprising a resin (B) having an alkali solubility that increases under action of an acid.

19. The chemically amplified photosensitive composition according to claim 17, further comprising an alkali-soluble resin (D).

20. The chemically amplified photosensitive composition according to claim 19, wherein the alkali-soluble resin (D) comprises at least one selected from the group consisting of a novolac resin (D1), a polyhydroxystyrene resin (D2), and an acrylic resin (D3).

21. A method for manufacturing a photosensitive dry film, the method comprising coating a substrate film with the chemically amplified photosensitive composition according to claim 13, to form a photosensitive layer.

22. A method for manufacturing a patterned resist film, the method comprising:
laminating a photosensitive layer on a substrate, the layer comprising the chemically amplified photosensitive composition according to claim 13;
exposing the photosensitive layer through irradiation with an active ray or radiation in a position-selective manner; and
developing the exposed photosensitive layer.

23. The method for manufacturing a patterned resist film according to claim 22, wherein the substrate is a substrate having a metal surface.
